(19) United States
(12) Patent Application Publication
(10) Pub. No.: US 2024/0172553 A1
(43) Pub. Date: May 23, 2024

(54) ORGANIC COMPOUND AND ORGANIC LIGHT EMITTING ELEMENT

(71) Applicant: CANON KABUSHIKI KAISHA, Tokyo (JP)

(72) Inventors: HIROKAZU MIYASHITA, Miyagi (JP); JUN KAMATANI, Tokyo (JP); NAOKI YAMADA, Tokyo (JP); HIRONOBU IWAWAKI, Kanagawa (JP); YOSUKE NISHIDE, Kanagawa (JP); ISAO KAWATA, Kanagawa (JP); YUTO ITO, Tokyo (JP)

(21) Appl. No.: 18/537,618

(22) Filed: Dec. 12, 2023

Related U.S. Application Data
(63) Continuation of application No. PCT/JP2022/021244, filed on May 24, 2022.

(30) Foreign Application Priority Data
Jun. 14, 2021 (JP) 2021-098605

(51) Int. Cl. H10K 85/30; C07F 15/00; C09K 11/06

(52) U.S. Cl. CPC H10K 85/342; C07F 15/0033; C09K 11/06; C09K 2211/1029; C09K 2211/185; H10K 2101/10

(57) ABSTRACT

An organic compound represented by M(L₁)ₙ(L₂)ₘ (M represents a metal atom, n+m=3, n≥1), in which M(L₁) is represented by any one of General Formulae [1] to [3], and M(L₂) is represented by General Formulae [4] or [5], a ring A is selected from structures represented by General Formulae [6] or [7],

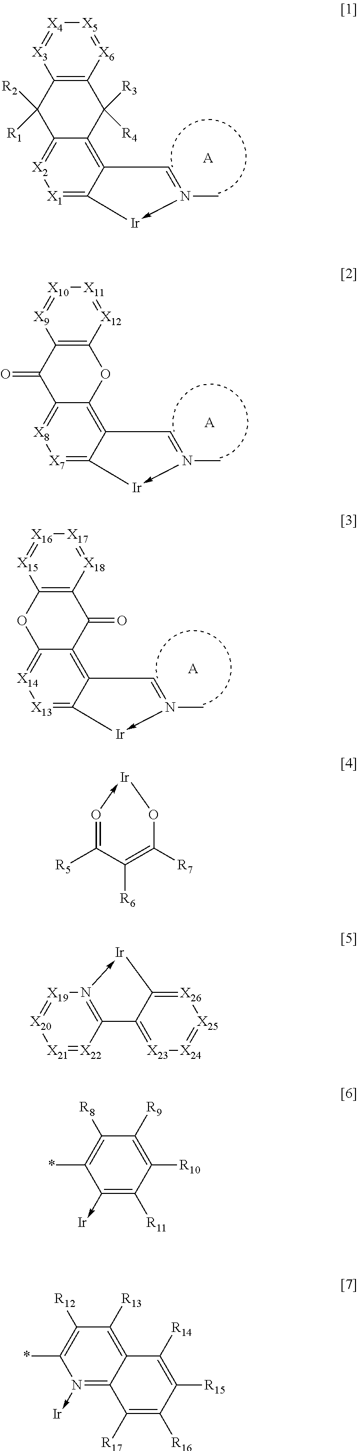

X₁ to X₂₆ each independently represent a carbon atom or a nitrogen atom, the carbon atom has a hydrogen atom, a deuterium atom, or a substituent R, the substituent R is selected from a halogen atom, an alkyl group, and the like, R₁ to R₄ represent a halogen atom or an alkyl group, and R₅ to R₁₇ represent a hydrogen atom, a deuterium atom, a halogen atom, an alkyl group, or the like.

### CROSS-REFERENCE TO RELATED APPLICATIONS

This application is a Continuation of International Patent Application No. PCT/JP2022/021244, filed May 24, 2022, which claims the benefit of Japanese Patent Application No. 2021-098605, filed Jun. 14, 2021, both of which are hereby incorporated by reference herein in their entirety.

### TECHNICAL FIELD

The present invention relates to an organic compound and an organic light emitting element formed of the organic compound.

### BACKGROUND ART

An organic light emitting element (hereinafter, also referred to as “organic electroluminescence element” or “organic EL element”) is an electron element including a pair of electrodes and an organic compound layer disposed between these electrodes. When electrons and positive holes are injected from the pair of these electrodes, excitons of a luminescent organic compound in the organic compound layer are generated, and the organic light emitting element emits light in a case where the excitons return to a ground state.

The recent progress in organic light emitting elements is remarkable, and the organic light emitting elements have characteristics such as a low drive voltage, various emission wavelengths, high-speed responsiveness, and an ability to make light emitting devices thinner and lighter.

Meanwhile, luminescent organic compounds have been actively created until now. The reason for this is that creation of compounds with excellent light emitting properties is important in providing high-performance organic light emitting elements.

PTL 1 describes the following compound 1-A as a compound that has been created so far. Further, PTL 2 describes the following compound 1-B.

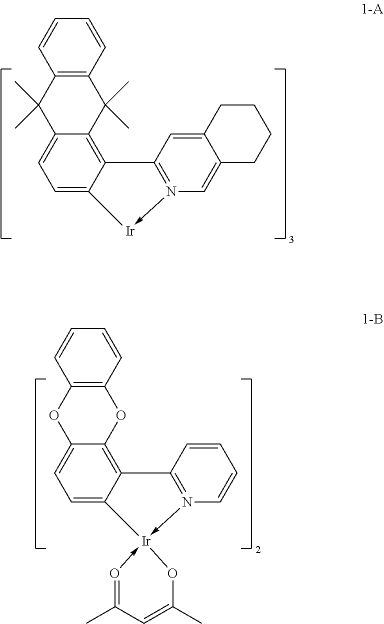

### CITATION LIST

### Patent Literature

PTL 1 Japanese Patent Laid-Open No. 2007-269734
PTL 2 United States Patent Application Publication No. 2019/0296251

As a result of investigation conducted by the present inventors, the compound 1-A is a material that has room for further improvement in light emitting properties and stability of the compound as described below. As a result of investigation conducted by the present inventors, the compound 1-B is a material that has room for further improvement in stability of the compound as described below.

The compound 1-A has room for further improvement in light emitting properties and chemical stability of the compound. An organic light emitting element with higher emission efficiency can be provided by improving the light emitting properties of the compound. Further, an organic light emitting element with more excellent durability can be provided by improving stability of the compound. The compound 1-B has low oxidation stability of the compound. An organic light emitting element with excellent durability can be provided by improving the oxidation stability.

### SUMMARY OF INVENTION

That is, an object of the present invention is to provide an organic compound with excellent light emitting properties and excellent stability of the compound. Further, another object of the present invention is to provide an organic light emitting element with excellent light emitting properties and excellent driving durability.

According to the present invention, there is provided an organic compound represented by M(L₁)ₙ(L₂)ₘ (M represents a metal atom, n+m=3, n≥1), in which M(L₁) is represented by any one of General Formulae [1] to [3], and M(L₂) is represented by General Formulae [4] or [5].

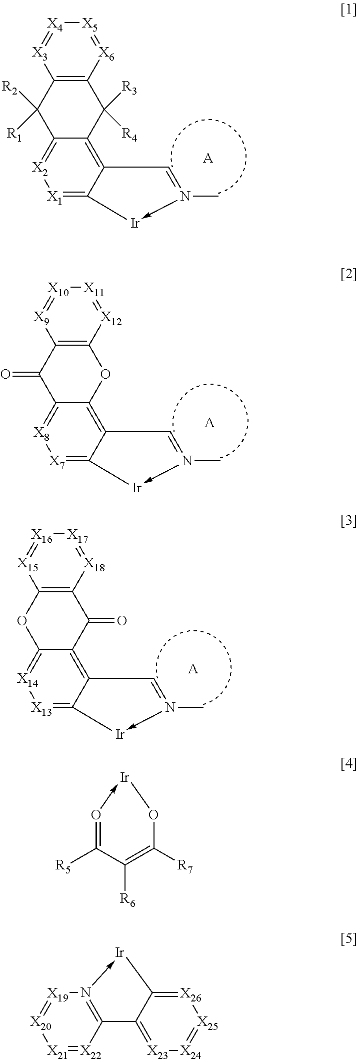

In General Formulae [1] to [3], a ring A is selected from structures represented by General Formulae [6] or [7].

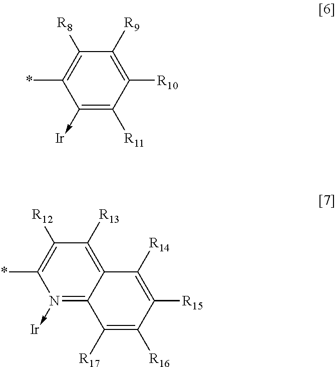

(* represents a bonding position.)

In General Formulae [1] to [3] and [5], X₁ to X₂₆ each independently represent a carbon atom or a nitrogen atom, the carbon atom has a hydrogen atom, a deuterium atom, or a substituent R, the substituent R is selected from a halogen atom, a substituted or unsubstituted alkyl group, a substituted or unsubstituted alkoxy group, a substituted or unsubstituted amino group, a substituted or unsubstituted aryloxy group, a substituted or unsubstituted heteroaryloxy group, a substituted or unsubstituted silyl group, a cyano group, a trifluoromethyl group, a substituted or unsubstituted aromatic hydrocarbon group, and a substituted or unsubstituted heterocyclic group.

In General Formula [1], R₁ to R₄ each independently represent a halogen atom or a substituted or unsubstituted alkyl group.

In General Formulae [4], [6], and [7], R₅ to R₁₇ each independently represent a hydrogen atom, a deuterium atom, a halogen atom, a substituted or unsubstituted alkyl group, a substituted or unsubstituted alkoxy group, a substituted or unsubstituted amino group, a substituted or unsubstituted aryloxy group, a substituted or unsubstituted heteroaryloxy group, a substituted or unsubstituted silyl group, a cyano group, a trifluoromethyl group, a substituted or unsubstituted aromatic hydrocarbon group, or a substituted or unsubstituted heterocyclic group.

Further features of the present invention will become apparent from the following description of exemplary embodiments with reference to the attached drawings.

### BRIEF DESCRIPTION OF DRAWINGS

FIG. 1 is a view showing planarity of an organic compound according to the present invention.

FIG. 2A is a schematic cross-sectional view showing an example of pixels of a display device according to an embodiment of the present invention.

FIG. 2B is a schematic cross-sectional view showing an example of a display device formed of an organic light emitting element according to an embodiment of the present invention.

FIG. 3 is a schematic view showing an example of a display device according to an embodiment of the present invention.

FIG. 4A is a schematic view showing an example of an imaging device according to an embodiment of the present invention.

FIG. 4B is a schematic view showing an example of an electronic device according to an embodiment of the present invention.

FIG. 5A is a schematic view showing an example of a display device according to an embodiment of the present invention.

FIG. 5B is a schematic view showing an example of a foldable display device.

FIG. 6A is a schematic view showing an example of a lighting device according to an embodiment of the present invention.

FIG. 6B is a schematic view showing an example of a moving body that includes a lamp for a vehicle according to an embodiment of the present invention.

FIG. 7A is a schematic view showing an example of a wearable device according to an embodiment of the present invention.

FIG. 7B is a schematic view showing another example of a wearable device according to an embodiment of the present invention.

FIG. 8A is a schematic view showing an example of an image forming apparatus according to an embodiment of the present invention. FIG. 8B is a schematic view showing an example of an exposure light source of the image forming apparatus according to an embodiment of the present invention.

### DESCRIPTION OF EMBODIMENTS

### <<Organic Compound (Organometallic Complex)>>

First, an organic compound according to the present embodiment will be described. The organic compound according to the present embodiment is an organic compound represented by M(L₁)ₙ(L₂)ₘ (M represents a metal atom, n+m=3, n≥1), which is an organometallic complex in which M(L₁) is represented by General Formulae [1] to [3], and M(L₂) is represented by General Formulae [4] and [5].

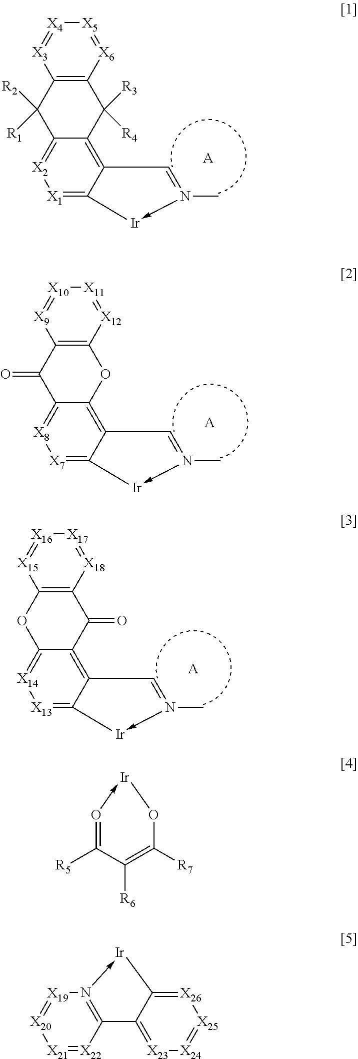

In General Formulae [1] to [3], a ring A is selected from structures represented by General Formulae [6] and [7].

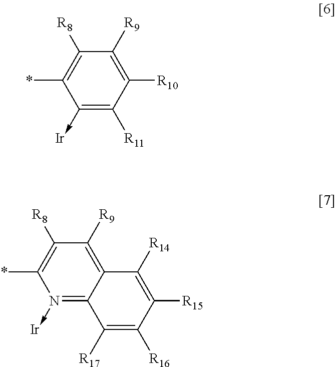

(* represents a bonding position)

<X₁ to X₂₆>

In General Formulae [1] to [3] and [5], X₁ to X₂₆ each independently represent a carbon atom or a nitrogen atom. The carbon atom has a hydrogen atom, a deuterium atom, or a substituent R, and the substituent R is selected from a halogen atom, a substituted or unsubstituted alkyl group, a substituted or unsubstituted alkoxy group, a substituted or unsubstituted amino group, a substituted or unsubstituted aryloxy group, a substituted or unsubstituted heteroaryloxy group, a substituted or unsubstituted silyl group, a cyano group, a trifluoromethyl group, a substituted or unsubstituted aromatic hydrocarbon group, and a substituted or unsubstituted heterocyclic group.

### [Substituent R]

Examples of the halogen atom include fluorine, chlorine, bromine, and iodine, but are not limited thereto.

Examples of the alkyl group include a methyl group, an ethyl group, a normal propyl group, an isopropyl group, a normal butyl group, a tertiary butyl group, a secondary butyl group, an octyl group, a cyclohexyl group, a 1-adamantyl group, and a 2-adamantyl group, but are not limited thereto. An alkyl group having 1 or more and 10 or less carbon atoms is preferable as the alkyl group. The hydrogen atoms of the alkyl group may be deuterium atoms. Adjacent alkyl groups, for example, adjacent alkyl groups represented by X₃ to X₆, X₉ to X₁₂, and X₁₅ to X₁₈ may be bonded to each other to form an aromatic ring such as a benzene ring.

Examples of the alkoxy group include a methoxy group, an ethoxy group, a propoxy group, a 2-ethyl-octyloxy group, and a benzyloxy group, but are not limited thereto. An alkoxy group having 1 or more and 10 or less carbon atoms is preferable as the alkoxy group.

Examples of the amino group include a N-methylamino group, a N-ethylamino group, a N,N-dimethylamino group, a N,N-diethylamino group, a N-methyl-N-ethylamino group, a N-benzylamino group, a N-methyl-N-benzylamino group, a N,N-dibenzylamino group, an anilino group, a N,N-diphenylamino group, a N,N-dinaphthylamino group, a N,N-difluorenylamino group, a N-phenyl-N-tolylamino group, a N,N-ditolylamino group, a N-methyl-N-phenylamino group, a N,N-dianisolylamino group, a N-mesityl-N-phenylamino group, a N,N-dimethylamino group, a N-phenyl-N-(4-tert-butylphenyl)amino group, a N-phenyl-N-(4-trifluoromethylphenyl)amino group, and a N-piperidyl group, but are not limited thereto. An amino group having 1 or more and 6 or less carbon atoms is preferable as the amino group.

Examples of the aryloxy group include a phenoxy group and a naphthoxy group, but are not limited thereto.

Examples of the heteroaryloxy group include a furanyloxy group and a thienyloxy group, but are not limited thereto.

Examples of the silyl group include a trimethylsilyl group and a triphenylsilyl group, but are not limited thereto.

Examples of the aromatic hydrocarbon group include a phenyl group, a naphthyl group, an indenyl group, a biphenyl group, a terphenyl group, a fluorenyl group, a phenanthryl group, a fluoranthenyl group, and a triphenylenyl group, but are not limited thereto. An aromatic hydrocarbon group having 6 or more and 30 or less carbon atoms is preferable as the aromatic hydrocarbon group.

Examples of the heterocyclic group include a pyridyl group, an oxazolyl group, an oxadiazolyl group, a thiazolyl group, a thiadiazolyl group, a carbazolyl group, an acridinyl group, a phenanthrolyl group, a dibenzofuranyl group, and a dibenzothiophenyl group, but are not limited thereto. A heterocyclic group having 3 or more and 27 or less carbon atoms is preferable as the heterocyclic group.

Examples of the substituent that the alkyl group, the alkoxy group, the amino group, the aryloxy group, the heteroaryloxy group, the silyl group, the aromatic hydrocarbon group, and the heterocyclic group may further have include a halogen atom such as fluorine, chlorine, bromine, or iodine, an alkyl group such as a methyl group, an ethyl group, a normal propyl group, an isopropyl group, a normal butyl group, or a tertiary butyl group, an alkoxy group such as a methoxy group, an ethoxy group, or a propoxy group, an amino group such as a dimethylamino group, a diethylamino group, a dibenzylamino group, a diphenylamino group, or a ditolylamino group, an aryloxy group such as a phenoxy group, an aromatic hydrocarbon group such as a phenyl group or a biphenyl group, a heterocyclic group such as a pyridyl group or a pyrrolyl group, and a cyano group, but are not limited thereto.

<R₁ to R₄>

In General Formula [1], R₁ to R₄ each independently represent a halogen atom or a substituted or unsubstituted alkyl group.

Specific examples of the halogen atom and the alkyl group represented by R₁ to R₄ include those described in the section of X₁ to X₂₆, but are not limited thereto. An alkyl group having 1 or more and 10 or less carbon atoms is preferable as the alkyl group. The hydrogen atoms of the alkyl group may be deuterium atoms. Further, specific examples of the substituent that the alkyl group may further have include those described in the section of X₁ to X₂₆, but are not limited thereto.

It is preferable that R₁ to R₄ represent any of a methyl group, an ethyl group, or an isopropyl group.

<R₅ to R₁₇>

In General Formulae [4], [6], and [7], R₅ to R₁₇ each independently represent a hydrogen atom, a deuterium atom, a halogen atom, a substituted or unsubstituted alkyl group, a substituted or unsubstituted alkoxy group, a substituted or unsubstituted amino group, a substituted or unsubstituted aryloxy group, a substituted or unsubstituted heteroaryloxy group, a substituted or unsubstituted silyl group, a cyano group, a trifluoromethyl group, a substituted or unsubstituted aromatic hydrocarbon group, or a substituted or unsubstituted heterocyclic group.

Specific examples of the halogen atom, the alkyl group, the alkoxy group, the amino group, the aryloxy group, the heteroaryloxy group, the silyl group, the aromatic hydrocarbon group, and the heterocyclic group represented by R₅ to R₁₇ include those described in the section of X₁ to X₂₆, but are not limited thereto. An alkyl group having 1 or more and 10 or less carbon atoms is preferable as the alkyl group. An alkoxy group having 1 or more and 10 or less carbon atoms is preferable as the alkoxy group. An amino group having 1 or more and 6 or less carbon atoms is preferable as the amino group. An aromatic hydrocarbon group having 6 or more and 30 or less carbon atoms is preferable as the aromatic hydrocarbon group. A heterocyclic group having 3 or more and 27 or less carbon atoms is preferable as the heterocyclic group. Further, specific examples of the substituent that the alkyl group, the alkoxy group, the amino group, the aryloxy group, the heteroaryloxy group, the silyl group, the aromatic hydrocarbon group, and the heterocyclic group may further have include those described in the section of X₁ to X₂₆, but are not limited thereto.

It is preferable that R₅ to R₁₇ represent any of a hydrogen atom, a deuterium atom, a tertiary butyl group, or a phenyl group. Further, it is preferable that R₈ and R₁₂ represent a hydrogen atom. The reason for this is that a structure that is easy to coordinate with an Ir metal is formed due to a decrease in the dihedral angle between a tetrahydroanthracene skeleton or a xanthone skeleton and the ring A in this case. In this manner, a more stable compound is obtained as an Ir complex.

<n and m>

“n+m=3” and “n≥1” are satisfied. It is preferable that n represent an integer of 1 or greater and 3 or less and m represent an integer of 0 or greater and 2 or less. Further, it is preferable that “n=1” be satisfied. The reason for this is that L₁ has a structure with high planarity and thus the compound is likely to undergo molecular association. In addition, when “n=1” is satisfied, the molecular weight can be reduced, the element can be prepared by sublimation purification or vacuum deposition at a lower temperature.

Next, a method of synthesizing the organic compound according to the present embodiment will be described. The organic compound according to the present embodiment is, for example, synthesized by the following reaction scheme.

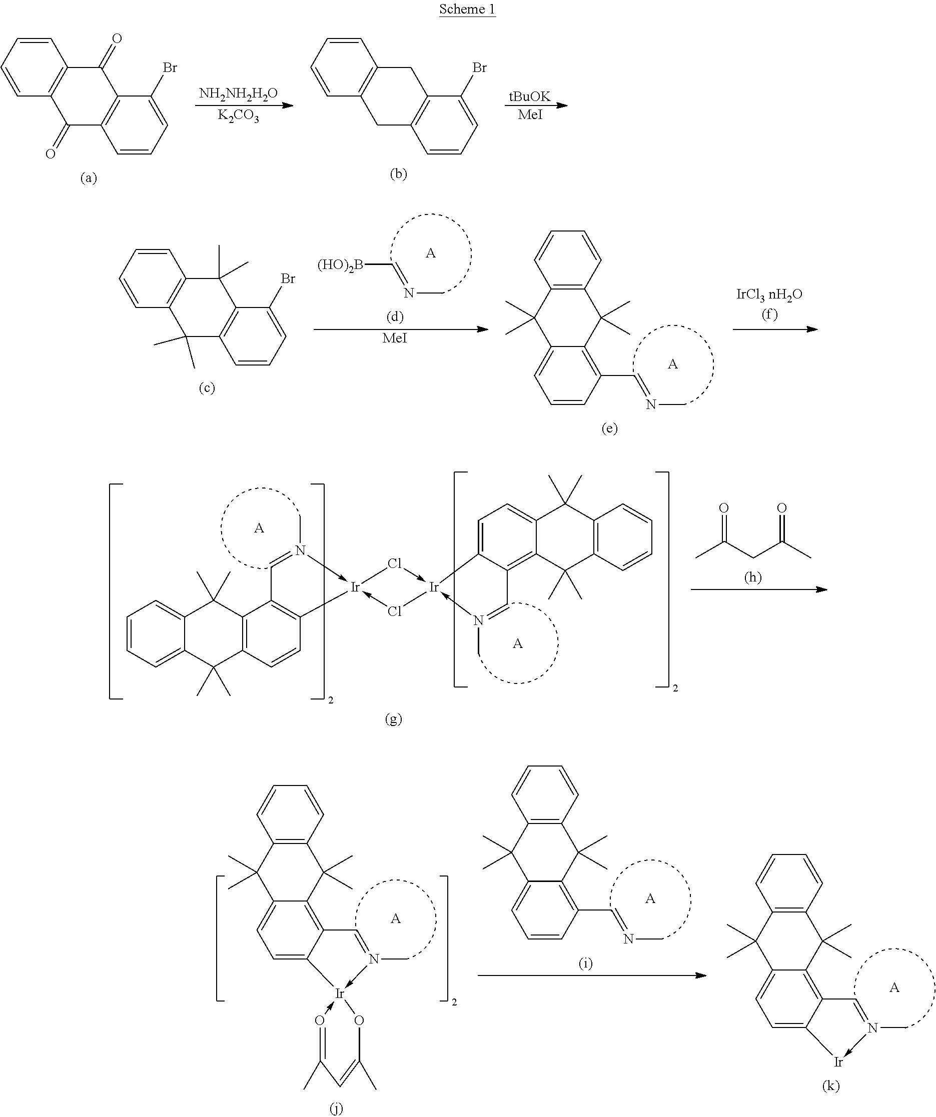

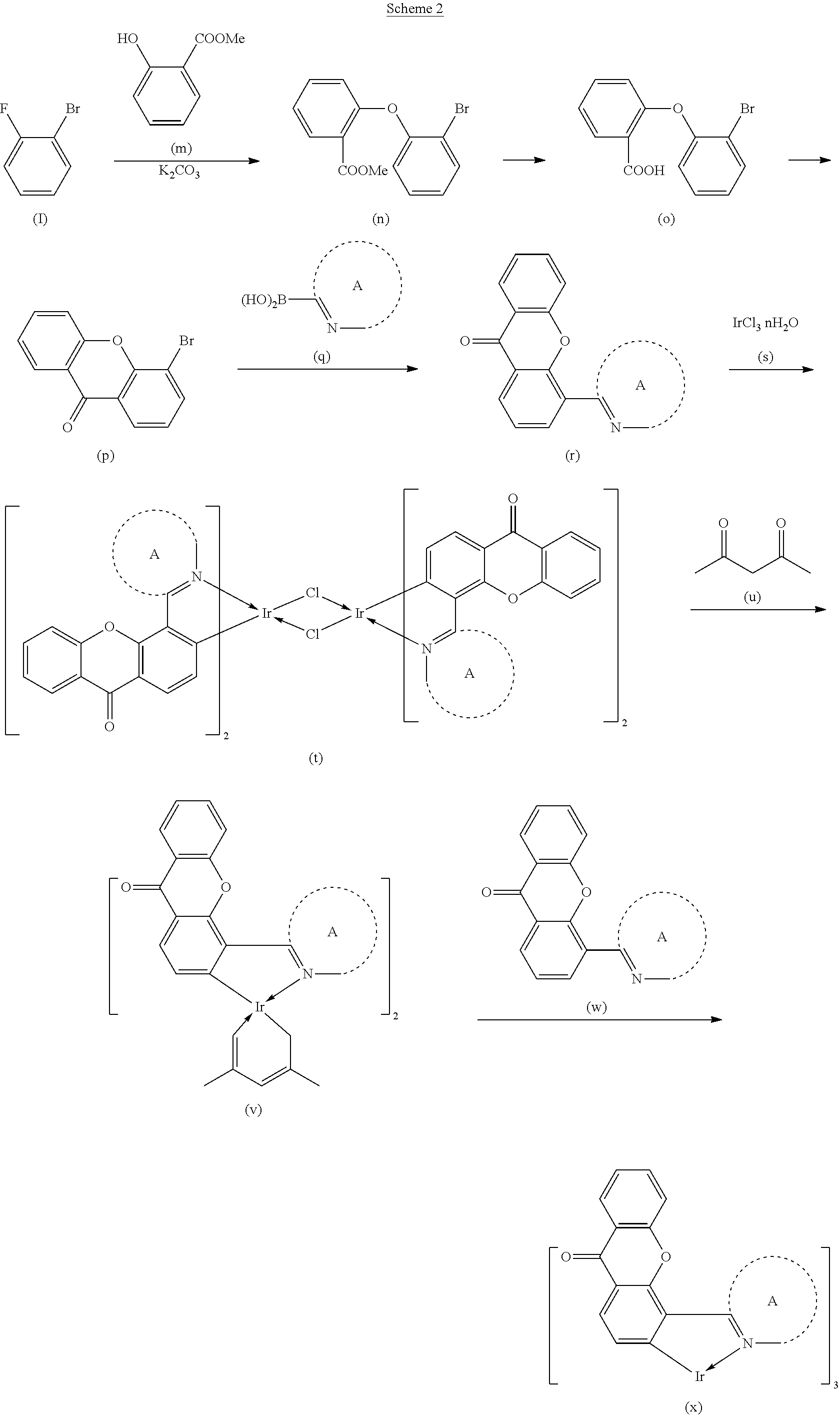

Here, various compounds can be obtained by appropriately changing compounds represented by Formulae (a) to (k) and (l) to (x). The method of synthesizing the organic compound according to the present embodiment is not limited to the synthesis schemes shown above, and various synthesis schemes and reagents can be used. Further, the synthesis method will be described in detail in examples.

Next, since the organic compound according to the present embodiment has the following characteristics, a compound with a high quantum yield and excellent chemical stability of the compound is formed, and an organic light emitting element with excellent emission efficiency and excellent element durability can also be provided by using this organic compound.

(1) Since the ring A does not have an aliphatic ring fused with the ring, the quantum yield is high.

(2) Since the ring A does not have an aliphatic ring fused with the ring and having a site corresponding to a benzylic position, the stability of the compound is high.

(3) Since the ring A does not have an aliphatic ring fused with the ring, the symmetry of the Ir complex is improved, and a stable complex is formed.

(4) An Ir complex with high oxidation stability is formed by reducing electron donating properties of a ligand L₁.

Hereinafter, these characteristics will be described using a comparative compound 1-A or 1-B for comparison and contrast. Further, the comparative compound 1-A is the compound 1-A described in PTL 1, and the comparative compound 1-B is the compound 1-B described in PTL 2.

(1) Since the ring A does not have an aliphatic ring fused with the ring, the quantum yield is high.

The present inventors have focused on the structure of the ligand of the organometallic complex when inventing the organometallic complex of the present invention. Specifically, an attempt has been made to improve the quantum yield by forming a structure in which the aromatic ring and the heterocyclic ring of the ring A constituting a ligand have fewer conformers.

Here, the results of comparing the light emitting properties of an exemplary compound A33 and a comparative compound 1-A are listed in Table 1. In addition, the emission wavelength is measured by photoluminescence (PL) measurement of a diluted toluene solution at an excitation wavelength of 350 nm at room temperature using F-4500 (manufactured by Hitachi, Ltd.). Further, the quantum yield is measured by measuring an absolute quantum yield in the diluted toluene solution using an absolute PL quantum yield measuring device (C9920-02) (manufactured by Hamamatsu Photonics K.K.). The quantum yield is expressed as an absolute value obtained by setting the quantum yield of the exemplary compound A33 to 1.0.

TABLE 1

| Compound | Structure | λmax | Quantum yield |
|---|---|---|---|
| Exemplary compound A33 | 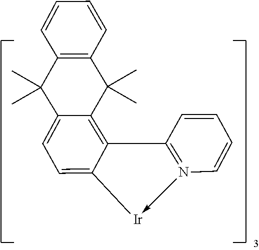 | 535 | 1.0 |
| Comparative compound 1-A | 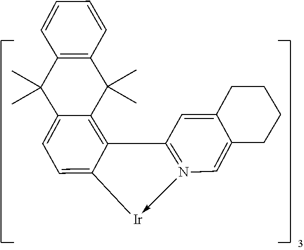 | 524 | 0.9 |

As listed in Table 1, it can be seen that the exemplary compound A33 has a higher quantum yield and more excellent light emitting properties than those of the comparative compound 1-A. The reason for this is considered as follows.

A difference between the structures of both compounds is that the exemplary compound A33 has a structure in which the aliphatic ring is not fused to a pyridine ring (ring A) while the comparative compound 1-A has a structure in which cyclohexane is fused to a pyridine ring.

Here, the cyclohexane is known to have a plurality of steric conformations as shown below. The structures of such steric conformations mutually change due to the energy of heat or the like to form conformers.

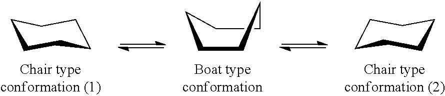

The comparative compound 1-A has a structure in which cyclohexane is fused onto a pyridine ring. Therefore, a conformer is formed. It is considered that since the excitation energy in the comparative compound 1-A is converted to thermal energy due to the structural change of a cyclohexane moiety in an excited state, the quantum yield is decreased. Further, it is considered that the decrease in quantum yield is caused by the plurality of conformers in the cyclohexane moiety, a plurality of excited levels as the excited state, and an increase in excited lifetime.

Meanwhile, it is considered that since the cyclohexane structure having a plurality of steric conformations in the exemplary compound A33 is not in the form of being fused to a ring in the skeleton of the ring A constituting the ligand, the structural change in the excited state is small, the compound rapidly reaches a light emitting process, and thus the quantum yield is high.

(2) Since the ring A does not have an aliphatic ring fused with the ring and having a site corresponding to a benzylic position, the stability of the compound is high.

The present inventors have focused on the strength of the bond in the structure of the ligand of the organometallic complex when inventing the organometallic complex of the present invention. Specifically, an attempt has been made to perform molecular design such that carbon-hydrogen bonds of the ring A constituting the ligand do not include bonds with small bond dissociation energy.

Here, the bond dissociation energies of the carbon-hydrogen bonds described in ACC. Chem. Res. 36, pp. 255 to 263, (2003) are listed in Table 2.

TABLE 2

| | | Bond dissociation energy |
|---|---|---|
| | Bond | (kcal/mol) |
| Methyl group | 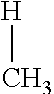 | 105 |
| Ethyl group | 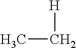 | 101 |
| Phenyl group | 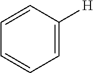 | 113 |
| Benzyl group | 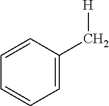 | 90 |

The bond is stronger as the numerical value of the bond dissociation energy increases, and the bond is weaker as the numerical value thereof decreases. That is, it can be seen that the carbon-hydrogen bond at the benzylic position of a benzyl group is a weak bond. The reason for this is that when the hydrogen atom at the benzylic position is desorbed to form a radical, the radical is stabilized by the resonance of the radical with n electrons of the benzene ring adjacent thereto. Therefore, the carbon-hydrogen bond at the benzylic position is a weak bond. That is, when the compound has a structure such as a benzyl group in the molecular structure, the bond of the carbon-hydrogen bond in the compound is likely to be cut, which is not preferable.

Here, the results of comparing the structures of the exemplary compound A33 and the comparative compound 1-A from the viewpoint of the carbon-hydrogen bond are listed in Table 3.

TABLE 3

| Compound | Structure |
|---|---|
| Exemplary compound A33 | 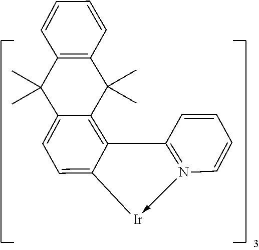 |
| Comparative compound 1-A | 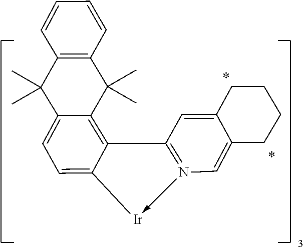 |

As listed in Table 3, the comparative compound 1-A is a compound in which radicals with a cut carbon-hydrogen bond are easily generated because the aliphatic ring fused with the pyridine ring has two sites (the sites of * in the table) corresponding to the benzylic position where the bond is weak. In the organic light emitting element, oxidation reduction is repeatedly carried out when the element is driven, and radicals are likely to be generated in molecules forming the element due to the presence of molecules with high energy in an excited state, which is not preferable. The reason for this is that material deterioration such as decomposition of the compound accompanied by the radical reaction is caused.

Meanwhile, the ring A in the exemplary compound A33 does not have an aliphatic ring fused with the ring and having a site corresponding to a benzylic position with a weak bond. Therefore, the compound can be said to be a compound with more excellent stability.

(3) Since the ring A does not have an aliphatic ring fused with the ring, the symmetry of the Ir complex is improved, and a stable complex is formed.

The present inventors have focused on the steric conformation of the organometallic complex when inventing the organometallic complex of the present invention. The Ir complex is known to have a complex structure of a regular octahedron.

Here, the results of comparing the complex structures of the exemplary compound A33 and the comparative compound 1-A are listed in Table 4. In addition, the complex structure is expressed by drawing one ligand for simplicity. In Table 4, C—N represents the same bidentate ligand.

TABLE 4

| | | |
|---|---|---|
| Compound | Structure | Complex structure |

| | | |
|---|---|---|
| Exemplary compound A33 | 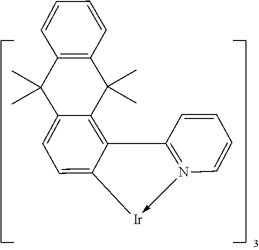 | 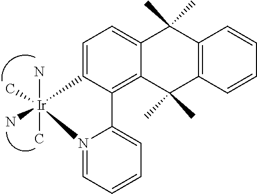 |
| Comparative compound 1-A | 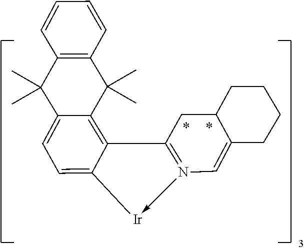 | 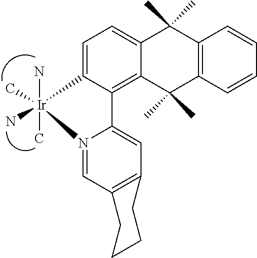 |
| | | 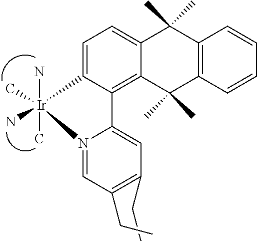 |
| | | 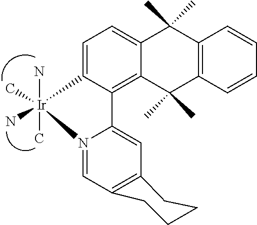 |

As described in the characteristic (1) above, the comparative compound 1-A has a structure in which cyclohexane having a plurality of steric conformations is fused with the pyridine ring. Therefore, in consideration of the complex structure, a plurality of complex structures can be formed by the conformation of the cyclohexane. That is, the symmetry of the complex structure is reduced by the steric conformer. The low symmetry of the compound leads to a decrease in melting point. As described in the characteristic (2) above, since the comparative compound 1-A is a compound in which radicals are likely to be generated, the reaction or decomposition derived from the radicals may be caused when the temperature of the compound is higher than the melting point. The reaction or decomposition is disadvantageous for preparation of the element by performing sublimation purification or vacuum deposition that makes the material to have a high temperature.

From a different viewpoint, it can be said that in a case where the compound has a plurality of complex structures, decomposition is likely to occur when the compound has a thermally unstable structure, which is not preferable.

Therefore, the exemplary compound A33 which has higher symmetry in the complex structure of the Ir complex and does not have a plurality of complex structures can be expected to have higher stability than that of the comparative compound 1-A.

(4) An Ir complex with high oxidation stability is formed by reducing electron donating properties of a ligand L1.

The present inventors have focused on the resonance structure of the ligand of the organometallic complex when inventing the organometallic complex of the present invention. Specifically, an attempt has been made to perform molecular design such that the Ir complex is not destabilized due to the resonance structure formed by the lone electron pair of the oxygen atom constituting the ligand L₁.

For example, phenol employs a resonance structure formed by a lone electron pair of an oxygen atom of a hydroxy group as shown below. That is, it can be seen that since the lone electron pair of the oxygen atom flows onto the benzene ring, the negative charge is distributed at the para position and the ortho position with respect to the position of the oxygen atom.

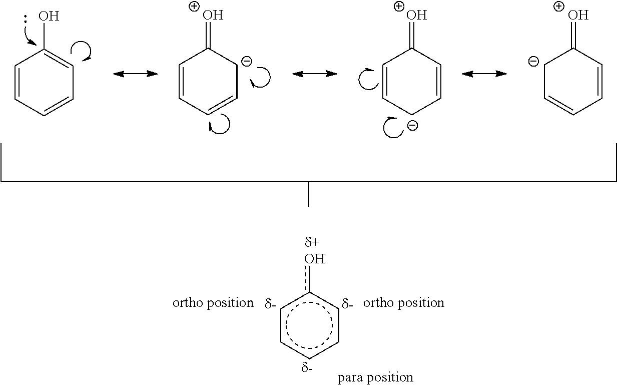

Here, the results of comparing the structures of the exemplary compound A33, the exemplary compound B1, and the comparative compound 1-B from the viewpoint of the oxygen atom are listed in Table 5.

TABLE 5

| Compound | Structure |
|---|---|
| Exemplary compound A33 | 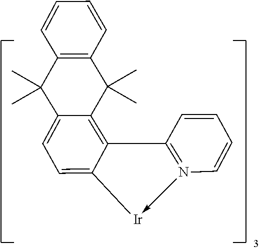 |
| Exemplary compound B1 | 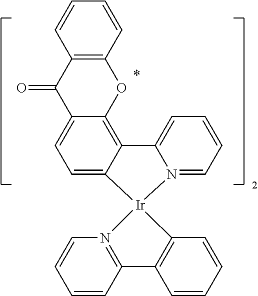 |
| Comparative compound 1-B | 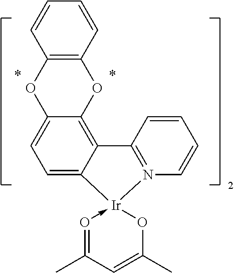 |

The exemplary compound A33 does not have an oxygen atom while the comparative compound 1-B has oxygen atoms (sites of * in the table). Therefore, the electron donating properties to the phenyl group bonded to the Ir metal are enhanced. Particularly, it is considered that the effect of the electron donating properties of the oxygen atom positioned at the para position increases with respect to the Ir metal. The enhancement of the electron donating properties leads to an effect of making the HOMO shallow (making the HOMO close to a vacuum level). In other words, the compound is formed into a material that is easily oxidized. That is, the comparative compound 1-B has low oxidation stability.

Here, the exemplary compound B1 has an oxygen atom, but the electron donating properties to the phenyl group bonded to the Ir metal can be reduced by introducing a ketone group which is an electron withdrawing substituent. As a result, the exemplary compound B1 is formed into a material with high oxidation stability.

In addition, evaluation of the stability of the compounds described in the characteristics (2) to (4) of the organometallic complex according to the present invention will be described in more detail in the examples described below.

Specific examples of the organic compound according to the present invention will be described below. However, the present invention is not limited thereto. Further, in the exemplary compounds shown below, coordinate bonds indicated by the arrows in General Formulae [1] to [7] are shown by dotted lines.

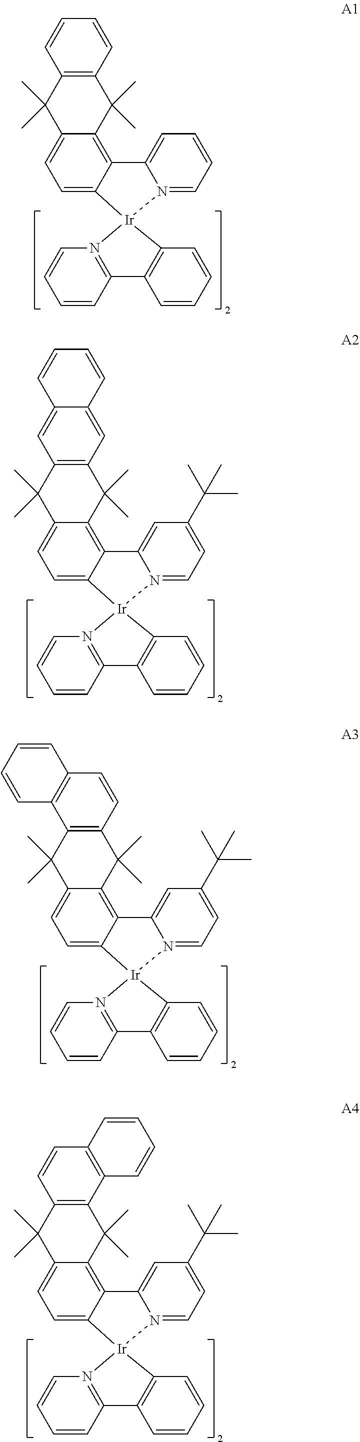

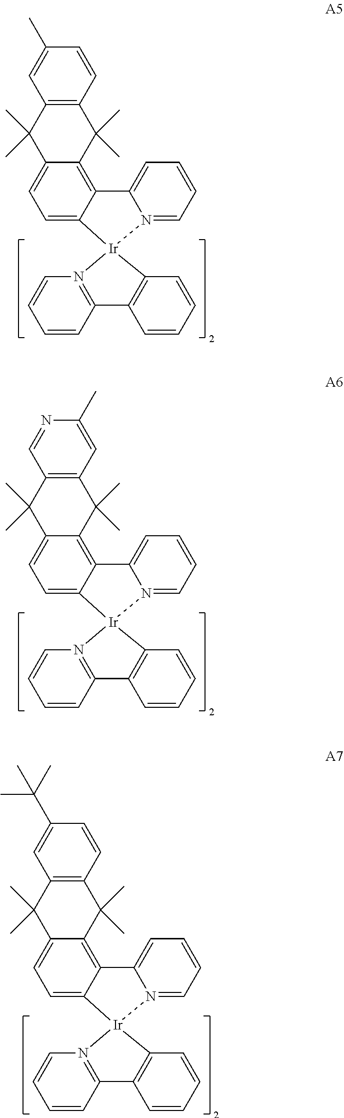

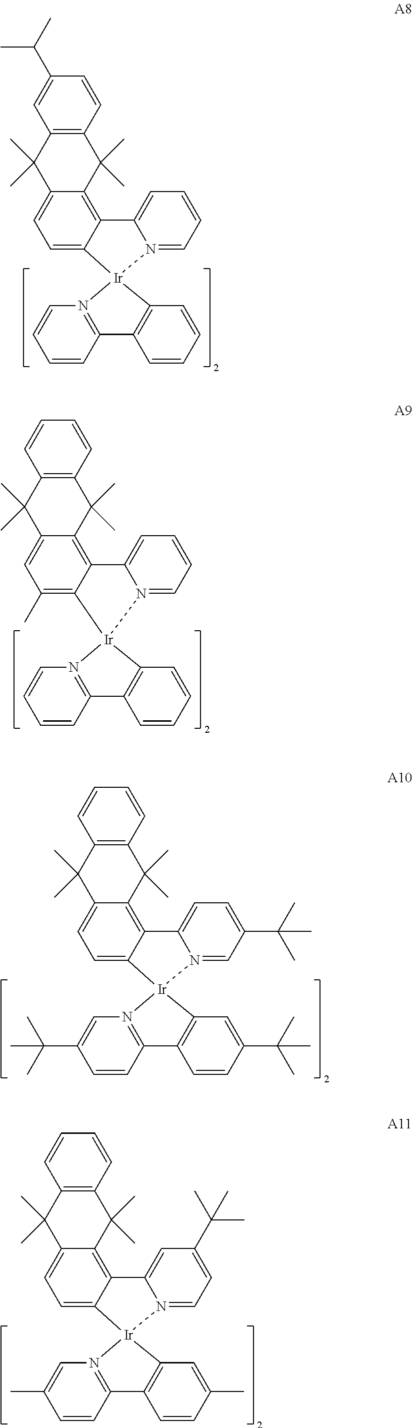

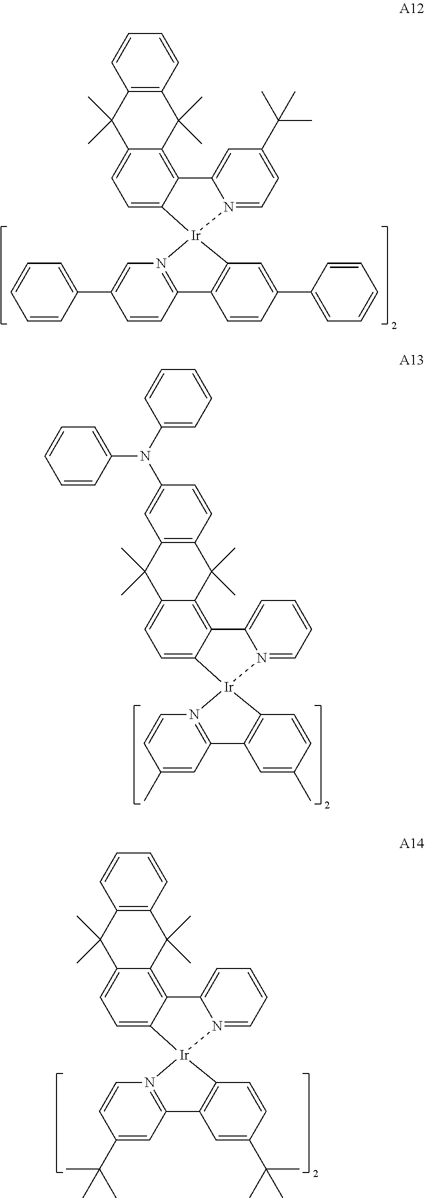

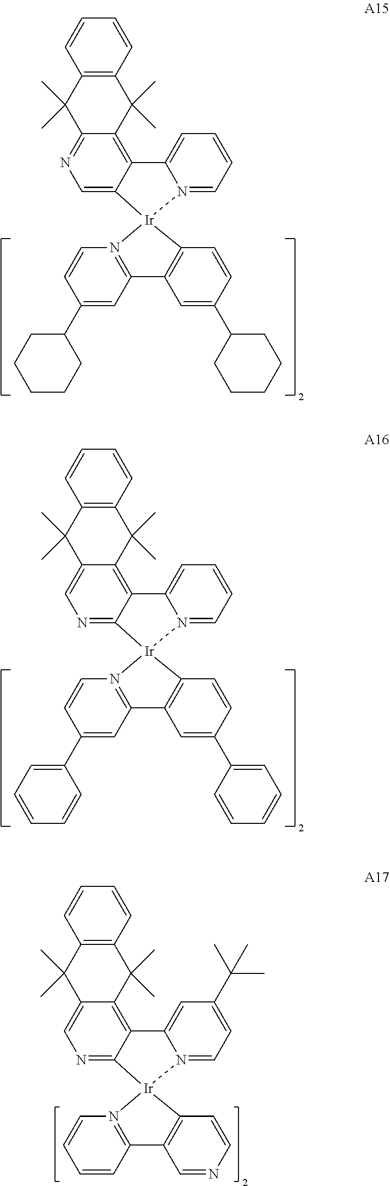

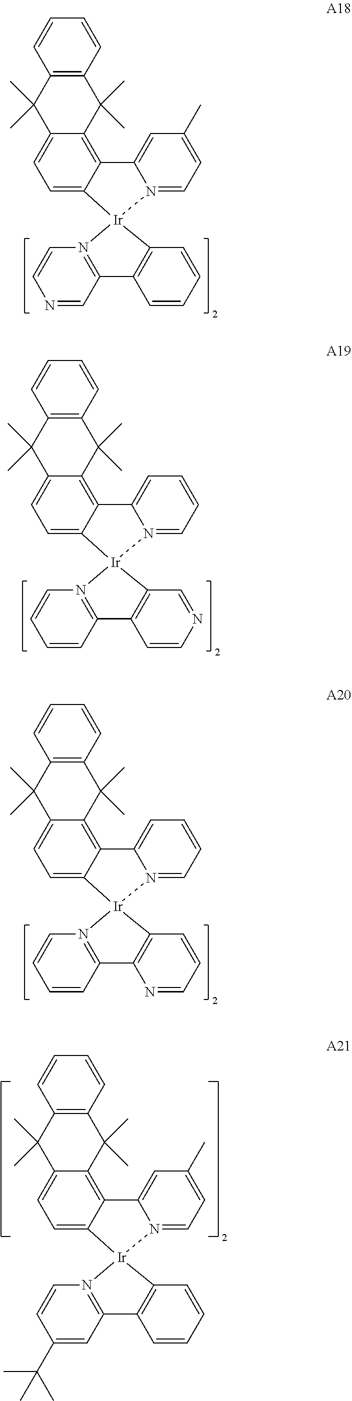

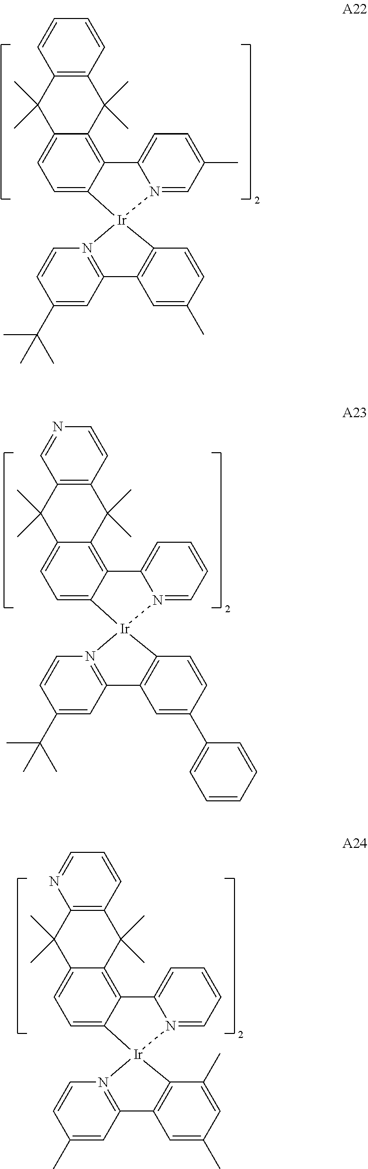

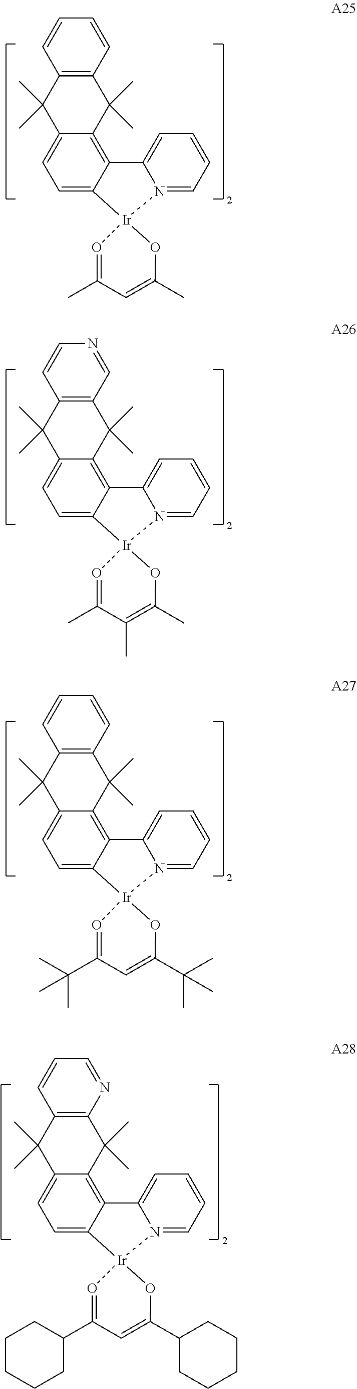

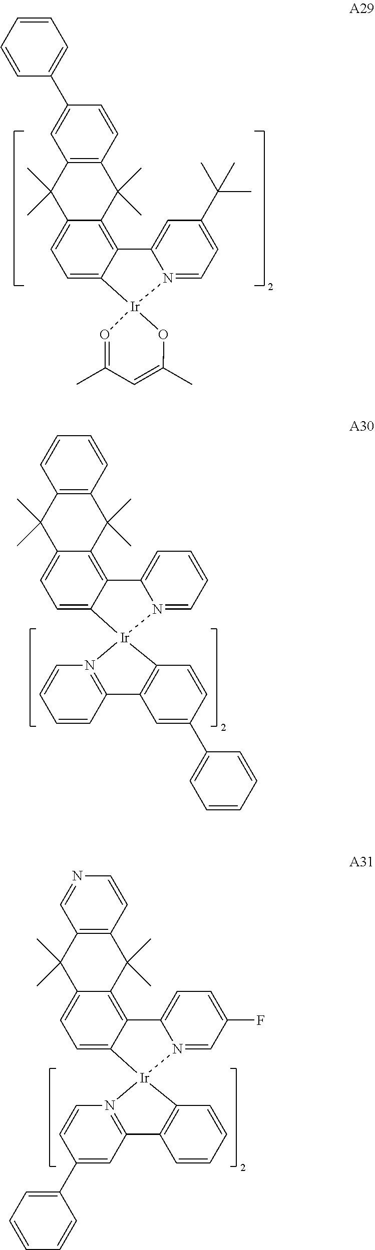

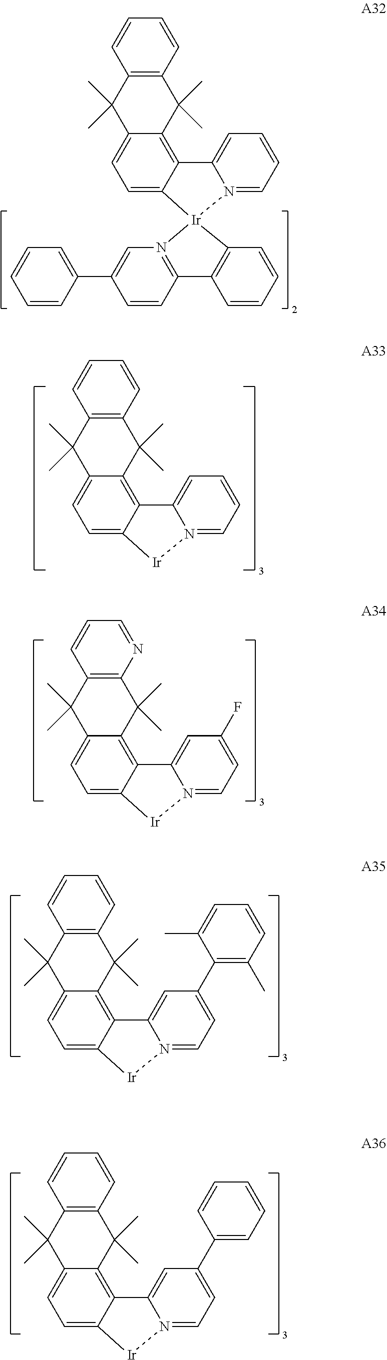

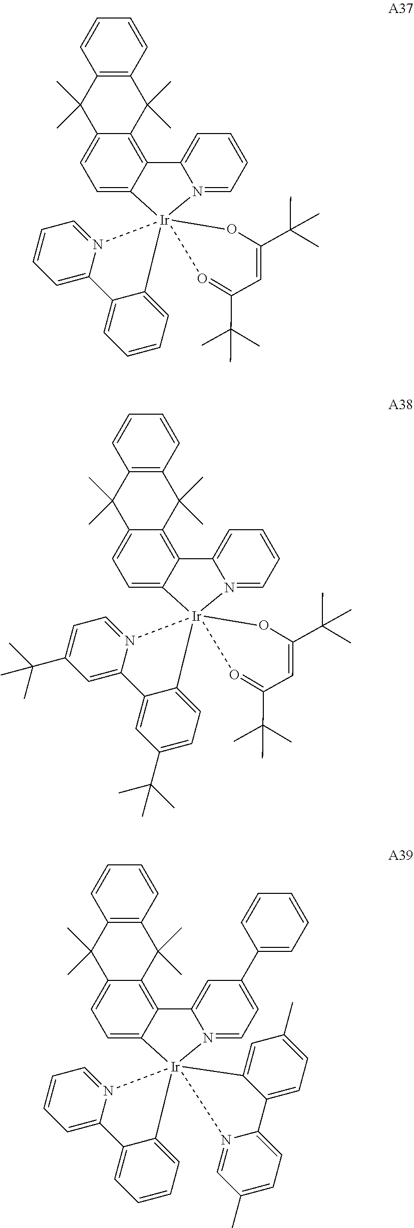

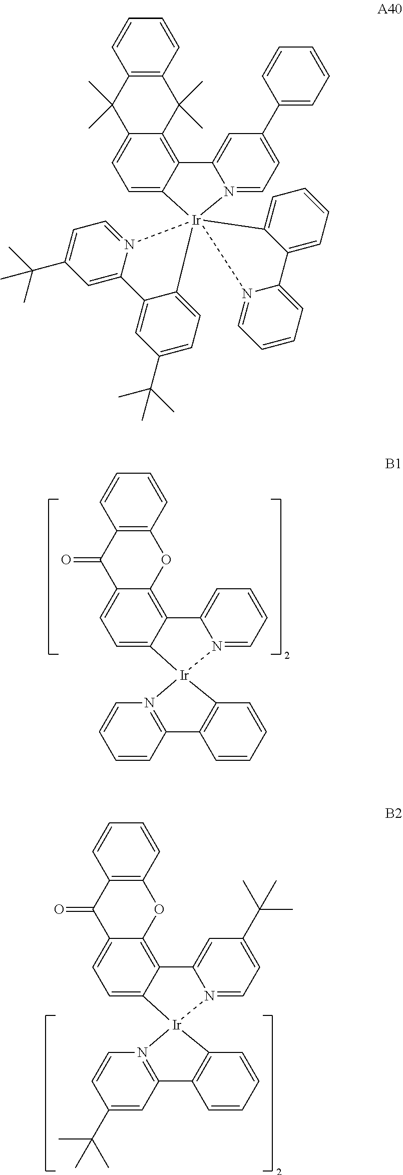

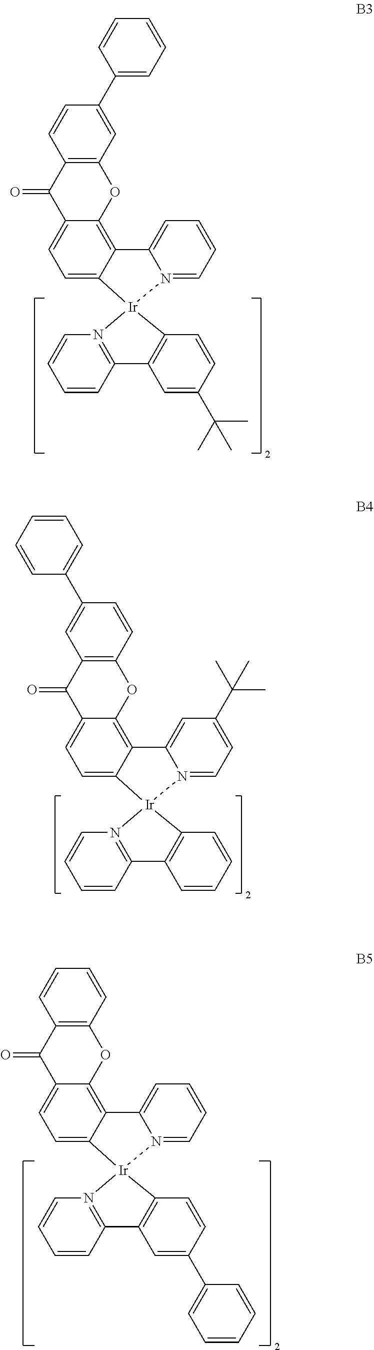

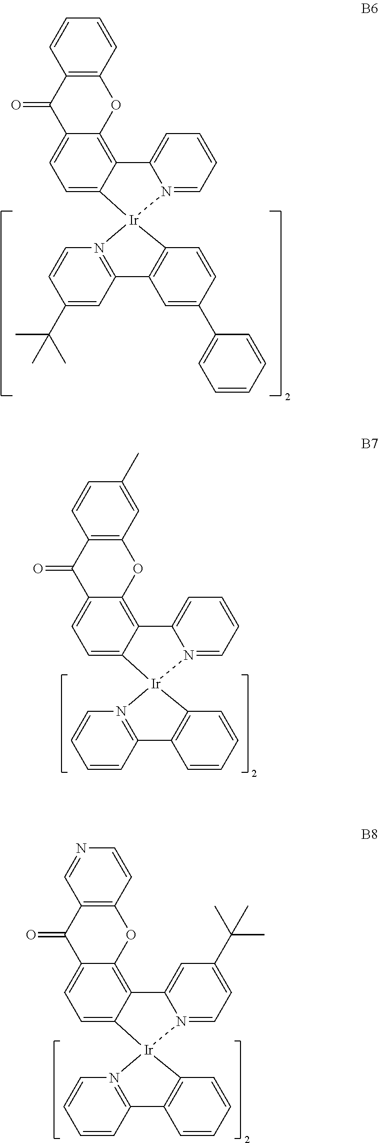

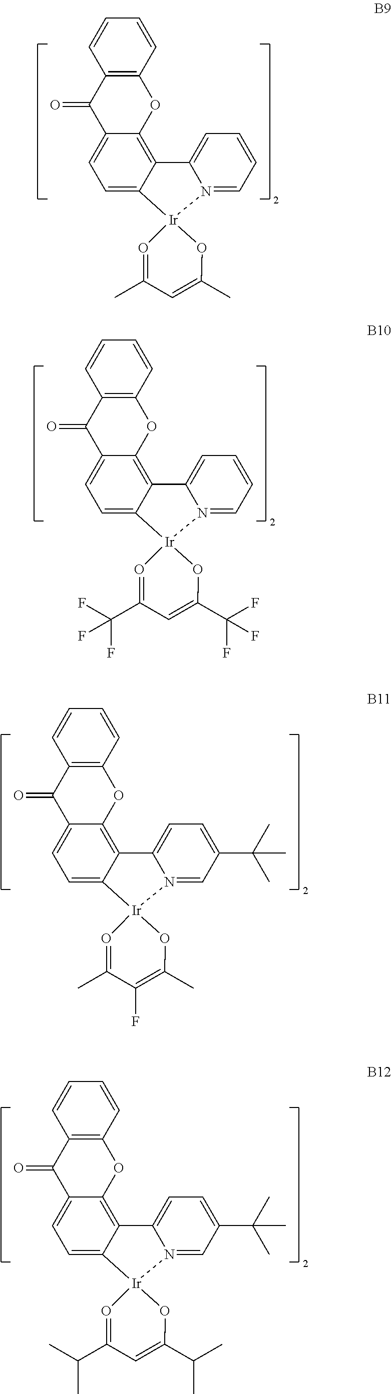

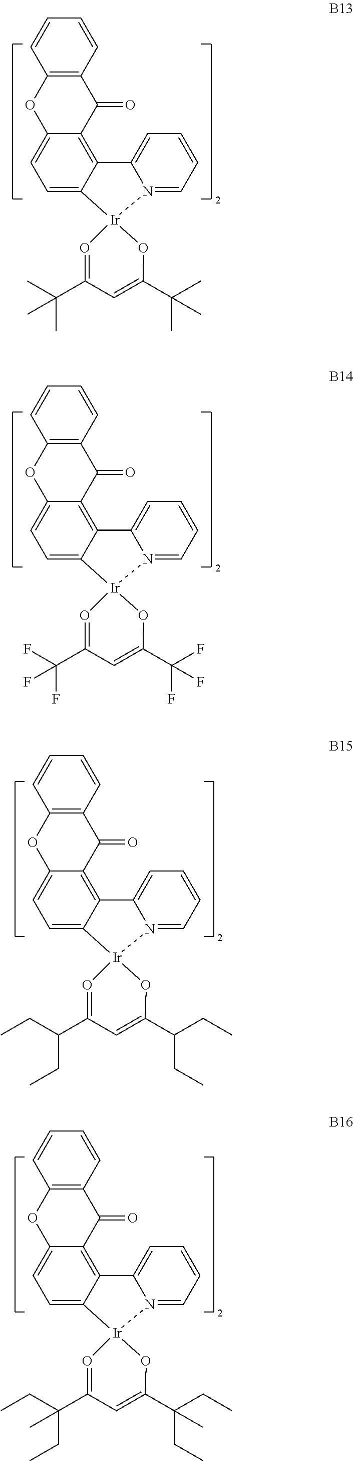

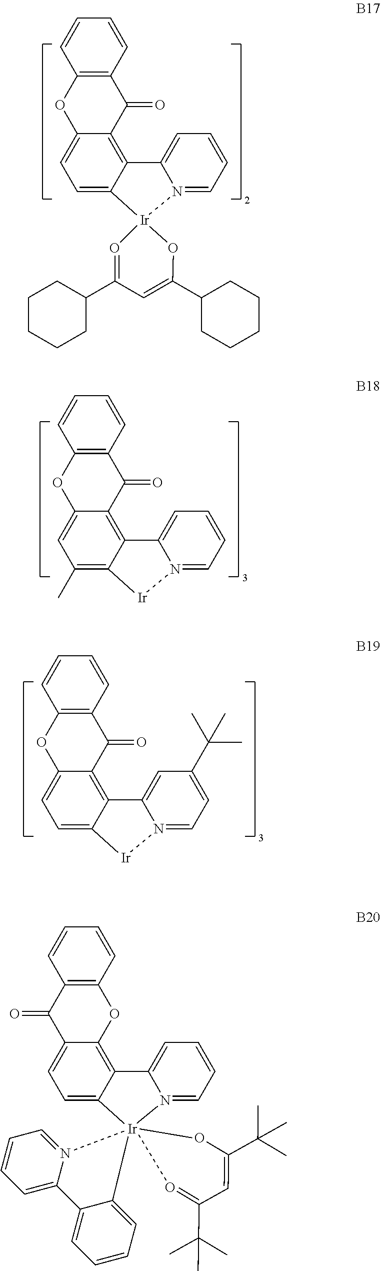

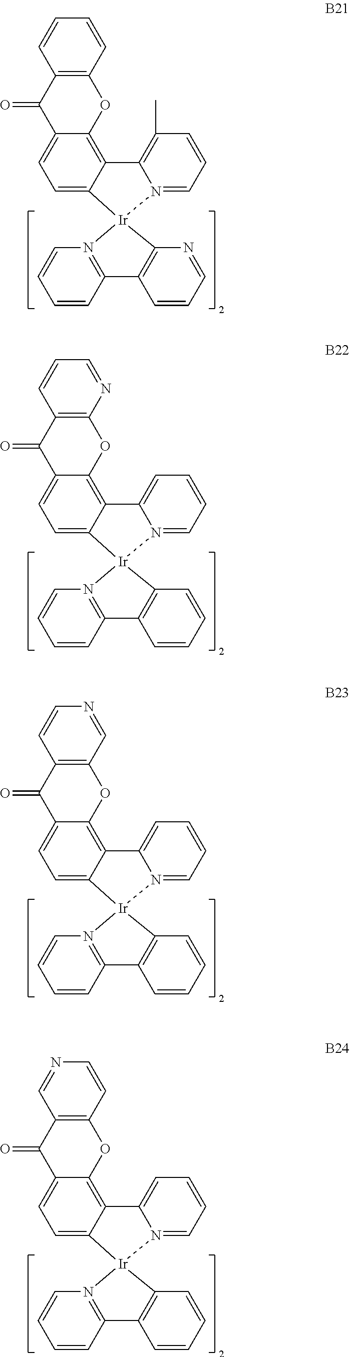

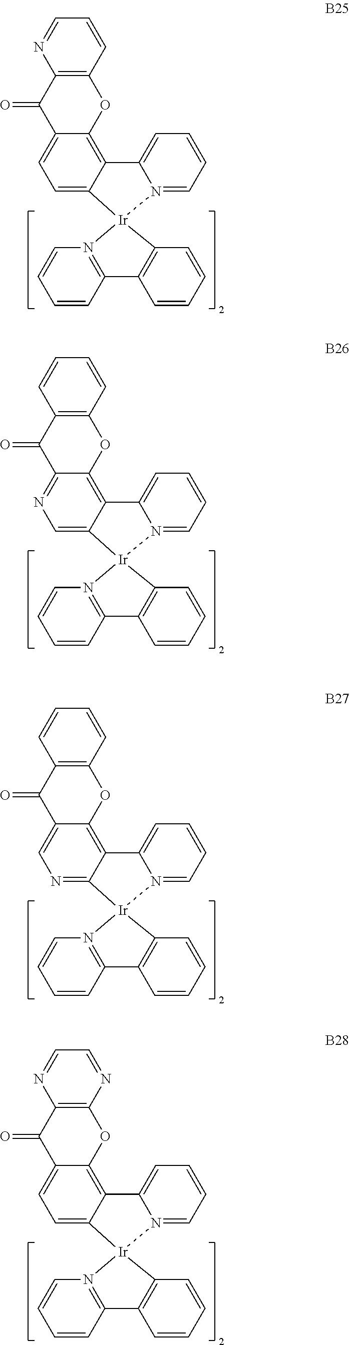

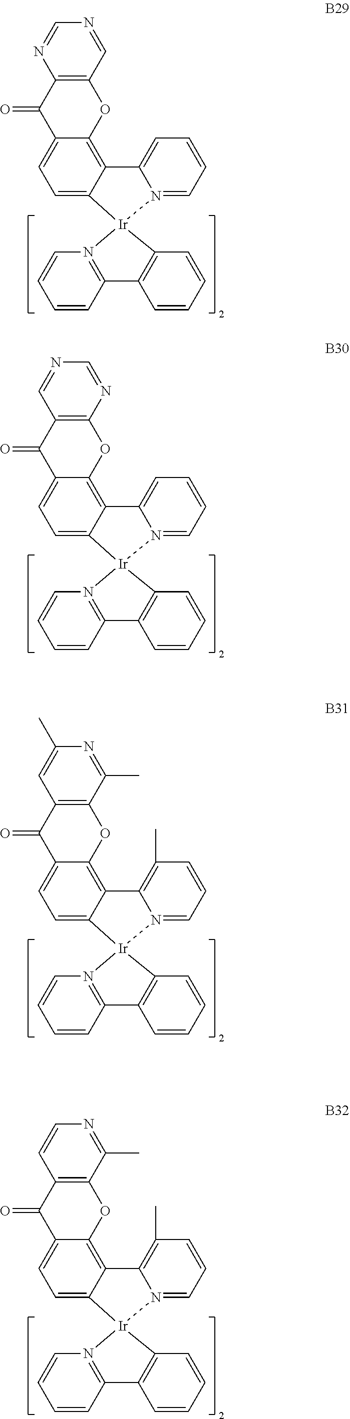

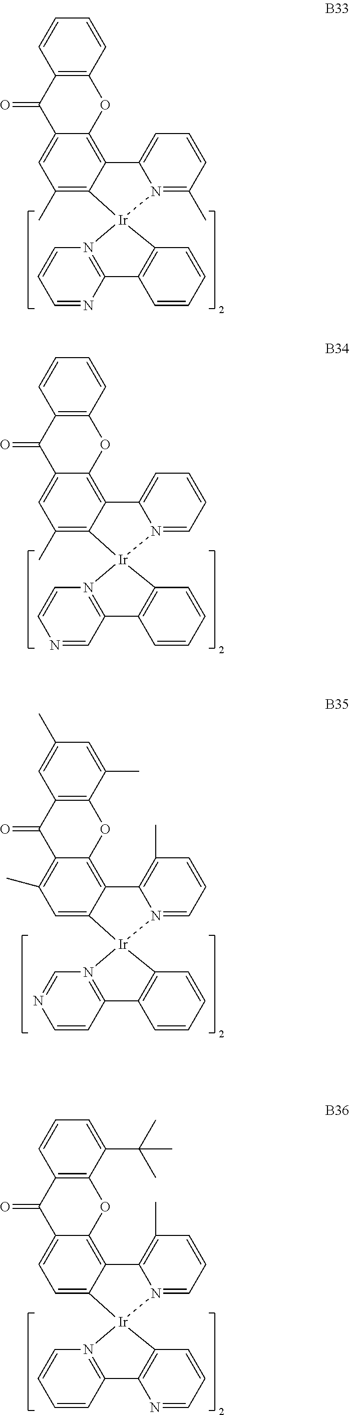

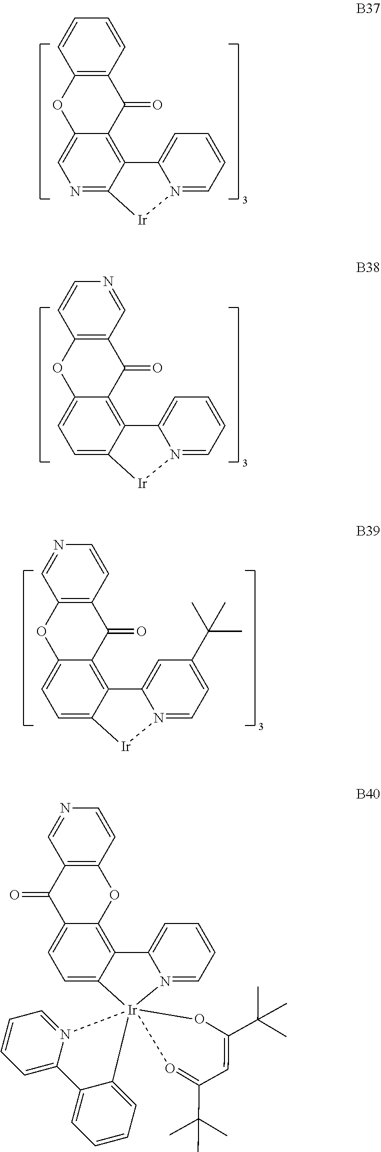

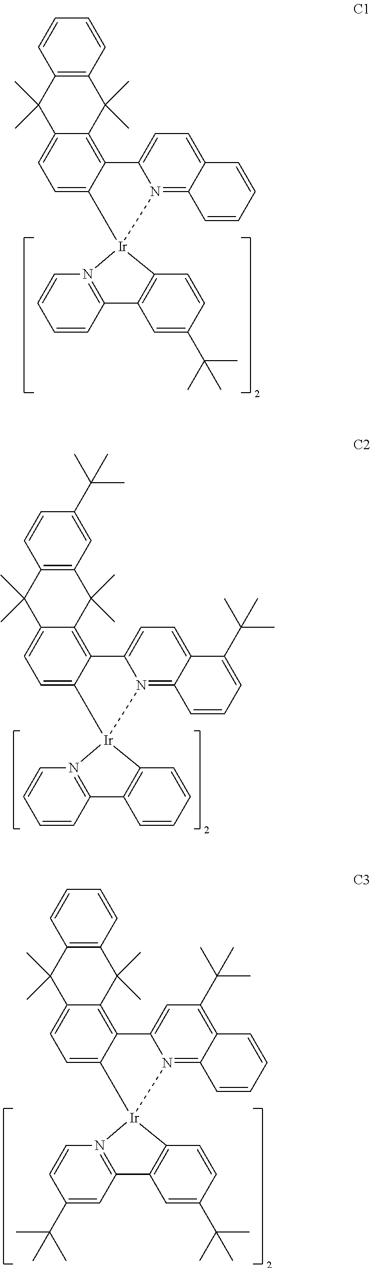

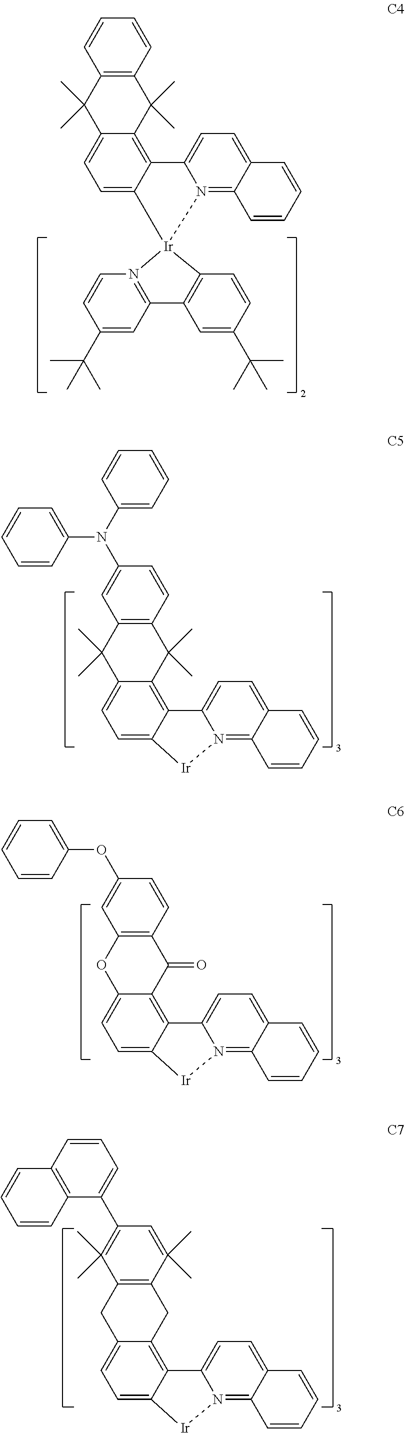

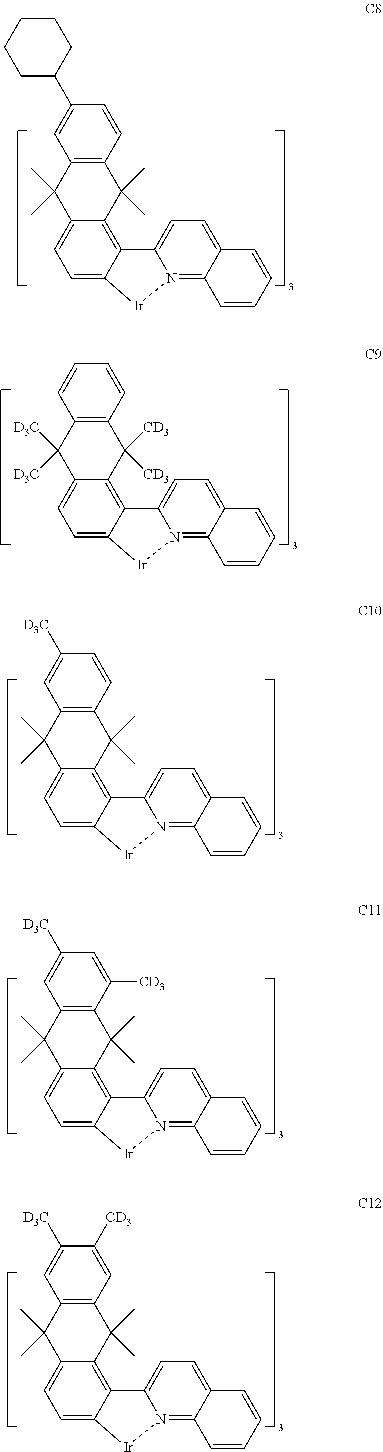

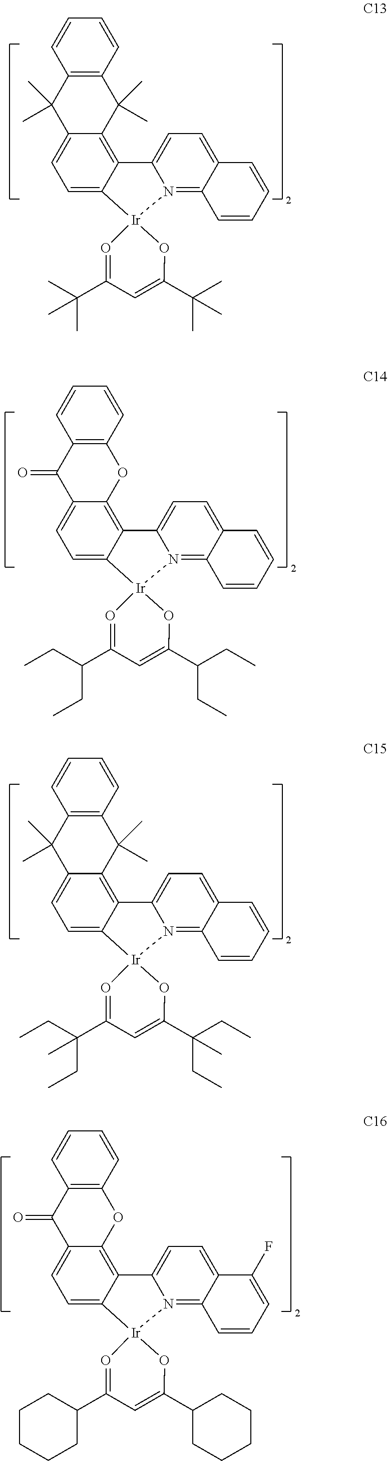

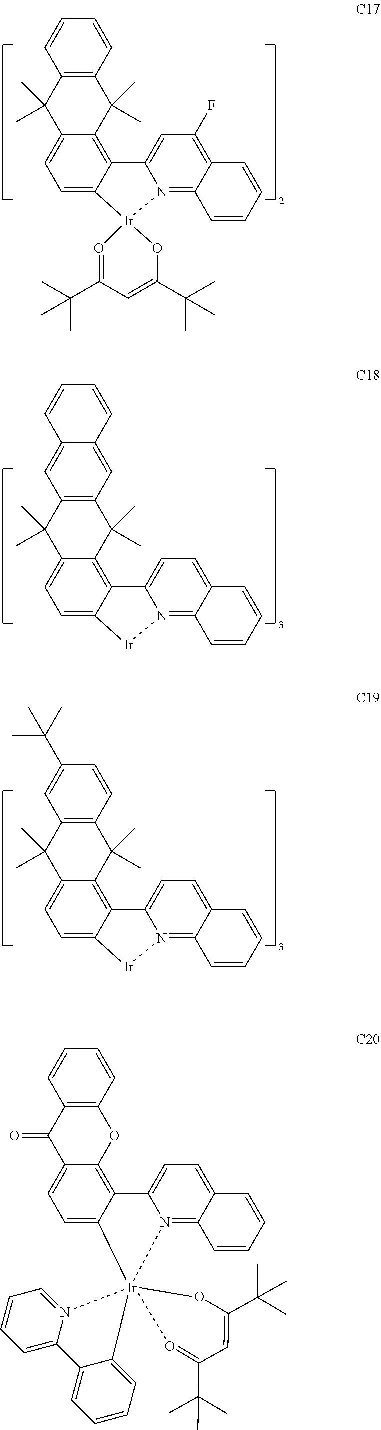

The exemplary compounds belonging to Group A are organometallic complexes in which M(L₁) is represented by General Formula [1] and the ring A is a pyridine ring represented by General Formula [6]. Therefore, the emission wavelength is in a range of green to yellow. A light emitting element emitting light of a green color to a yellow color can be provided by using such compounds.

The exemplary compounds belonging to Group B are organometallic complexes in which M(L₁) is represented by General Formulae [2] and [3] and the ring A is a pyridine ring represented by General Formula [6]. Therefore, the emission wavelength is in a range of green to yellow. Further, these compounds are compounds with particularly high oxidation stability due to containing an electron withdrawing ketone group.

The exemplary compounds belonging to Group C are organometallic complexes in which M(L₁) is represented by General Formulae [1] to [3] and the ring A is a quinoline ring represented by General Formula [7]. Therefore, the emission wavelength is in a range of yellow to red. A light emitting element emitting light of a yellow color to a red color can be provided by using such compounds.

Further, it is preferable that the compound of the present invention be used in the light emitting layer of the organic light emitting element under the following conditions.

(5) The content of the compound according to the present invention to be mixed with a host material in the light emitting layer is 1% by mass or greater and 30% by mass or less.

(6) The host material mixed with the compound of the present invention in the light emitting layer has at least an azine skeleton.

(7) The host material mixed with the compound of the present invention in the light emitting layer contains at least any of triphenylene, phenanthrene, chrysene, or fluoranthene in the skeleton.

(8) The host material mixed with the compound of the present invention in the light emitting layer contains at least any of dibenzothiophene or dibenzofuran in the skeleton.

(9) The host material used with the compound of the present invention does not contain SP³ carbon.

Hereinafter, the above-described conditions will be described.

(5) The content of the compound according to the present invention to be mixed with a host material in the light emitting layer is 1% by mass or greater and 30% by mass or less.

PTL 1 describes that when the above-described comparative compound 1-A is used in the light emitting layer, the content thereof is most preferably 51% by mass or greater and 100% by mass or less. Further, when the organometallic complex of the present invention is used in the light emitting layer, the content thereof is preferably 1% by mass or greater and 30% by mass or less. This can be said that the ideas of PTL 1 and the present invention are opposite to each other. That is, the organometallic complex of the present invention can be said to be a compound that exhibits excellent functions only at a low concentration when used in the light emitting layer. Further, a light emitting element with high efficiency and high color purity can be provided by setting the concentration to be low.

This is due to the characteristics of the structure of the organometallic complex according to the present invention. The organometallic complex of the present invention has a tetrahydroanthracene skeleton or a xanthone skeleton with high planarity in the ligand. Therefore, when the organometallic complexes are mixed into the light emitting layer at an excessively high concentration, since the organometallic complexes are likely to be aggregated to cause concentration quenching, the emission efficiency can be decreased. Accordingly, when the organometallic complex of the present invention is used in the light emitting layer, the content thereof is preferably 1% by mass or greater and 30% by mass or less. A light emitting element with high efficiency can be provided under such conditions.

(6) The host material mixed with the compound of the present invention in the light emitting layer has at least an azine skeleton.

The organometallic complex of the present invention is a compound that has a deep HOMO and high oxidation stability. Therefore, it is preferable that the host material forming the light emitting layer with the organometallic complex of the present invention be also a material having a deep HOMO. The reason for this is that excessive HOMO and LUMO gaps between the organometallic complex and the host material are not generated.

Here, the present inventors found that the host material preferably has an azine ring in the skeleton as the material having a deep HOMO. The azine ring such as pyridine, pyrazine, pyrimidine, or triazine is an electron-deficient heterocyclic ring. That is, the host material having such a structure can be expected to have a deep HOMO.

Meanwhile, since the HOMO is extremely deep in the host material formed of only an azine ring, positive hole injection from a positive hole transport layer to the light emitting layer may be degraded. Therefore, it is particularly preferable to introduce a carbazole skeleton expected to have a shallow HOMO to the extent that the positive hole injection characteristics can be maintained.

That is, when the host material has a carbazole skeleton and an azine skeleton, a light emitting layer having HOMO and LUMO gaps suitable for the organometallic complex of the present invention can be formed, and carrier injection from a positive hole transport layer and an electron transport layer to the light emitting layer can be maintained.

In addition, the host material has a shallow HOMO when formed of only arylamine and a carbazole skeleton. Since the HOMO is shallow and the LUMO is also shallow in the entire light emitting layer when the host material having a shallow HOMO is used, electron injection from the electron transport layer to the light emitting layer is difficult to carry out, which is not preferable. Specifically, CBP (4,4′-bis(9H-carbazol-9-yl)biphenyl) or the like is not preferable as the host material used with the organometallic complex of the present invention.

(7) The host material mixed with the compound of the present invention in the light emitting layer contains at least any of triphenylene, phenanthrene, chrysene, or fluoranthene in the skeleton.

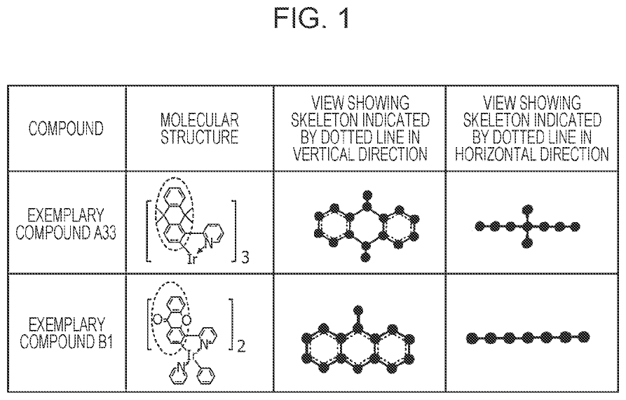

The organometallic complex of the present invention has a tetrahydroanthracene skeleton or a xanthone skeleton. As shown in FIG. 1, the tetrahydroanthracene skeleton and the xanthone skeleton are structures with high planarity. Therefore, it is preferable that the host material similarly have a structure with high planarity. The reason for this is that when the host material has a structure with high planarity, sites with high planarity can approach each other through an interaction. More specifically, the tetrahydroanthracene skeleton or the xanthone skeleton of the organometallic complex and the planar site of the host material are likely to approach each other. Accordingly, the intermolecular distance between the organometallic complex and the host material can be expected to be decreased.

Here, triplet energy used for a phosphorescent light emitting element is known to undergo energy transfer based on Dexter electron transfer. According to the Dexter electron transfer, the energy transfer is carried out by the contact of molecules. That is, the energy transfer from the host material to a guest material is efficiently made by decreasing the intermolecular distance between the host material and the guest material.

In the present invention, when a material with high planarity is used as the host material, the intermolecular distance between the organometallic complex and the host material is decreased, and thus the energy transfer from the host material to the organometallic complex is more efficiently and easily carried out. As a result, a highly efficient organic light emitting element can be provided.

Here, the structure with high planarity indicates triphenylene, phenanthrene, chrysene, or fluoranthene. A light emitting element with higher efficiency can be provided by using the organometallic complex of the present invention when a compound having at least any of these structures is used as the host material.

(8) The host material mixed with the compound of the present invention in the light emitting layer contains at least any of dibenzothiophene or dibenzofuran in the skeleton.

The organometallic complex of the present invention has a tetrahydroanthracene skeleton or a xanthone skeleton in the ligand. Therefore, as listed in Table 6, the HOMO site formed by the ligand and the Ir metal has a characteristic molecular orbital with conjunction broken by SP³ carbons at the 9 and 10 positions of tetrahydroanthracene. The same applies to xanthone.

Therefore, an opposite side of the Ir metal in the tetrahydroanthracene skeleton and the xanthone skeleton is an unoccupied orbital in the molecular orbital of the HOMO, and thus the hole transport ability is decreased.

It is preferable that the host material be a material having a skeleton with an excellent hole transport ability in order to improve the hole transport ability. The skeleton with an excellent hole transport ability is a skeleton abundantly having lone electron pairs and having high electron donating properties. Specific examples of the skeleton include a skeleton having a nitrogen atom with electron donating properties, such as carbazole, described in the section of the condition (6) above and a skeleton having a chalcogen atom abundantly having lone electron pairs, such as dibenzothiophene or dibenzofuran.

Among these, a host material having a skeleton of dibenzothiophene or dibenzofuran is preferable as the host material that can be suitably used with the organometallic complex of the present invention. The skeleton of dibenzothiophene or dibenzofuran does not have an extremely shallow HOMO, and thus is suitable as a skeleton capable of adjusting the carrier balance between holes and electrons and supporting the hole transport ability of the organometallic complex according to the present invention.

TABLE 6

| Compound | Structure | HOMO | LUMO |
|---|---|---|---|
| Exemplary compound A33 | 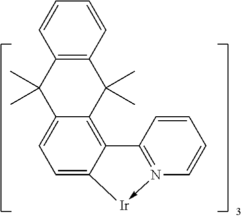 | 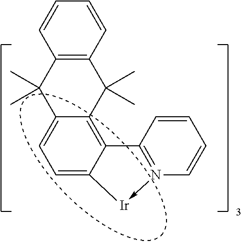 | 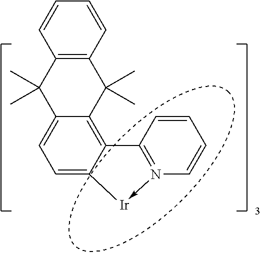 |
| Exemplary compound B1 | 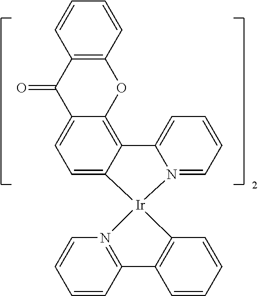 | 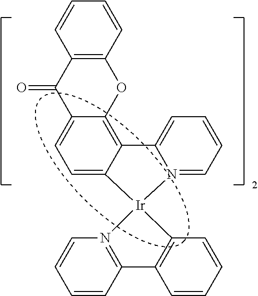 | 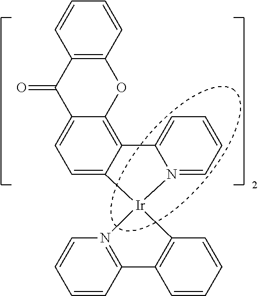 |

(9) The host material used with the compound of the present invention does not contain SP³ carbon.

The organometallic complex of the present invention is a compound having light emitting properties improved by reducing the distance between the organometallic complex and the host material as described in the section of the condition (6). The distance between the organometallic complex and the host material can be reduced by using a material having no SP³ carbon as the host material. The reason for this is that the distance between the organometallic complex and the host material increases due to the hydrophobic interaction and steric hindrance of an alkyl group when the host material has SP³ carbon. The distance between the host material and the organometallic complex serving as a guest material can be reduced by using a host material having no SP³ carbon as the host material.

Specific preferred examples of the host material according to the present invention will be shown below. However, the present invention is not limited thereto.

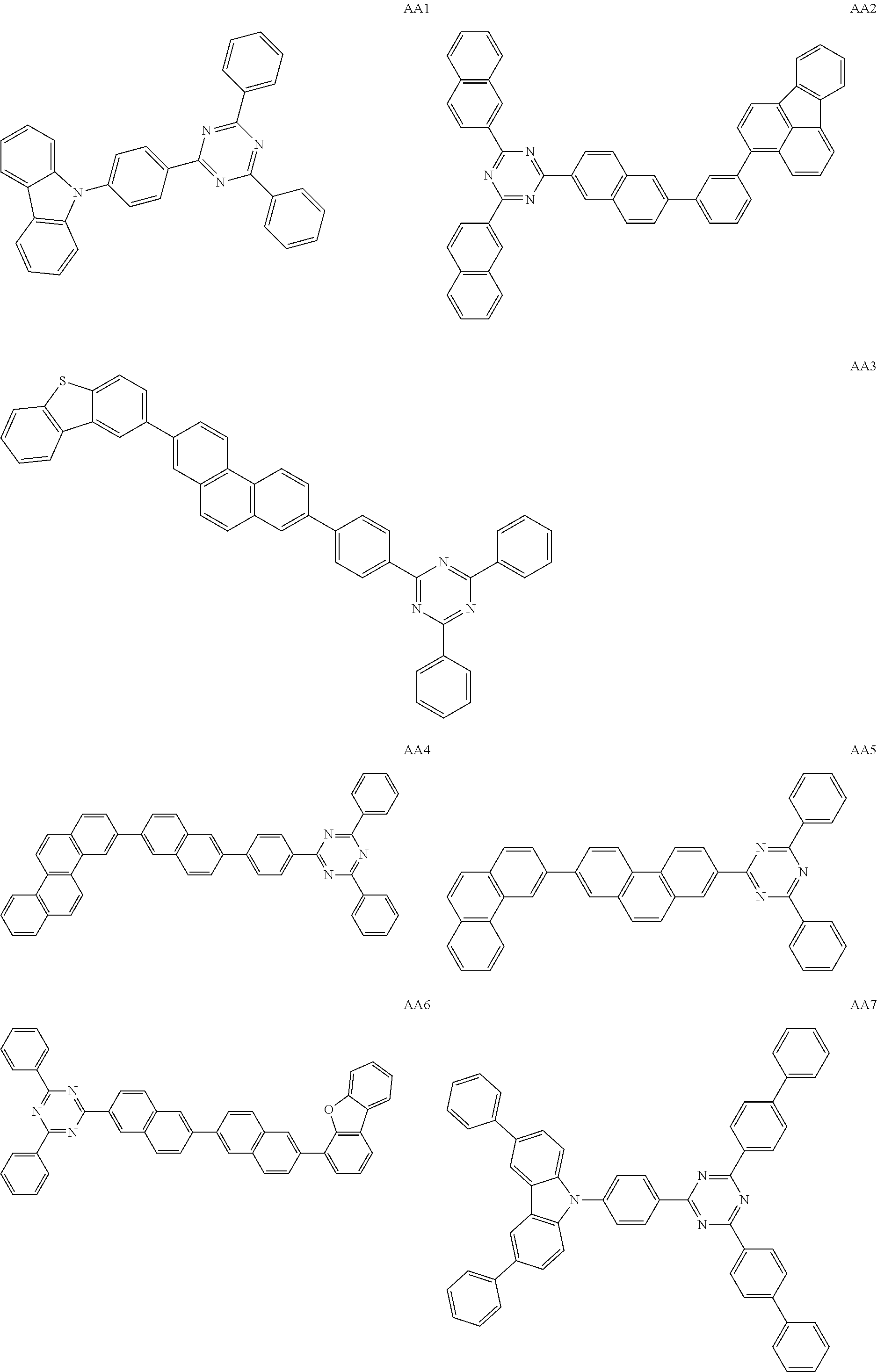

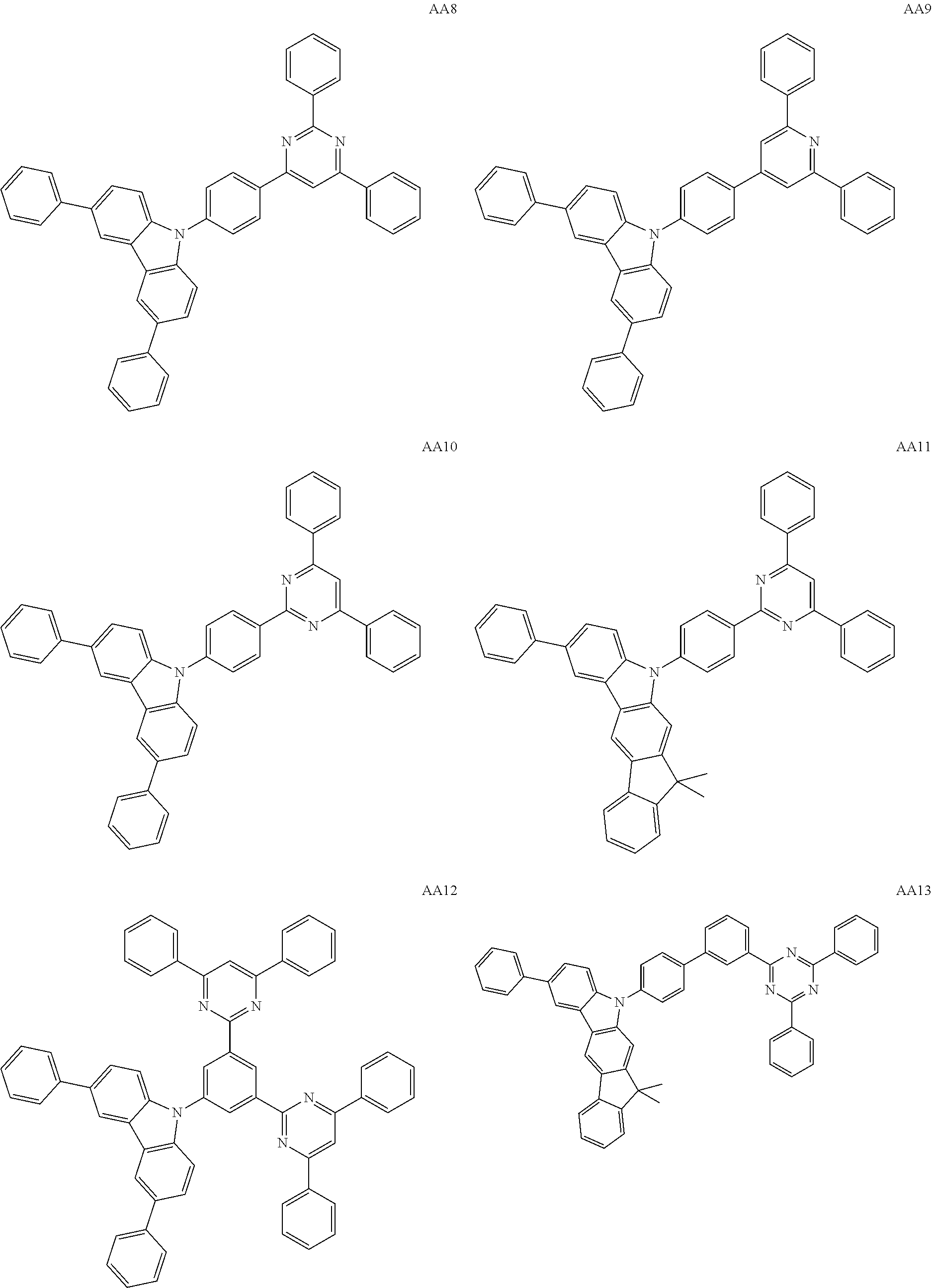

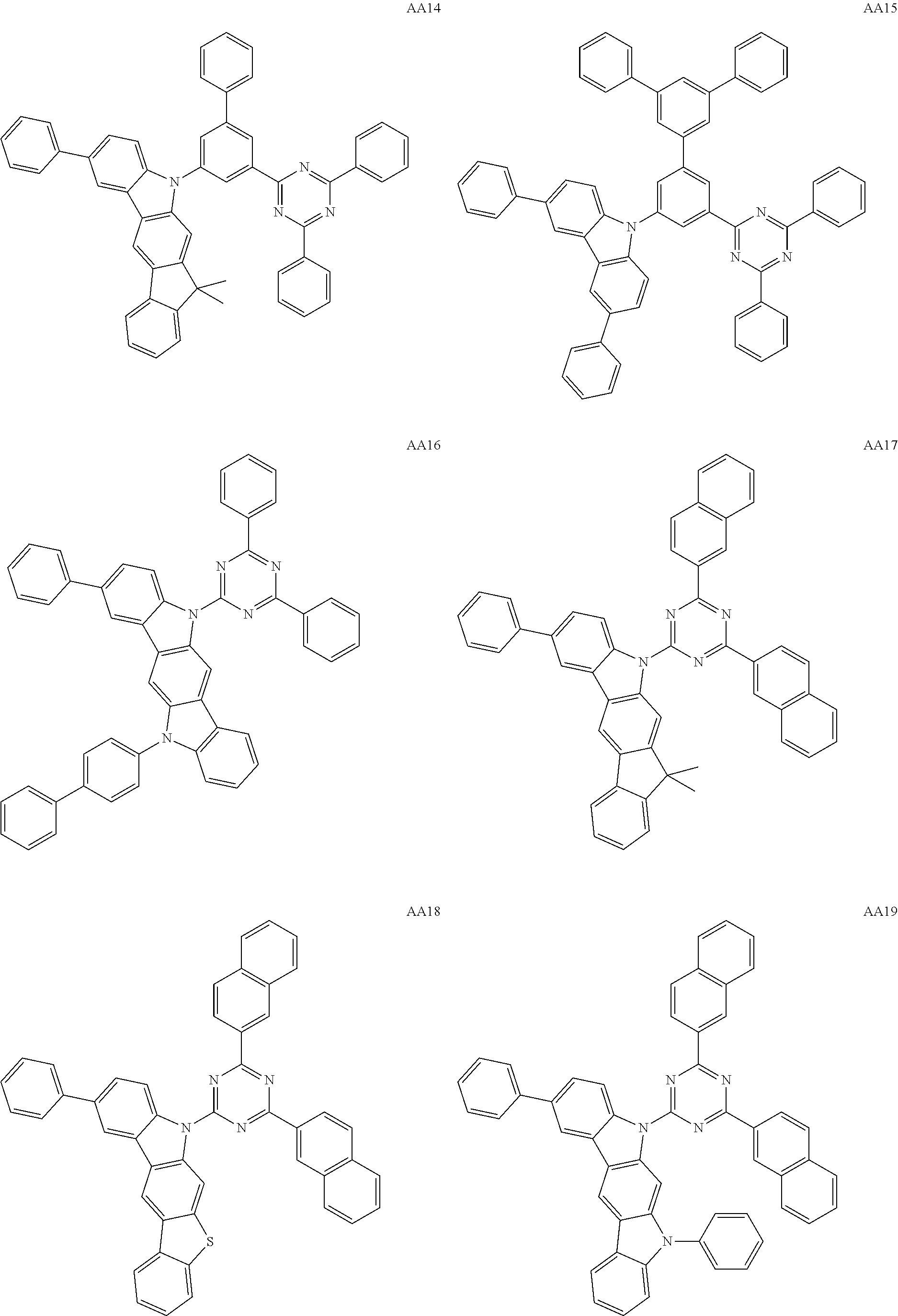

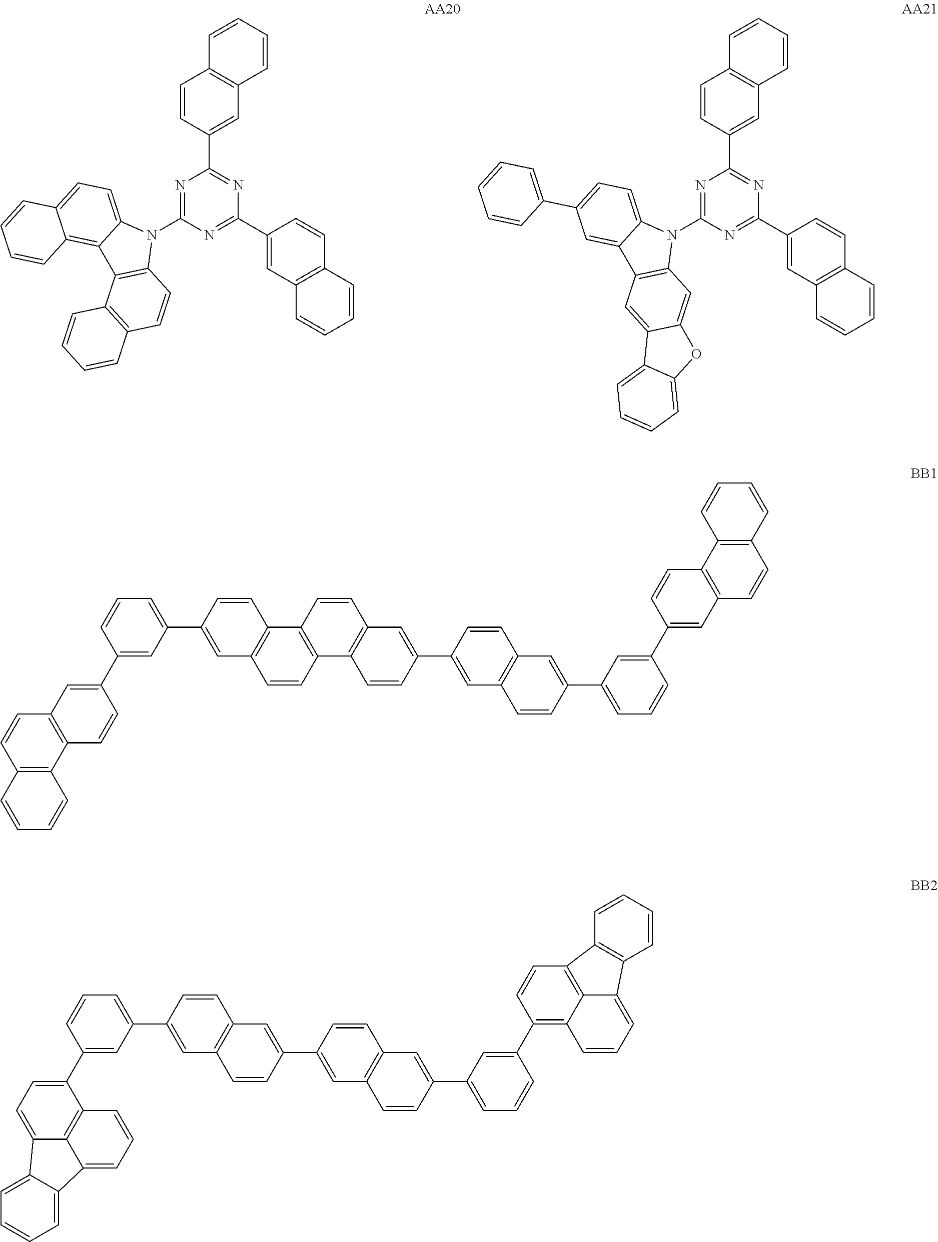

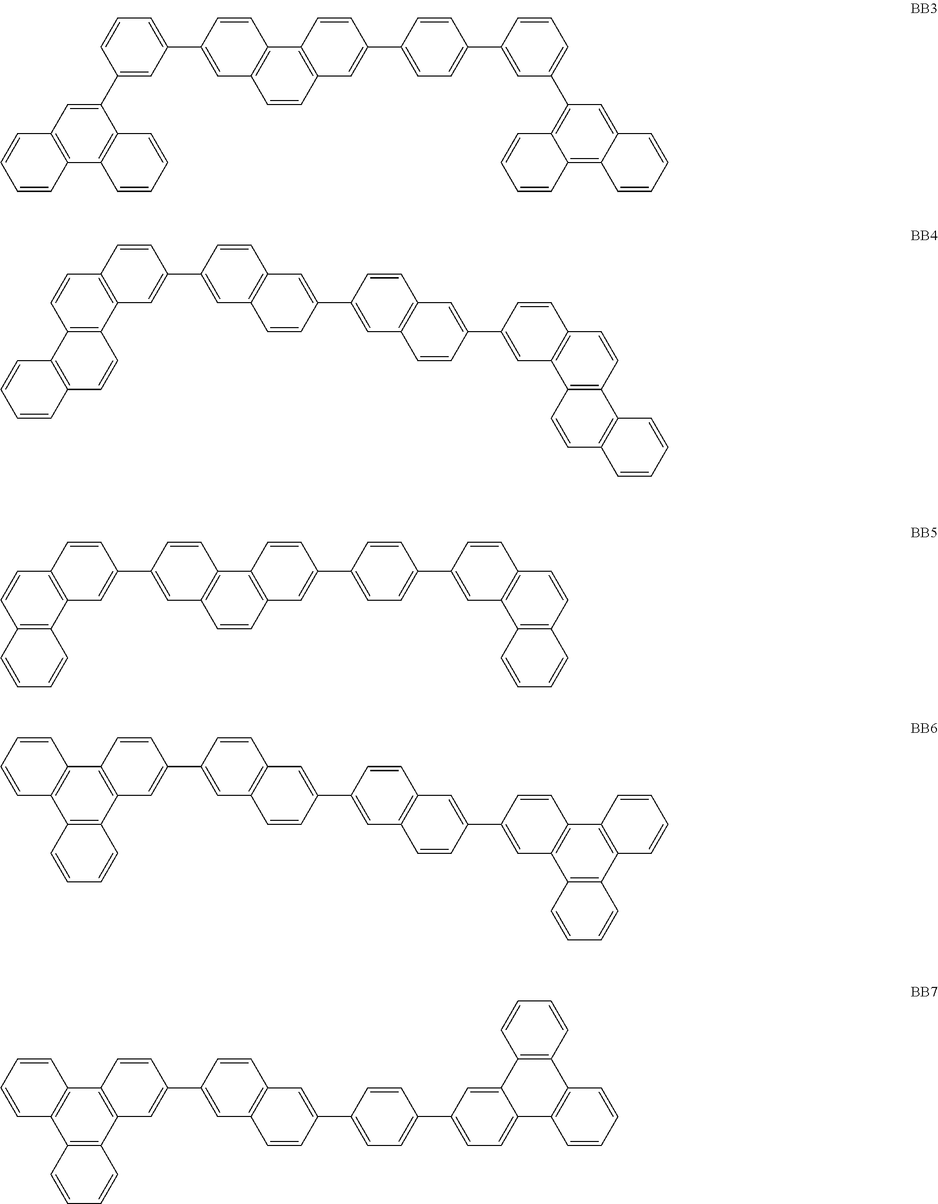

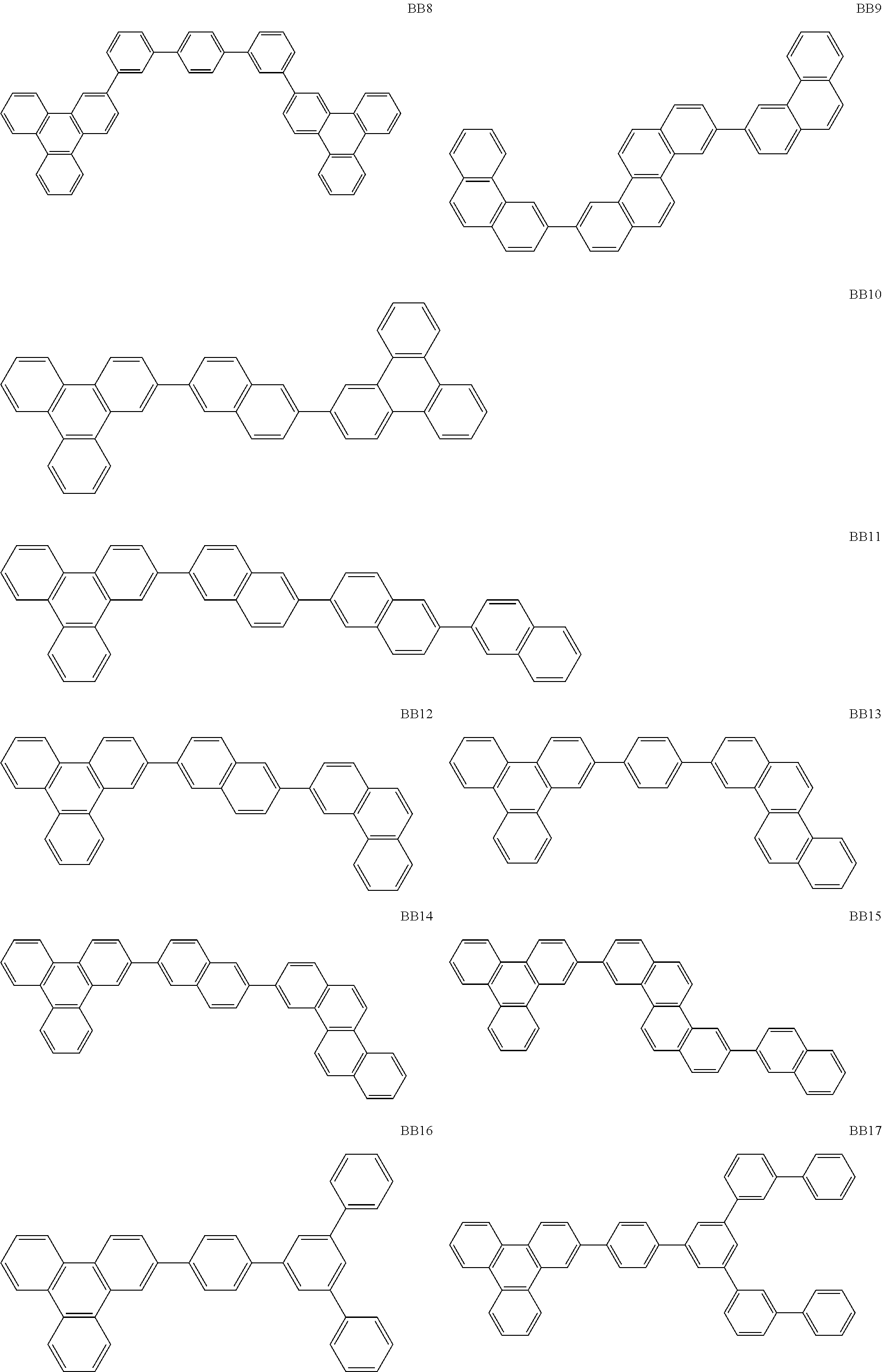

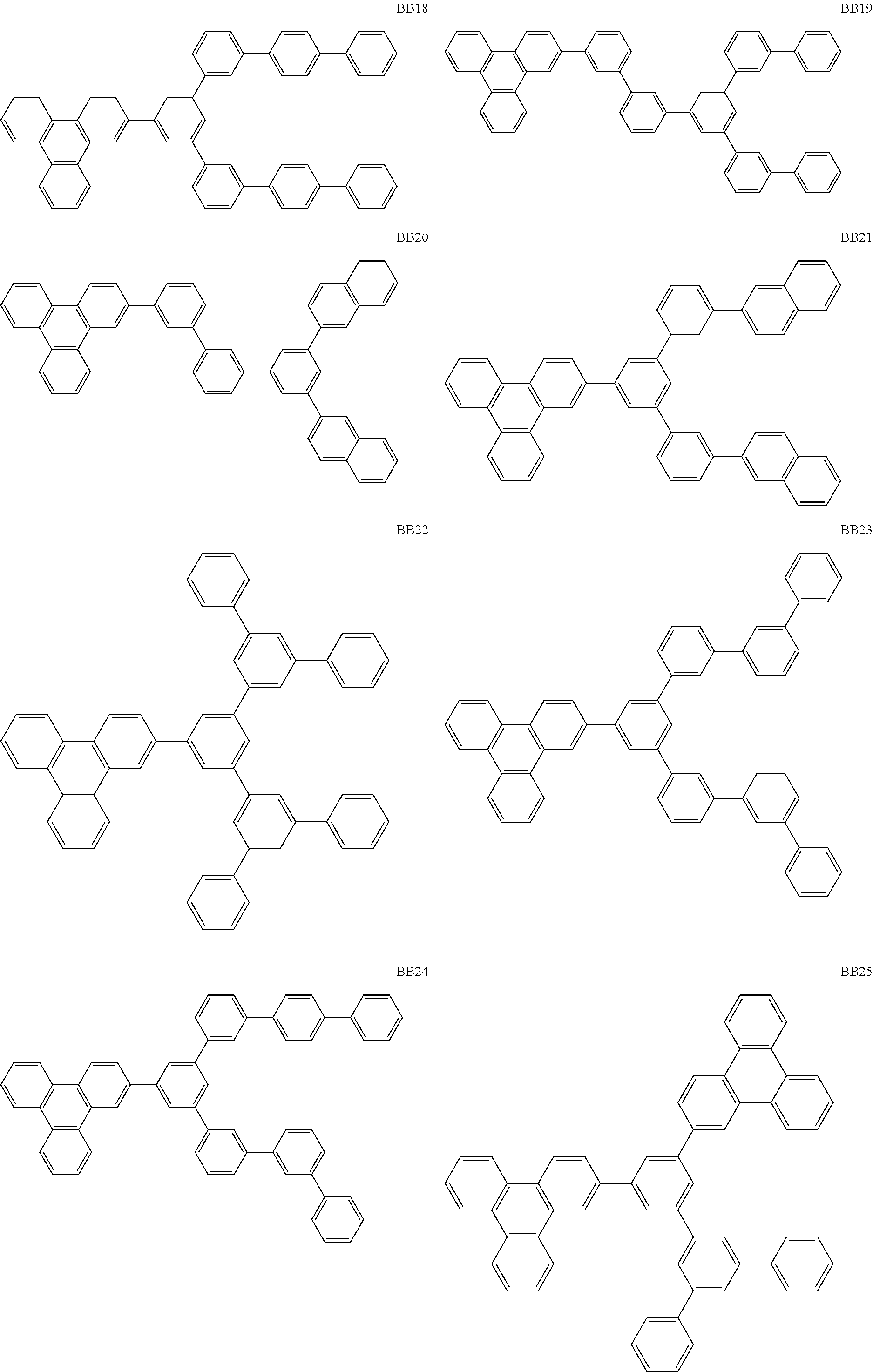

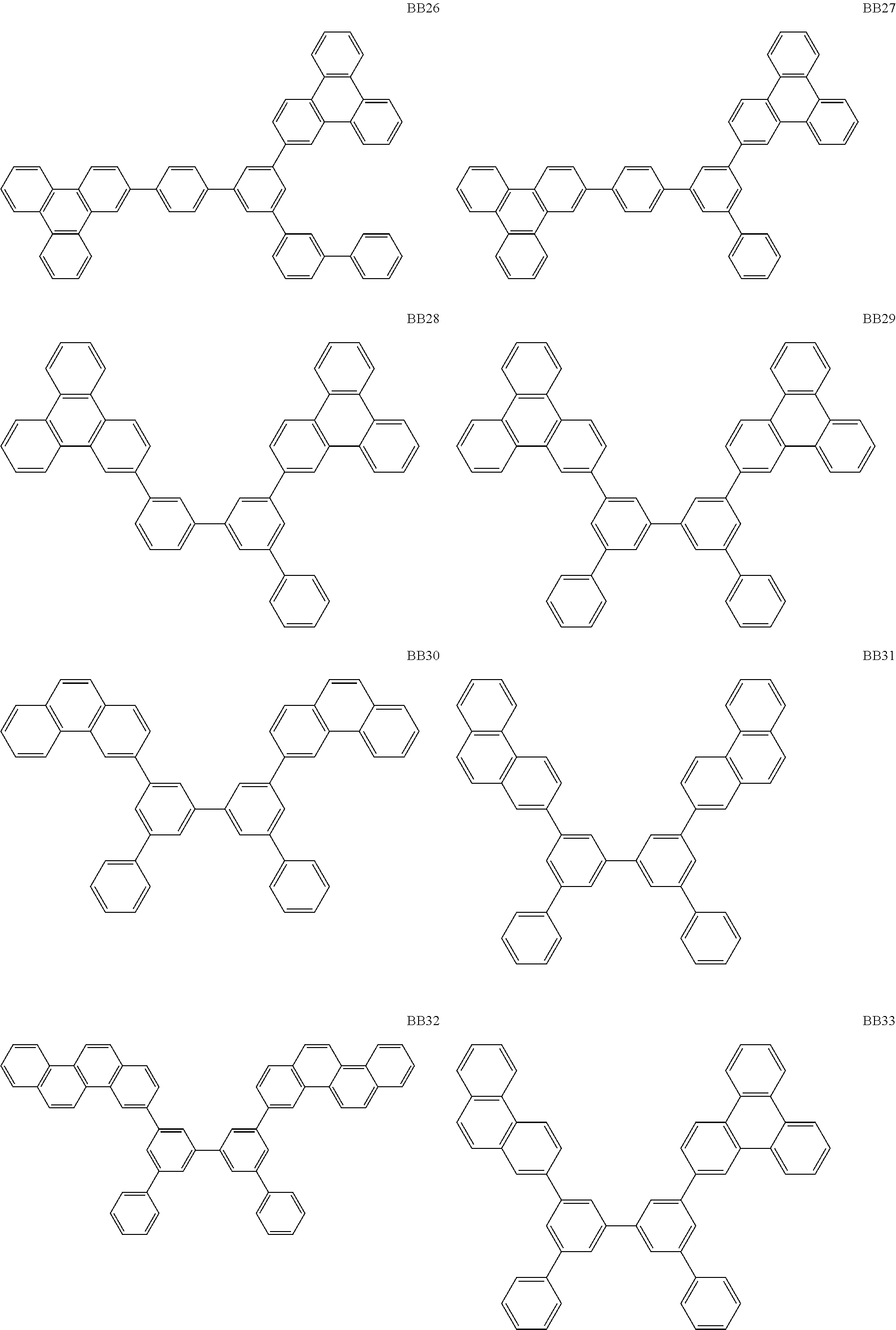

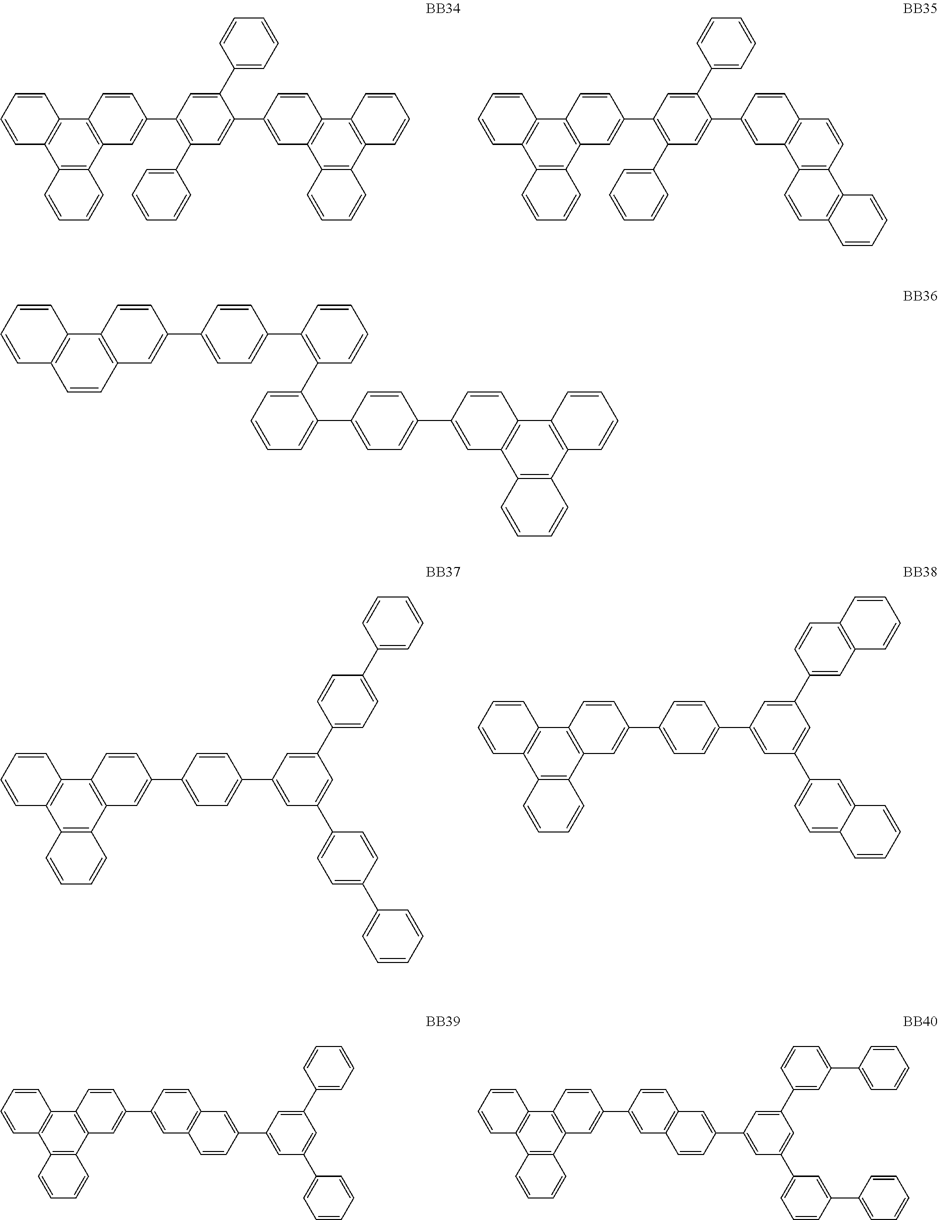

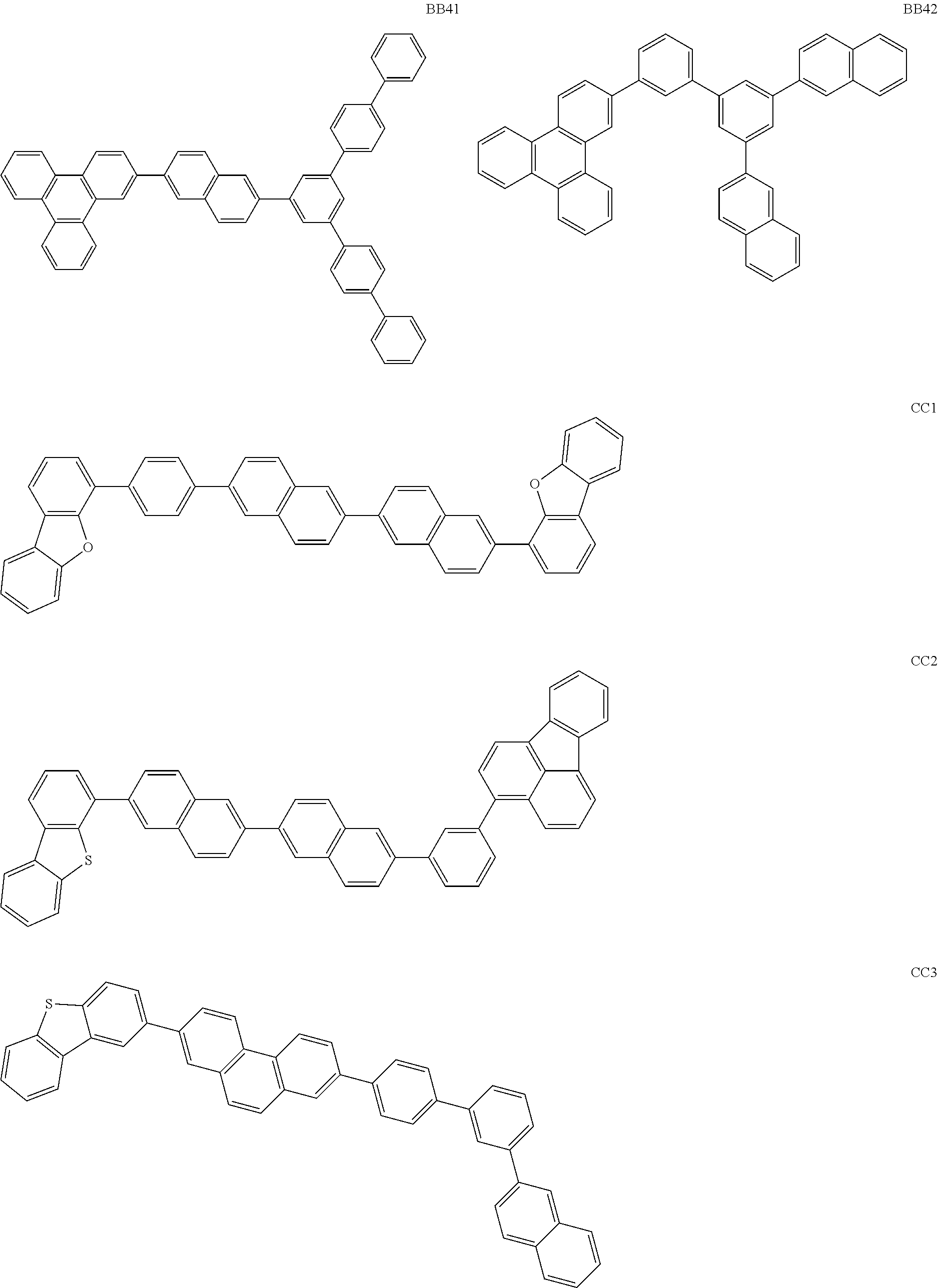

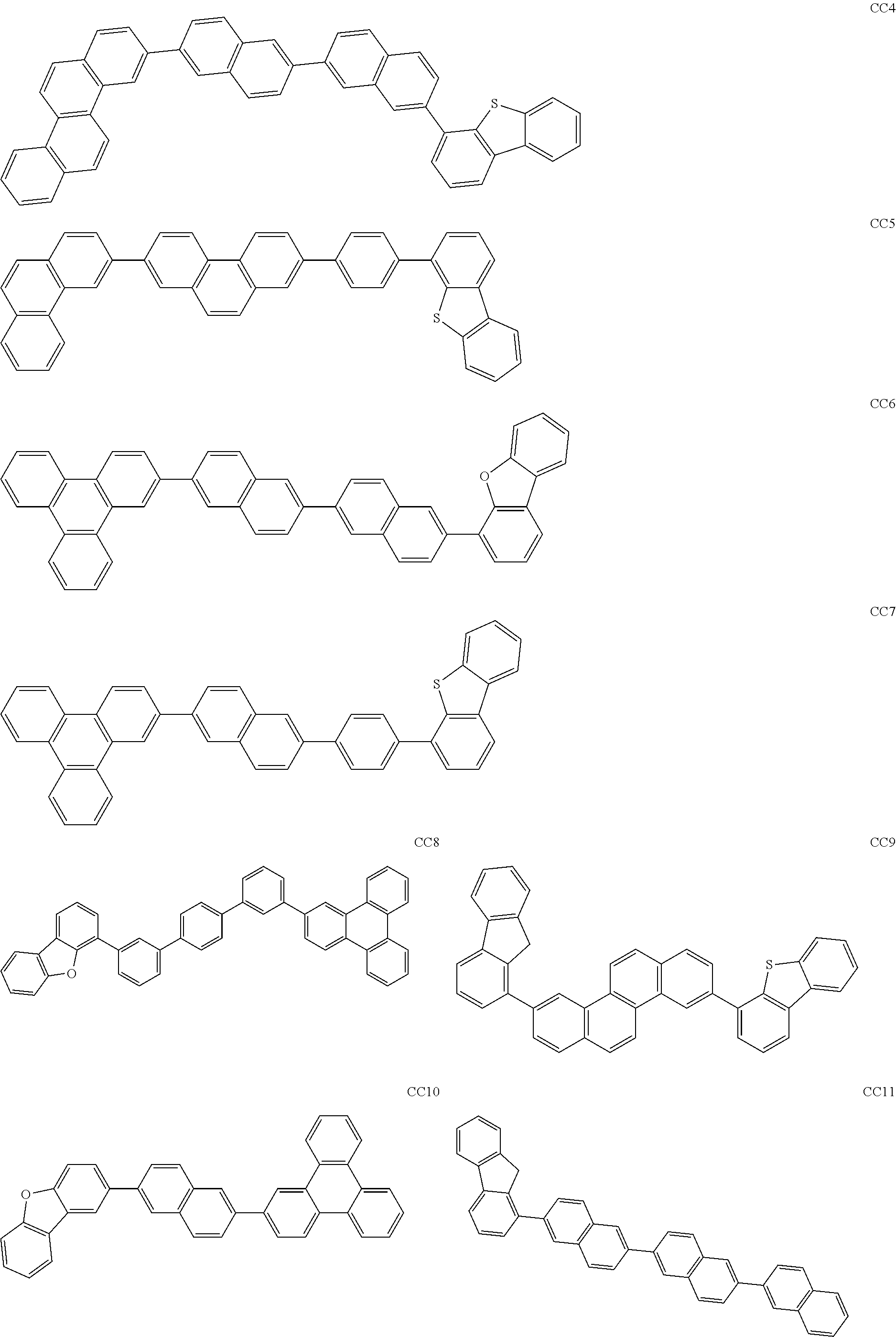

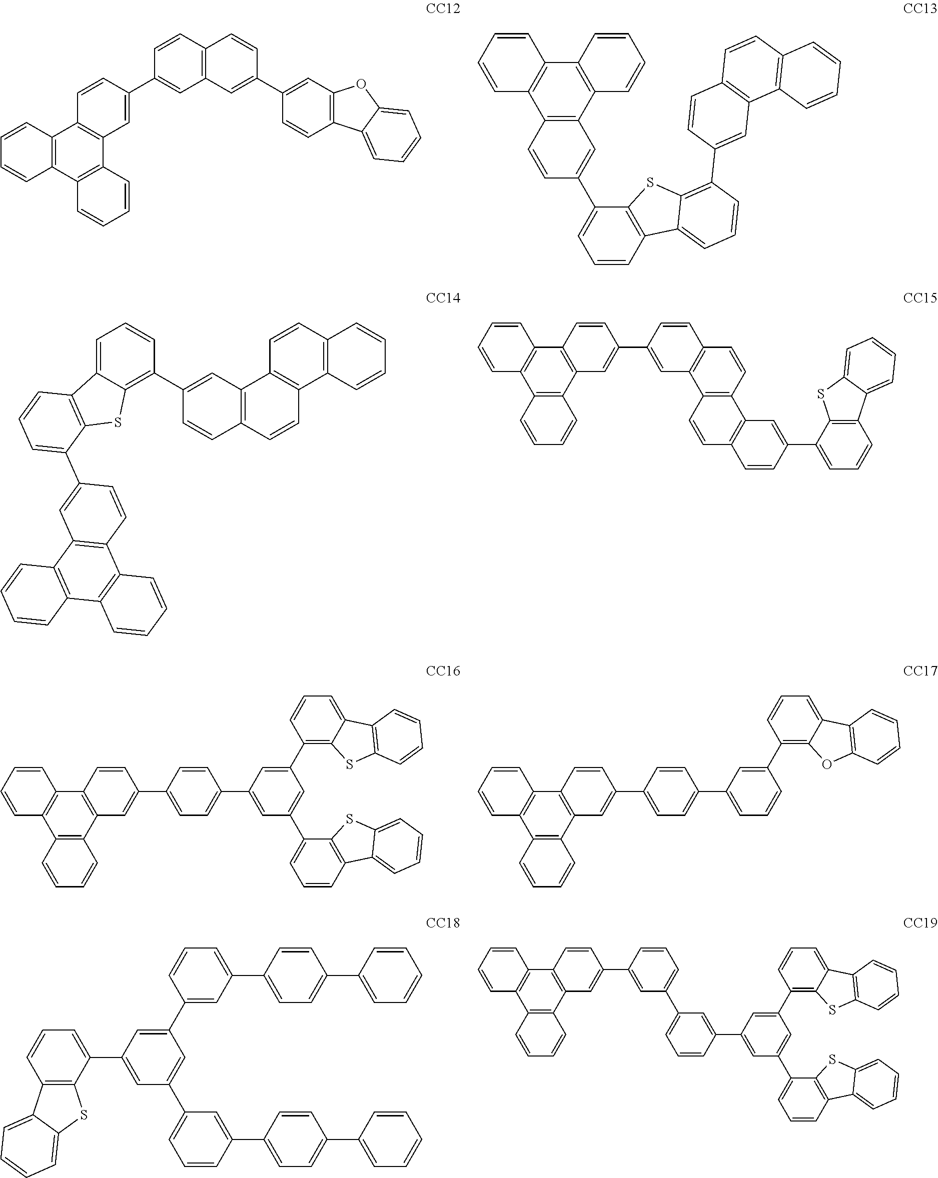

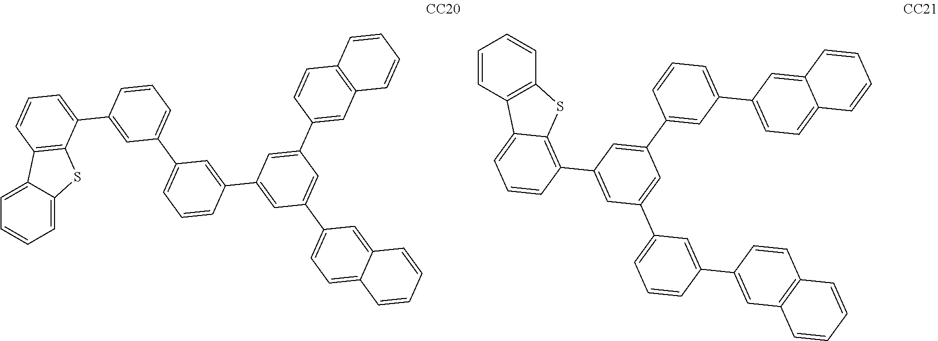 [SMILES: c1cc(-c2cc(-c3ccc4ccccc4c3)cc(-c3ccc4ccccc4c3)c2)cc(-c2cccc(-c3cccc4c3sc3ccccc34)c2)c1 ; c1cc(-c2cc(-c3cccc(-c4ccc5ccccc5c4)c3)cc(-c3cccc4c3sc3ccccc34)c2)cc(-c2ccc3ccccc3c2)c1]

The exemplary compounds belonging to Group AA are compounds having at least an azine ring in the skeleton. Therefore, these compounds have a deep HOMO and small HOMO and LUMO gaps between the compounds and the organometallic complex of the present invention, and thus a satisfactory light emitting layer can be formed with the organometallic complex of the present invention.

The exemplary compounds belonging to Group BB are compounds having at least any of triphenylene, phenanthrene, chrysene, or fluoranthene in the skeleton and having no SP³ carbon. Therefore, these compounds are host materials that undergo satisfactory energy transfer to the organometallic complex of the present invention because the compounds can further approach the organometallic complex of the present invention. Among the examples, a compound having triphenylene in the skeleton is particularly preferable from the viewpoint of high planarity.

The exemplary compounds belonging to Group CC are compounds having at least any of dibenzothiophene or dibenzofuran in the skeleton and having no SP³ carbon. Therefore, when these compounds are used to form a light emitting layer with the organometallic complex of the present invention, the balance between the HOMO and the LUMO is satisfactory. Accordingly, the compounds are host materials realizing satisfactory carrier balance when used as host materials of the organometallic complex of the present invention. Among the examples, a compound having dibenzothiophene in the skeleton is particularly preferable from the viewpoint that the lone electron pairs are abundantly present.

### <<Organic Light Emitting Element>>

Next, the organic light emitting element of the present embodiment will be described.

The organic light emitting element of the present embodiment includes at least a pair of electrodes, an anode and a cathode, and an organic compound layer disposed between these electrodes. In the organic light emitting element of the present embodiment, the organic compound layer may be a single layer or a laminate formed of a plurality of layers as long as the organic compound layer includes a light emitting layer. Here, when the organic compound layer is a laminate formed of a plurality of layers, the organic compound layer may include, in addition to the light emitting layer, a hole injection layer, a hole transport layer, an electron blocking layer, a hole/exciton blocking layer, an electron transport layer, and an electron injection layer. Further, the light emitting layer may be a single layer or a laminate formed of a plurality of layers.

In the organic light emitting element of the present embodiment, at least one layer of the organic compound layer contains the organic compound of the present embodiment. Specifically, the organic compound according to the present embodiment is contained in any of a light emitting layer, a hole injection layer, a hole transport layer, an electron blocking layer, a hole/exciton blocking layer, an electron transport layer, or an electron injection layer. It is preferable that the organic compound according to the present embodiment be contained in a light emitting layer.

In the organic light emitting element of the present embodiment, when the organic compound according to the present embodiment is contained in a light emitting layer, the light emitting layer may be a layer formed of only the organic compound according to the present embodiment or a layer formed of the organic compound according to the present embodiment and other compounds. Here, when the light emitting layer is a layer formed of the organic compound according to the present embodiment and other compounds, the organic compound according to the present embodiment may be used as a host or a guest in the light emitting layer. Further, the organic compound may be used as an assist material that can be contained in the light emitting layer. Here, the host is a compound having the highest mass ratio among the compounds constituting the light emitting layer. Further, the guest is a compound that has a mass ratio less than that of the host among the compounds constituting the light emitting layer and is responsible for main light emission. Further, the assist material is a compound which has a mass ratio less than that of the host among the compounds constituting the light emitting layer and supports light emission of the guest. In addition, the assist material is referred to as a second host. Here, when the organic compound according to the present embodiment is used as the guest of the light emitting layer, the concentration of the guest is preferably 1% by mass or greater and 30% by mass or less and more preferably 5% by mass or greater and 15% by mass or less with respect to the total concentration of the light emitting layer. Further, when the organic compound according to the present embodiment is used as the guest of the light emitting layer, the light emitting layer may contain, in addition to the host, a third component such as an assist material.

As a result of various research conducted by the present inventors, it was found that when the organic compound according to the present embodiment is used as a host or a guest of the light emitting layer, particularly as a guest of the light emitting layer, an element that outputs light with high efficiency and high brightness and has extremely high durability can be obtained. The light emitting layer may be formed of a single layer or a plurality of layers, and emission colors can be mixed by setting the emission color of the present embodiment as green and allowing the light emitting layer to contain light emitting materials having other emission colors. The plurality of layers denote a state where the light emitting layer and other light emitting layers are laminated. In this case, the emission color of the organic light emitting element is not limited to green. More specifically, the emission color may be white or an intermediate color. When the emission color is white, other light emitting layers emit light of colors other than green, that is, blue and red. Further, the film formation is also performed by a vapor deposition method or a coating film forming method. The details will be described in examples below.

The organic compound according to the present embodiment can be used as a constituent material for the organic compound layer other than the light emitting layer constituting the organic light emitting element of the present embodiment. Specifically, the organic compound may be used as a constituent material for an electron transport layer, an electron injection layer, a hole transport layer, a hole injection layer, a hole blocking layer, or the like. In this case, the emission color of the organic light emitting element is not limited to green. More specifically, the emission color may be white or an intermediate color.

Here, known low-molecular-weight and high-molecular-weight hole injecting compounds or hole transporting compounds, compounds serving as a host, light emitting compounds, electron injecting compounds, or electron transporting compounds of the related art can be used together as necessary in addition to the organic compound according to the present embodiment. Examples of such compounds will be described below.

A material with high hole mobility formed such that hole injection from an anode is easily carried out and the injected holes can be transported to the light emitting layer is preferable as the hole injecting and transporting material. Further, a material with a high glass transition temperature that reduces deterioration of the film quality such as crystallization in the organic light emitting element is preferable. Examples of the low-molecular-weight and high-molecular-weight materials having a hole injecting transporting ability include a triarylamine derivative, an arylcarbazole derivative, a phenylene diamine derivative, a stilbene derivative, a phthalocyanine derivative, a porphyrin derivative, poly(vinylcarbazole), poly(thiophene), and other conductive polymers. Further, the above-described hole injecting and transporting material is suitably used in the electron blocking layer. Specific examples of the compound used as the hole injecting and transporting material will be shown below, but the present invention is not limited thereto.

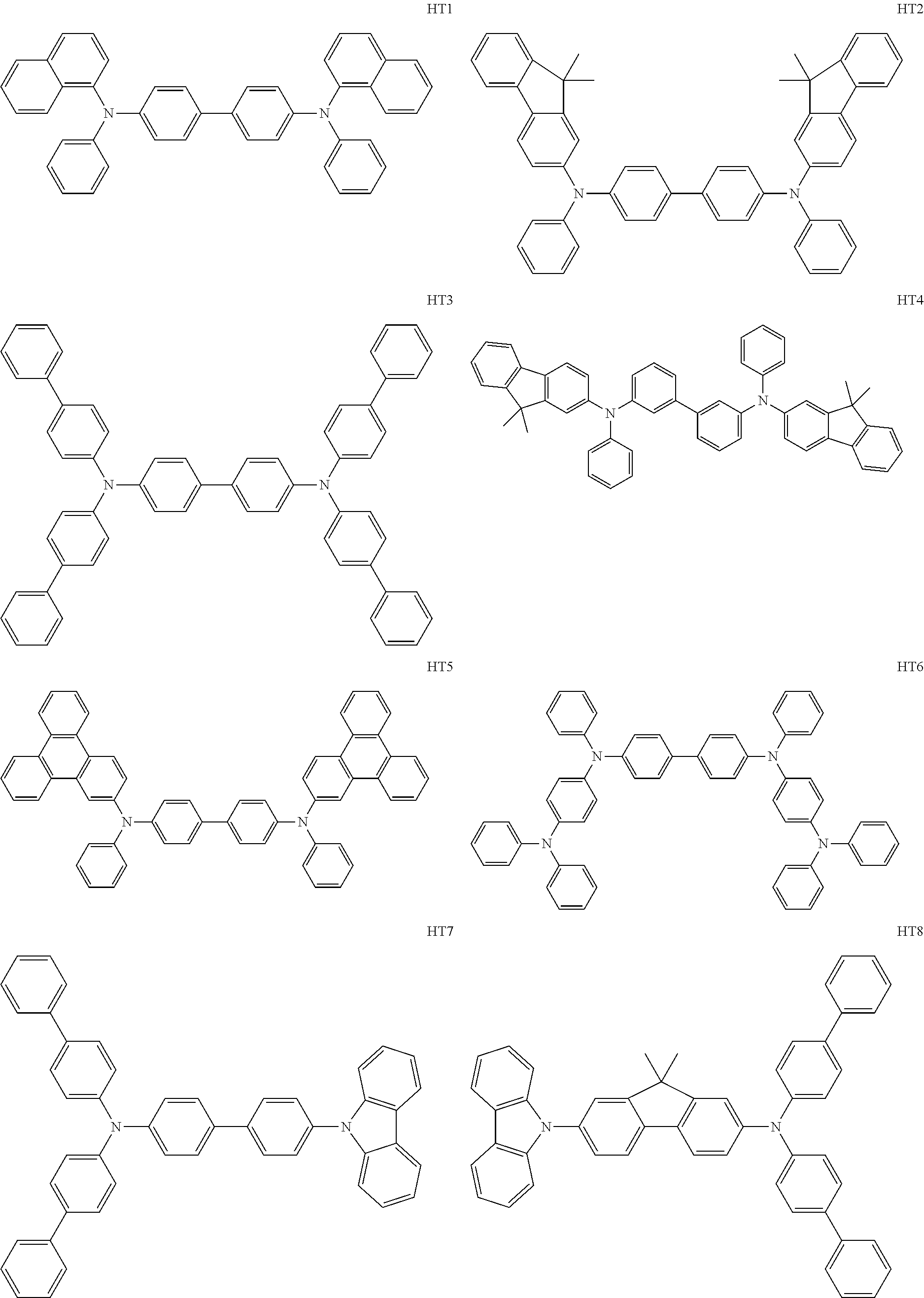

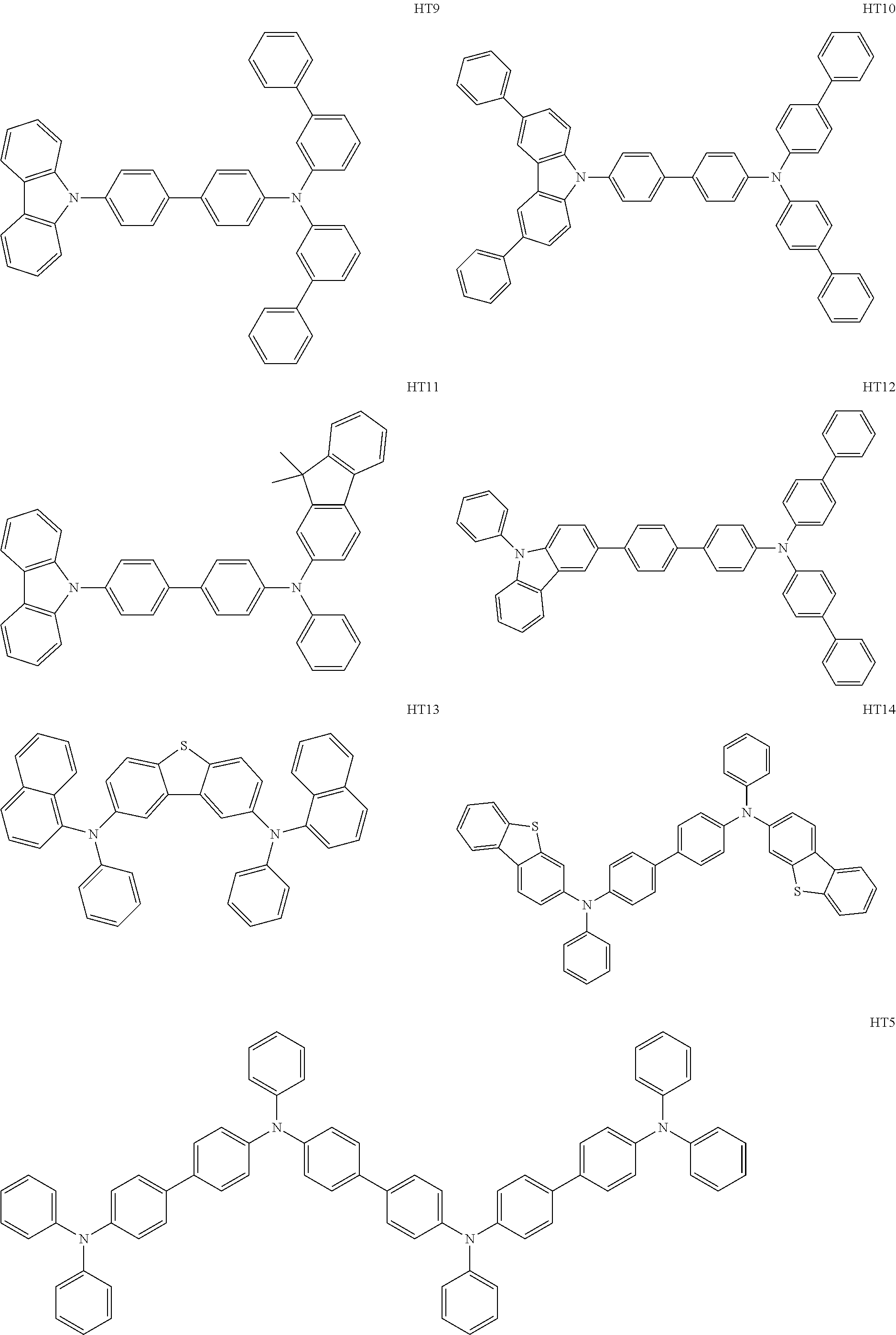

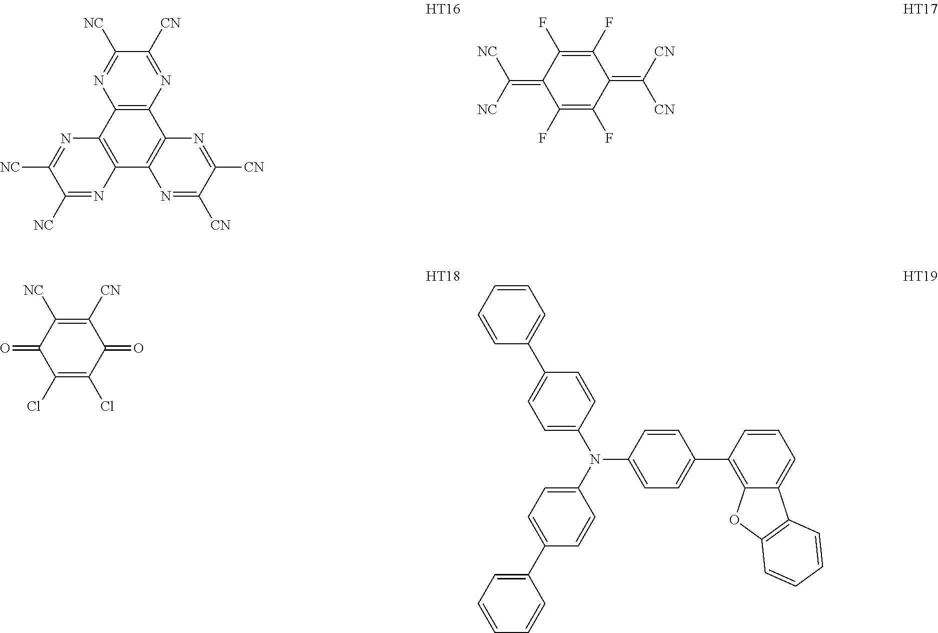 [SMILES: N#Cc1nc2c3nc(C#N)c(C#N)nc3c3nc(C#N)c(C#N)nc3c2nc1C#N ; N#CC(C#N)=c1c(F)c(F)c(=C(C#N)C#N)c(F)c1F ; N#CC1=C(C#N)C(=O)C(Cl)=C(Cl)C1=O ; c1ccc(-c2ccc(N(c3ccc(-c4ccccc4)cc3)c3ccc(-c4cccc5c4oc4ccccc45)cc3)cc2)cc1]

Examples of the light emitting material mainly related to the light emitting function include, in addition to the organic compound according to the present embodiment, a fused ring compound (such as a fluorene derivative, a naphthalene derivative, a pyrene derivative, a perylene derivative, a tetracene derivative, an anthracene derivative, or rubrene), a quinacridone derivative, a coumarin derivative, a stilbene derivative, an organic aluminum complex such as tris(8-quinolinolato)aluminum, an iridium complex, a platinum complex, a rhenium complex, a copper complex, a europium complex, a ruthenium complex, and a polymer derivative such as a poly(phenylenevinylene) derivative, a poly(fluorene) derivative, or a poly(phenylene) derivative. Specific examples of the compound used as the light emitting material are shown below, but the present invention is not limited thereto.

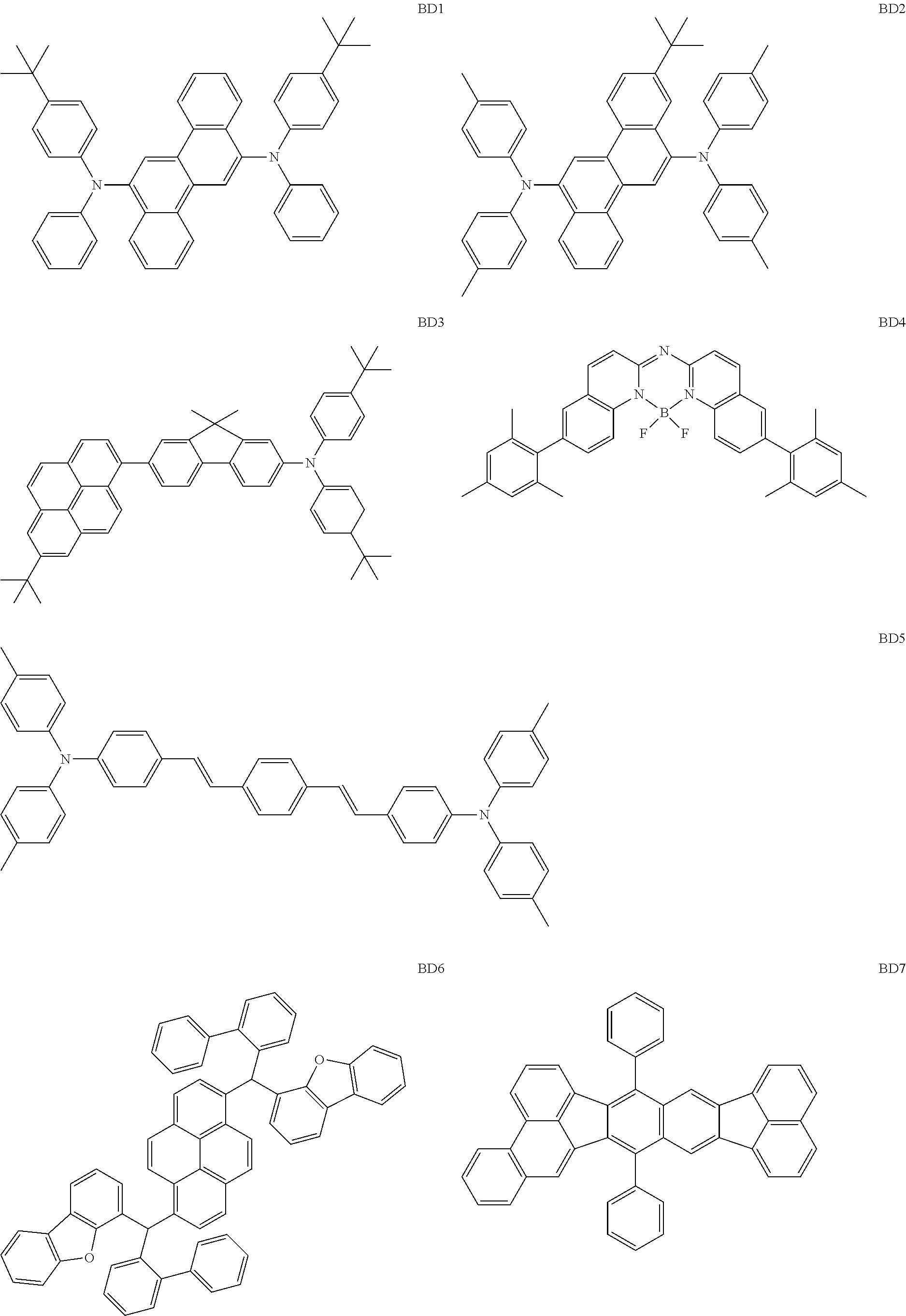

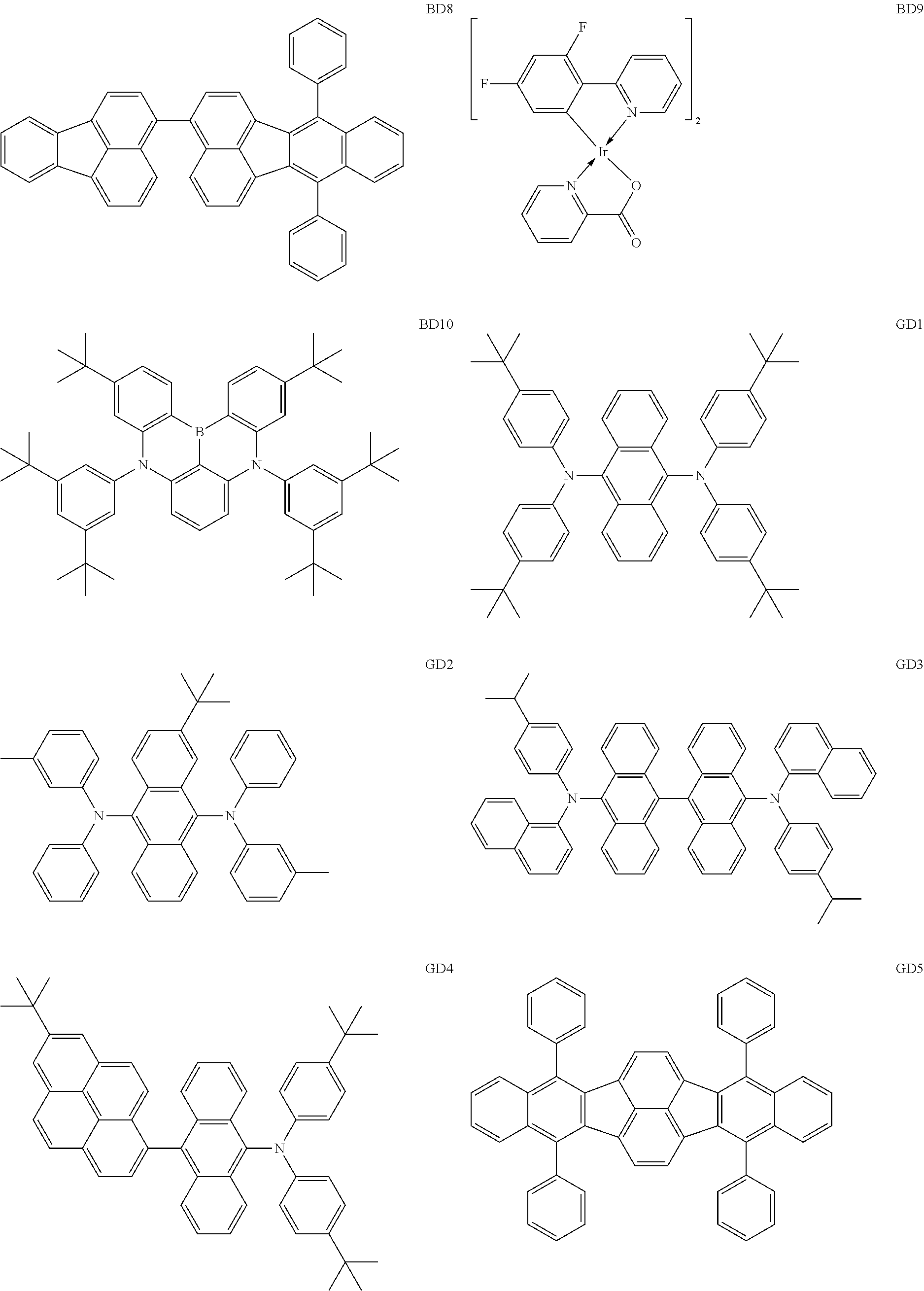

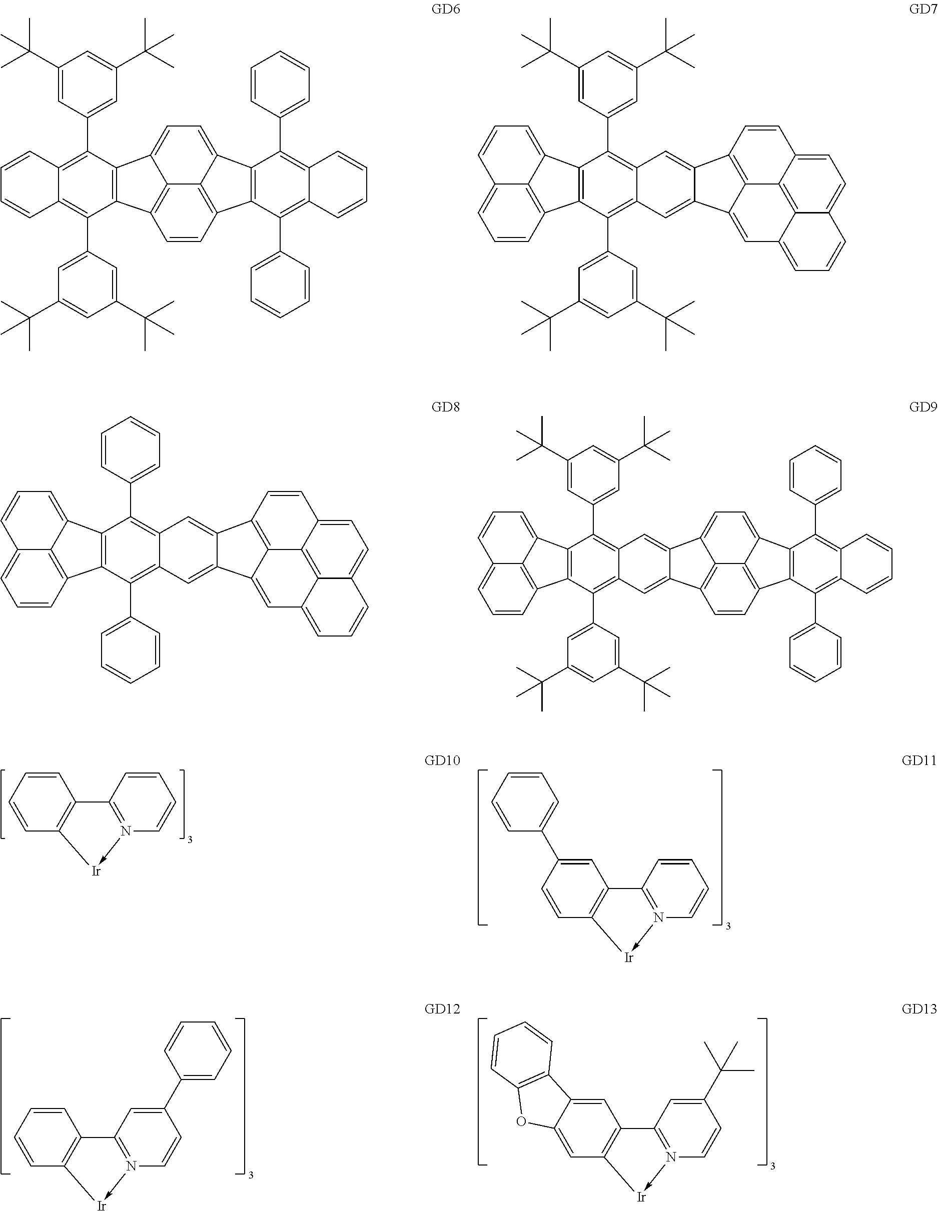

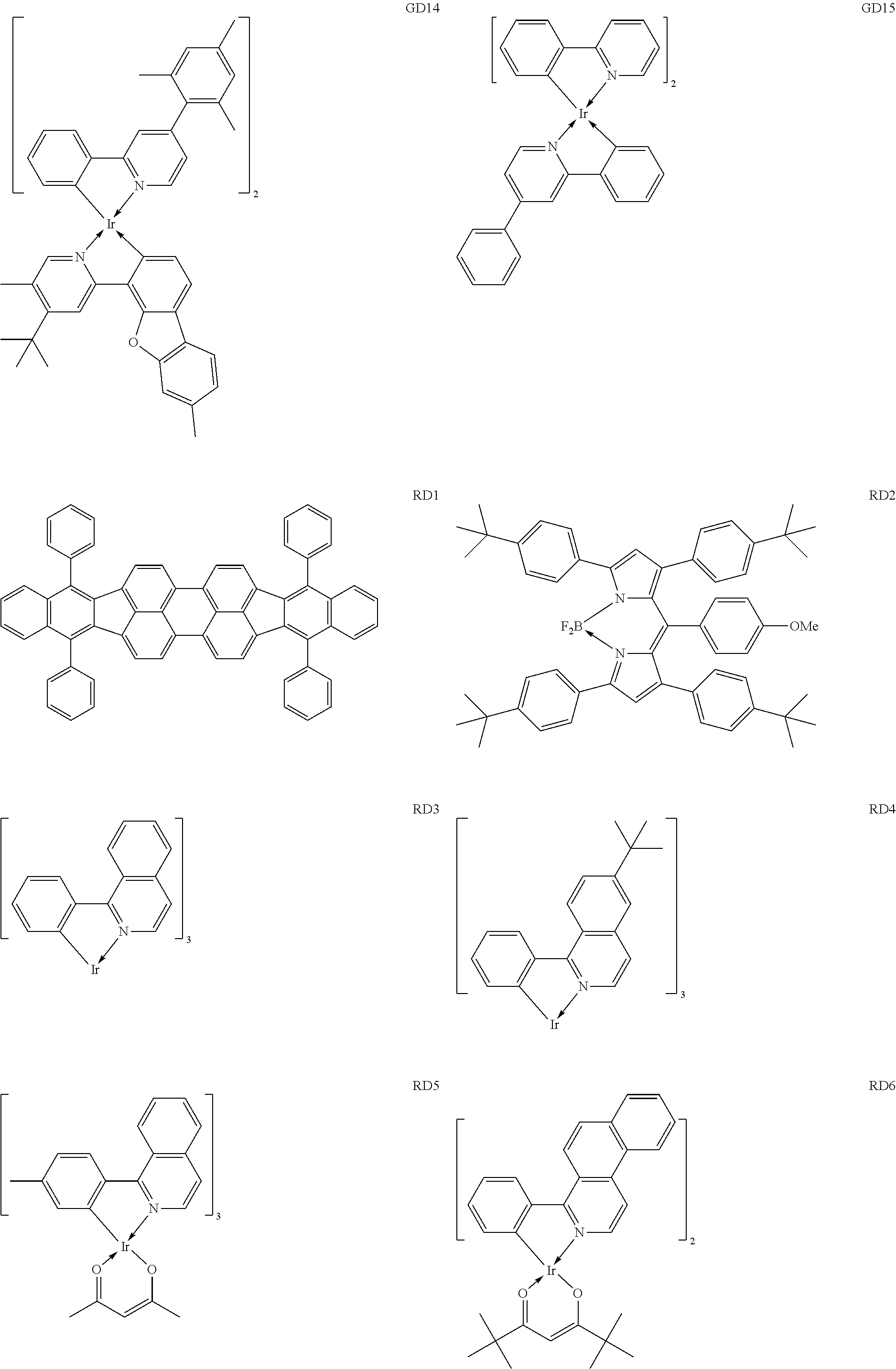

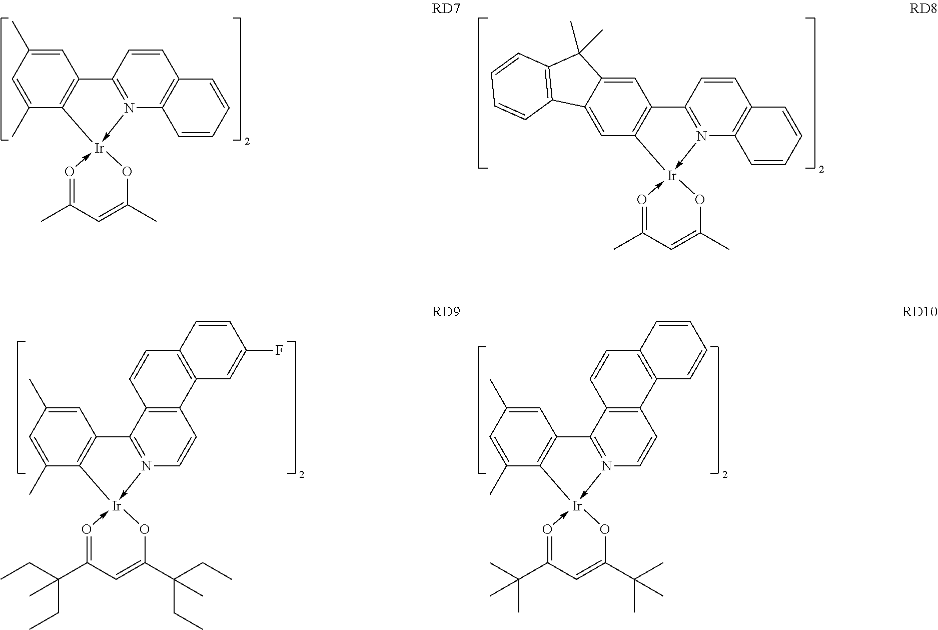

Examples of the host material or the assist material contained in the light emitting layer include, in addition to the materials belonging to Groups AA to CC shown above, an aromatic hydrocarbon compound and a derivative thereof, a carbazole derivative, a dibenzofuran derivative, a dibenzothiophene derivative, an organic aluminum complex such as tris(8-quinolinolato)aluminum, and an organic beryllium complex. Further, among the examples of the organometallic complex according to the present embodiment, EM28 and EM30 having the same xanthone skeleton are particularly preferable as the assist material in a case of the compound in which M(L₁) is represented by General Formulae [2] and [3]. Specific examples of the compound used as the host material or the assist material contained in the light emitting layer are shown below, but the present invention is not limited thereto.

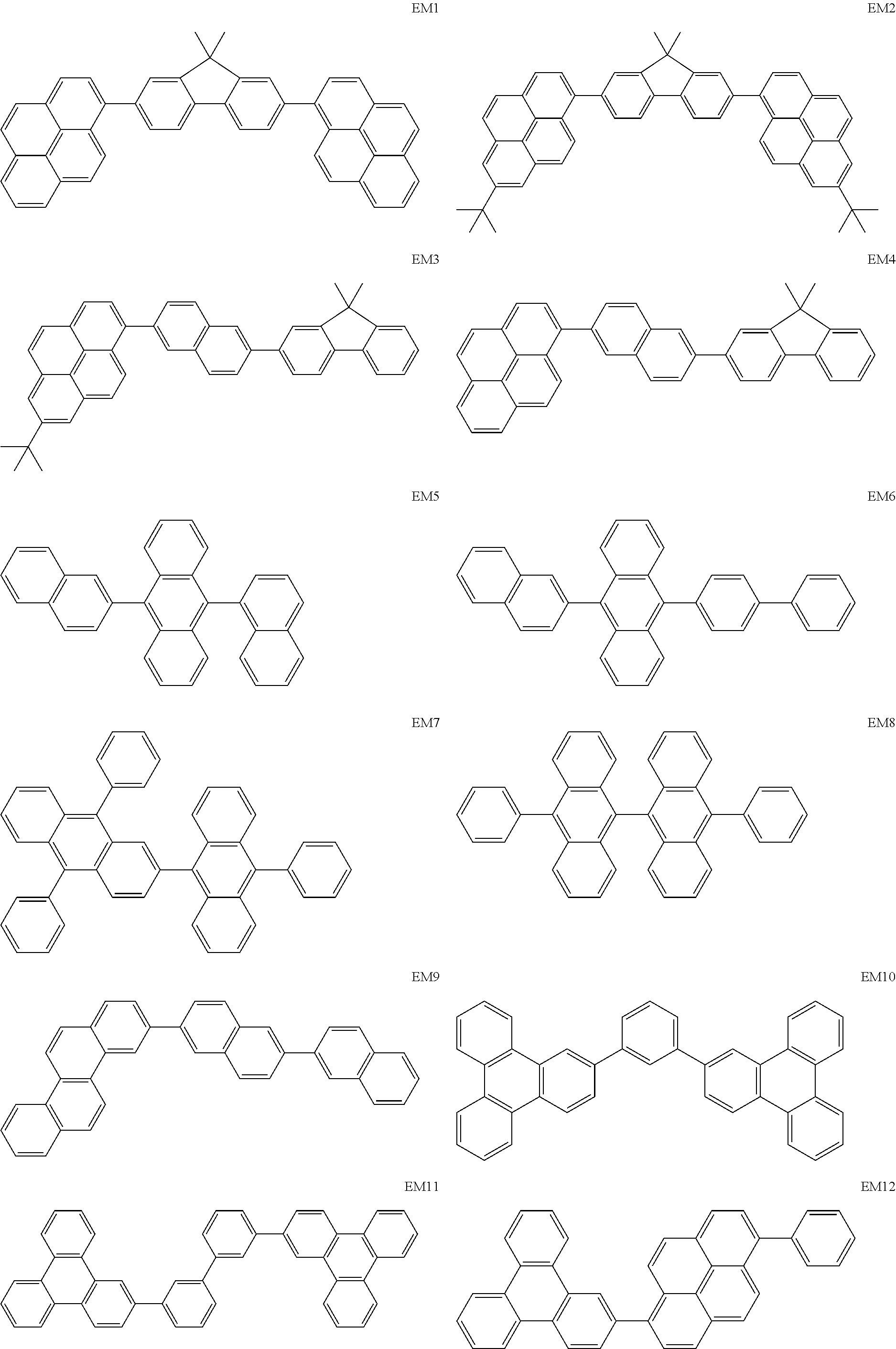

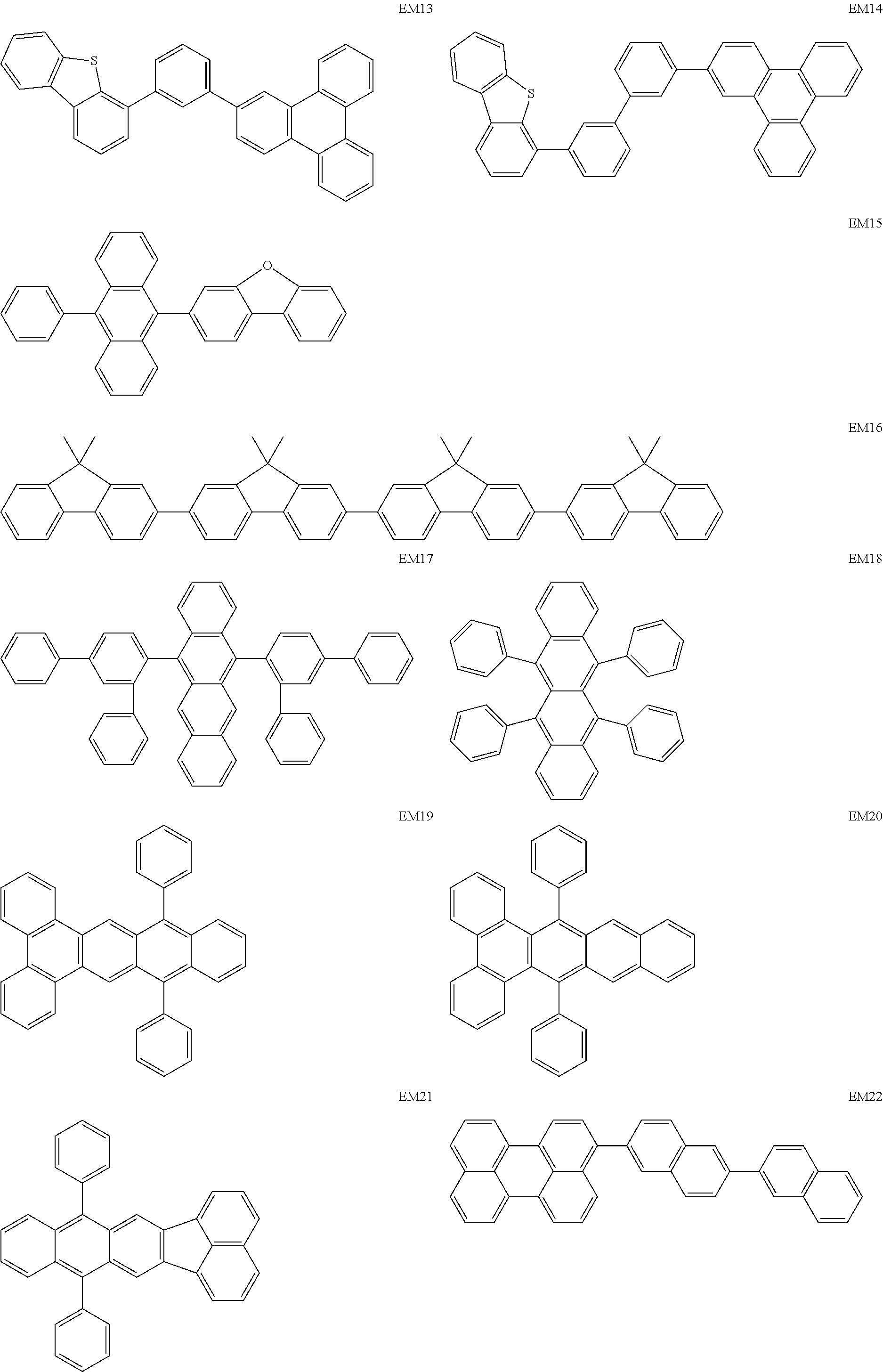

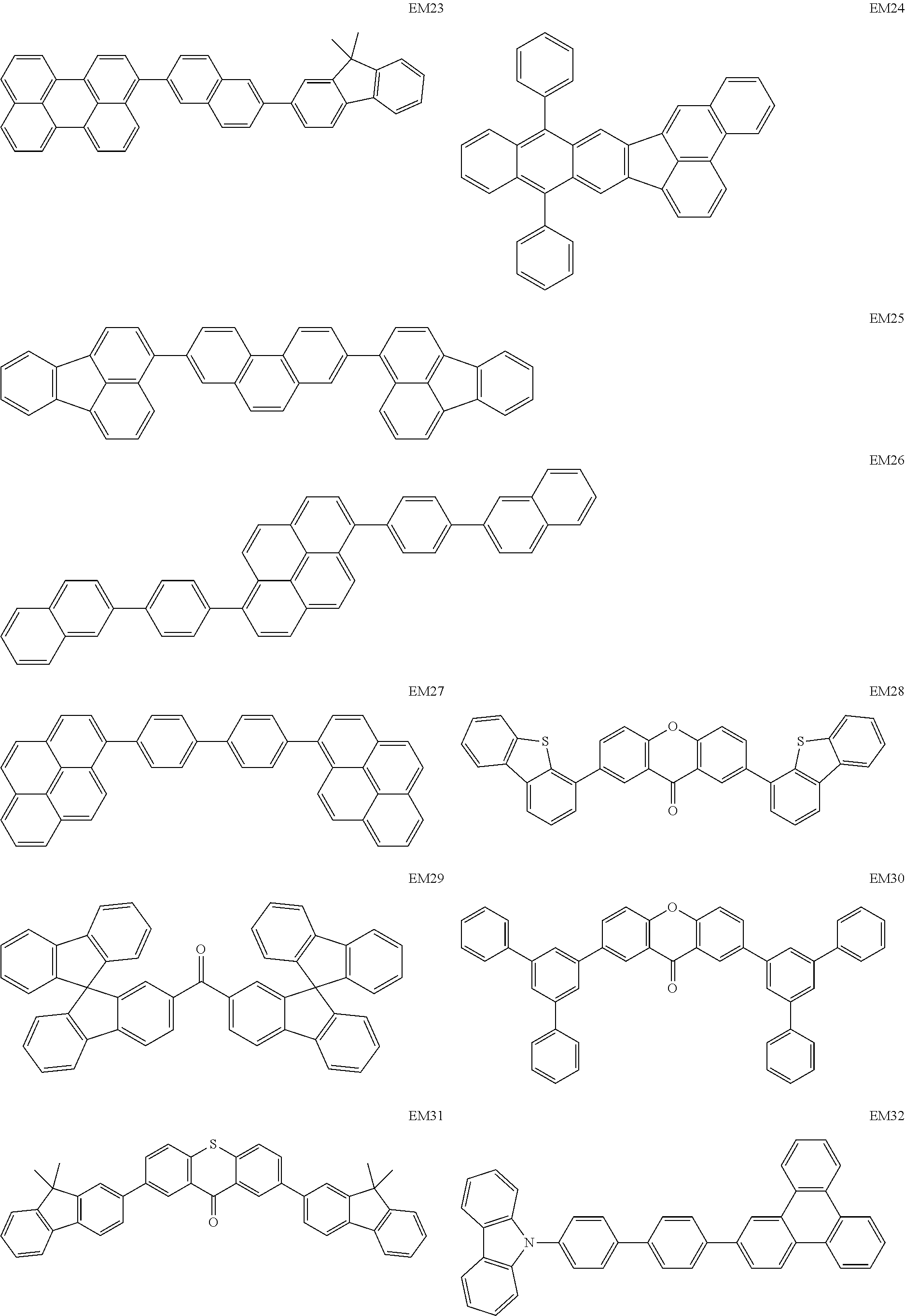

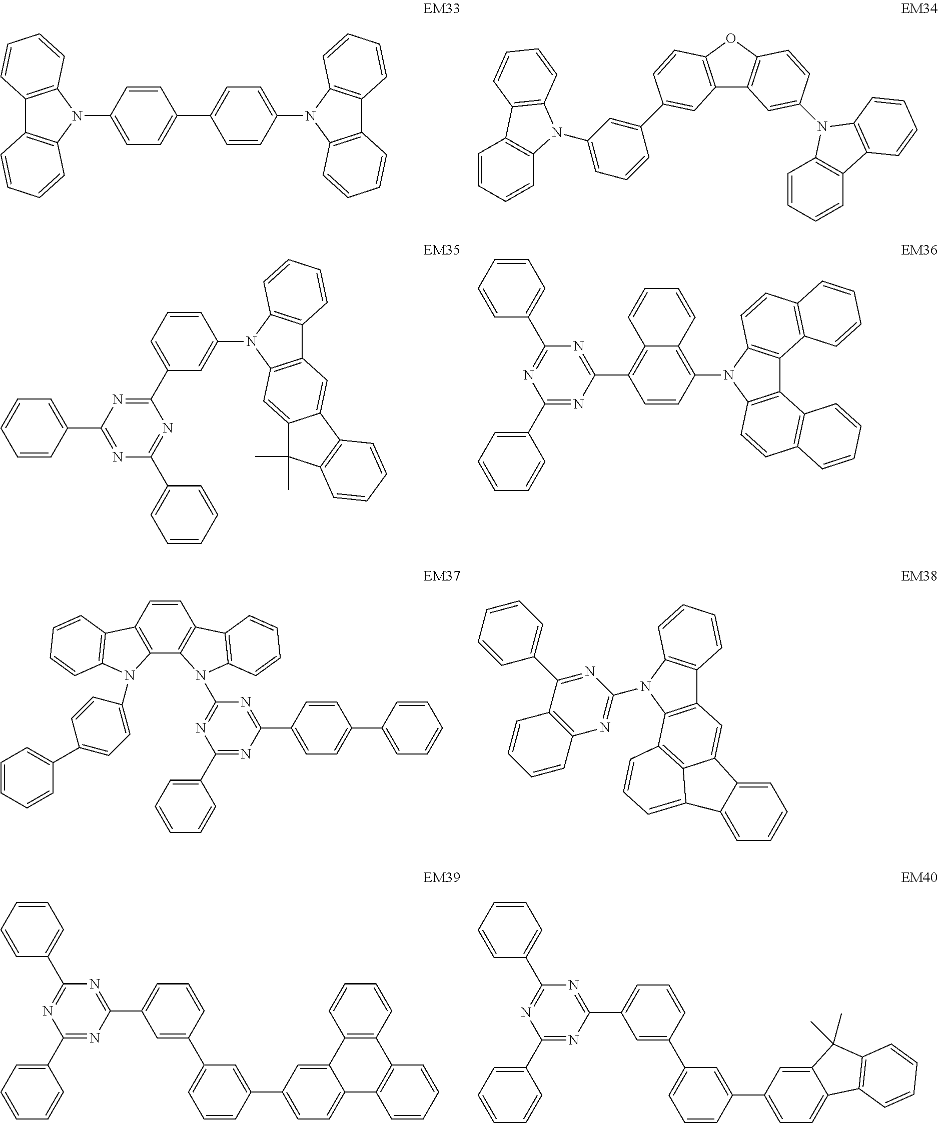

The electron transporting material can be arbitrarily selected from materials capable of transporting electrons injected from the cathode to the light emitting layer, and is selected in consideration of the balance or the like with the hole mobility of the hole transporting material. Examples of the material having an electron transporting ability include an oxadiazole derivative, an oxazole derivative, a pyrazine derivative, a triazole derivative, a triazine derivative, a quinoline derivative, a quinoxaline derivative, a phenanthroline derivative, an organic aluminum complex, and a fused ring compound (such as a fluorene derivative, a naphthalene derivative, a chrysene derivative, or an anthracene derivative). Further, the electron transporting material is also suitably used as the hole blocking layer. Specific examples of the compound used as the electron transporting material are shown below, but the present invention is not limited thereto.

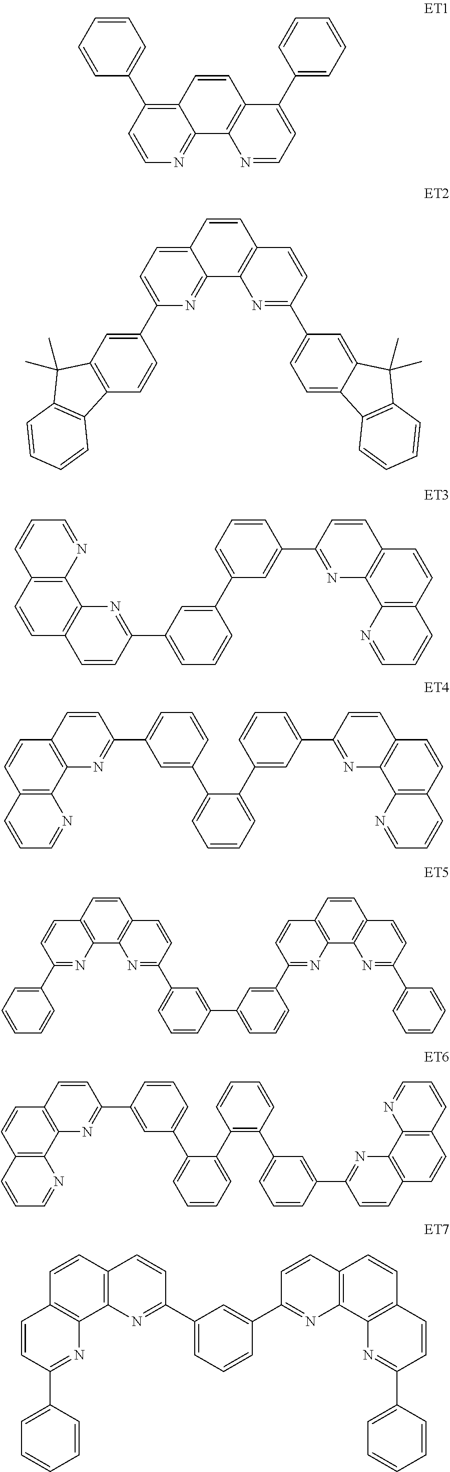

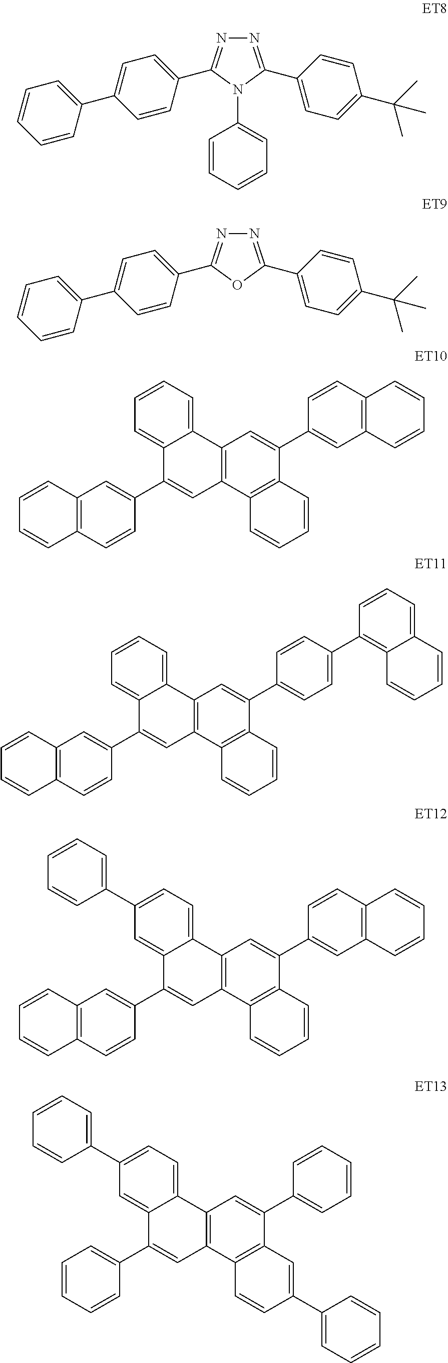

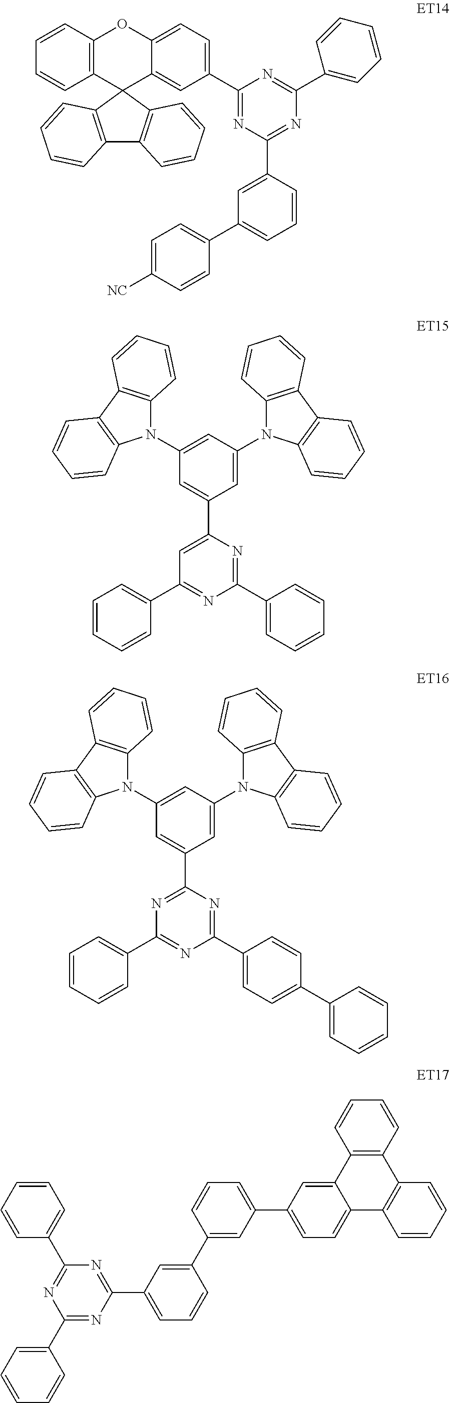

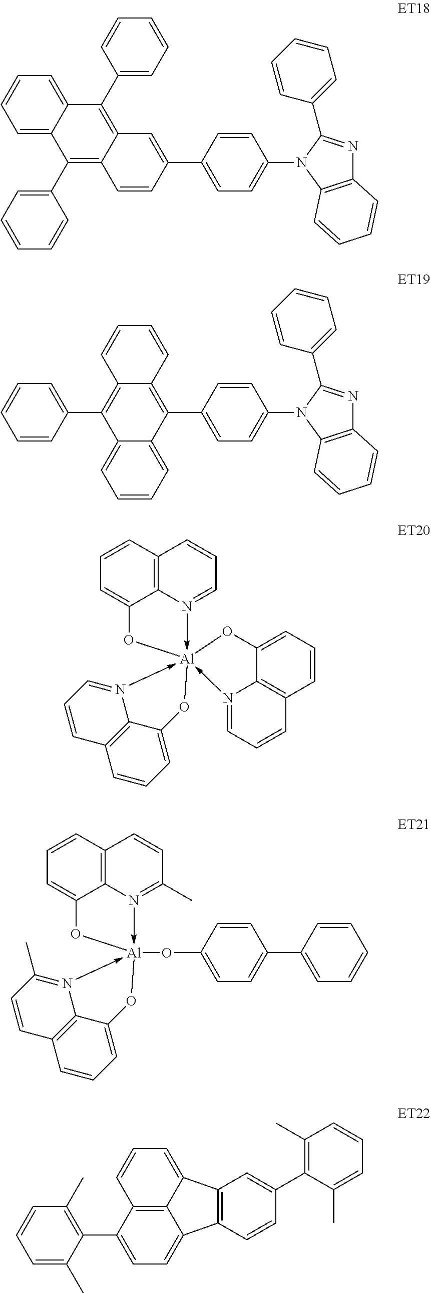

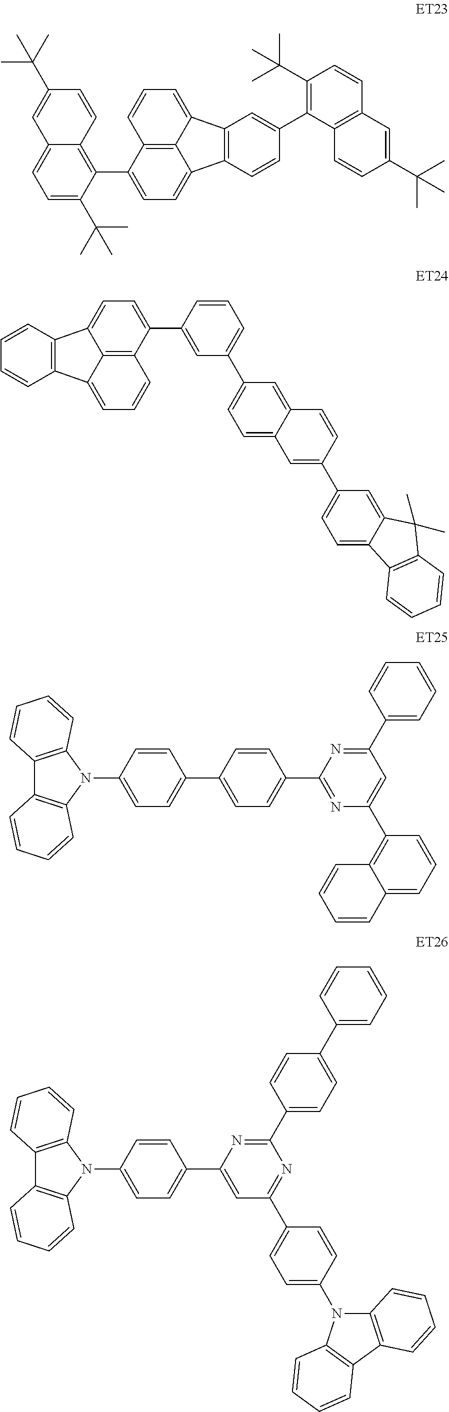

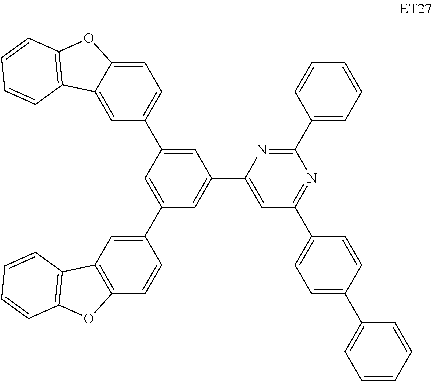 [SMILES: c1ccc(-c2ccc(-c3cc(-c4cc(-c5ccc6oc7ccccc7c6c5)cc(-c5ccc6oc7ccccc7c6c5)c4)nc(-c4ccccc4)n3)cc2)cc1]

### <Configuration of Organic Light Emitting Element>

The organic light emitting element is provided by forming an insulating layer, a first electrode, an organic compound layer, and a second electrode on a substrate. A protective layer, a color filter, a microlens, or the like may be provided on the second electrode. When a color filter is provided, a flattening layer may be provided between the color filter and the protective layer. The flattening layer can be formed of an acrylic resin or the like. The same applies to a case where the flattening layer is provided between the color filter and the microlens.

### [Substrate]

Examples of the substrate include quartz, glass, a silicon wafer, a resin, and a metal. Further, a switching element such as a transistor or a wiring is provided on the substrate, and an insulating layer may also be provided thereon. The insulating layer may be formed of any material as long as a contact hole can be formed such that a wiring can be formed between the insulating layer and the first electrode and insulation with an unconnected wiring can be ensured. For example, a resin such as polyimide, silicon oxide, silicon nitride, or the like can be used as the material of the insulating layer.

### [Electrode]

A pair of electrodes can be used as the electrodes. The pair of electrodes may be an anode and a cathode. When an electric field is applied in a direction in which the organic light emitting element emits light, the electrode with a higher potential is an anode and the other electrode is a cathode. Further, it can also be said that the electrode supplying holes to the light emitting layer is an anode and the electrode supplying electrons to the light emitting layer is a cathode.

A material having a work function as large as possible is suitable as the constituent material for the anode. Examples of such a material include a single metal such as gold, platinum, silver, copper, nickel, palladium, cobalt, selenium, vanadium, or tungsten, a mixture containing these metals, an alloy obtained by combining these metals, and a metal oxide such as tin oxide, zinc oxide, indium oxide, indium tin oxide (ITO), or indium zinc oxide. Further, a conductive polymer such as polyaniline, polypyrrole, or polythiophene can also be used.

These electrode materials may be used alone or in combination of two or more kinds thereof. Further, the anode may be formed of a single layer or a plurality of layers.

For example, a material obtained by laminating chromium, aluminum, silver, titanium, tungsten, molybdenum, or an ally thereof can be used when the material is used as a reflective electrode. The above-described material can function as a reflective film without having a role of an electrode. Further, a transport conductive layer formed of an oxide such as indium tin oxide (ITO) or indium zinc oxide can be used when the material is used as a transparent electrode, but the present invention is not limited thereto. The electrode can be formed by using a photolithography technique.

Meanwhile, a material having a small work function is preferable as the constituent material for the cathode. Examples thereof include an alkali metal such as lithium, an alkaline earth metal such as calcium, a single metal such as aluminum, titanium, manganese, silver, lead, or chromium, and a mixture thereof. Alternatively, an alloy obtained by combining these single metals can also be used. For example, magnesium-silver, aluminum-lithium, aluminum-magnesium, silver-copper, zinc-silver, or the like can be used. A metal oxide such as indium tin oxide (ITO) can also be used. These electrode materials may be used alone or in combination of two or more kinds thereof. Further, the cathode may be formed of a single layer or a plurality of layers. Among the examples, it is preferable to use silver and more preferable to use a silver alloy from the viewpoint of reducing aggregation of silver. The alloy ratio is not limited as long as the aggregation of silver can be reduced. For example, the alloy ratio of silver to other metals may be 1:1, 3:1, or the like.

The cathode may be used as a top emission element by using an oxide conductive layer such as ITO or a bottom emission element by using a reflective electrode such as aluminum (A1), and the use thereof is not particularly limited. A method of forming the cathode is not particularly limited, but it is preferable to use a direct current sputtering method or an alternating current sputtering method from the viewpoint that the film coverage is satisfactory and the resistance is easily lowered.

### [Organic Compound Layer]

The organic compound layer may be formed of a single layer or a plurality of layers. In a case where the organic compound layer is formed of a plurality of layers, the layers may be referred to as a hole injection layer, a hole transport layer, an electron blocking layer, a light emitting layer, a hole blocking layer, an electron transport layer, and an electron injection layer depending on the functions thereof. The organic compound layer is formed of an organic compound, but may contain inorganic atoms and inorganic compounds. For example, the organic compound layer may contain copper, lithium, magnesium, aluminum, iridium, platinum, molybdenum, zinc, or the like. The organic compound layer may be disposed between the first electrode and the second electrode or may be disposed in contact with the first electrode and the second electrode.

The organic compound layer (such as a positive hole injection layer, a positive hole transport layer, an electron blocking layer, a light emitting layer, a positive hole blocking layer, an electron transport layer, or an electron injection layer) constituting the organic light emitting element according to an embodiment of the present invention is formed by the following method.

The organic compound layer constituting the organic light emitting element according to an embodiment of the present invention can be formed by a dry process such as a vacuum deposition method, an ionization deposition method, a sputtering method, or a plasma method. Further, a wet process of dissolving the material in an appropriate solvent to form a layer by a known coating method (such as a spin coating method, a dipping method, a cast method, an LB method, or an ink jet method) can also be used in place of the dry process.

Here, when a layer is formed by a vacuum deposition method or a solution coating method, crystallization or the like is unlikely to occur and temporal stability is excellent. Further, a film can also be formed by combining the material with an appropriate binder resin when the film formation is performed by a coating method.

Examples of the binder resin include a polyvinyl carbazole resin, a polycarbonate resin, a polyester resin, an ABS resin, an acrylic resin, a polyimide resin, a phenol resin, an epoxy resin, a silicon resin, and a urea resin, but the present invention is not limited thereto.

Further, these binder resins may be used alone or in the form of a mixture of two or more kinds thereof, as a homopolymer or a copolymer. Further, the binder resins may be used in combination with known additives such as a plasticizer, an antioxidant, and an ultraviolet absorbing agent as necessary.

### [Protective Layer]

A protective layer may be provided on the second electrode. For example, infiltration of water or the like to the organic compound layer can be reduced by making glass provided with a moisture absorbent adhere onto the second electrode, and thus occurrence of display failure can be reduced. Further, as another embodiment, a passivation film formed of silicon nitride or the like is provided on the second electrode so that the infiltration of water or the like to the organic compound layer may be reduced. For example, the second electrode is formed and transported to another chamber without breaking the vacuum, and a silicon nitride film having a thickness of 2 μm is formed by a CVD method and then used as a protective layer. A protective layer may be provided by an atomic layer deposition method (ALD method) after film formation using the CVD method. The material of the film obtained by the ALD method is not limited, and examples thereof include silicon nitride, silicon oxide, and aluminum oxide. Silicon nitride may be further formed by the CVD method on the film formed by the ALD method. The film formed by the ALD method may be a film thickness less than the film thickness of the film formed by the CVD method. Specifically, the film thickness of the film formed by the ALD method may be 50% or less or 10% or less of the film thickness of the film formed by the CVD method.

### [Color Filter]

A color filter may be provided on the protective layer. For example, a color filter prepared in consideration of the size of the organic light emitting element is provided on another substrate and this substrate and the substrate provided with the organic light emitting element may be bonded to each other, or a color filter may be patterned on the protective layer described above using a photolithography technique. The color filter may be formed of high molecules.

### [Flattening Layer]

A flattening layer may be provided between the color filter and the protective layer. The flattening layer is provided for the purpose of reducing the unevenness of the underlying layer. The flattening layer is also referred to as a material resin layer in some cases without limiting the purpose thereof. The flattening layer may be formed of an organic compound, low molecules, or high molecules, but it is preferable that the flattening layer be formed of high molecules.

The flattening layer may be provided above and below the color filter, and the constituent materials may be the same as or different from each other. Specific examples of the constituent materials include a polyvinyl carbazole resin, a polycarbonate resin, a polyester resin, an ABS resin, an acrylic resin, a polyimide resin, a phenol resin, an epoxy resin, a silicon resin, and a urea resin.

### [Microlens]

The organic light emitting element or the organic light emitting device may include an optical member such as a microlens on a light emission side thereof. The microlens can be formed of an acrylic resin, an epoxy resin, or the like. The purpose of the microlens may be to increase the amount of light extracted from the organic light emitting element or the organic light emitting device and to control the direction of light to be extracted. The microlens may have a hemispherical shape. When the microlens has a hemispherical shape, a tangent line in parallel with an insulating layer is present among tangent lines in contact with the hemisphere, and the contact point between the tangent line and the hemisphere is the apex of the microlens. The apex of the microlens can be similarly determined in any cross-sectional view. That is, a tangent line in parallel with an insulating layer is present among tangent lines in contact with the semicircle of the microlens in a cross-sectional view, and the contact point between the tangent line and the semicircle is the apex of the microlens.

Further, a midpoint of the microlens can also be defined. In a cross section of the microlens, a line segment from a point where the shape of a circular arc ends to a point where the shape of another circular arc ends is assumed, and the midpoint of the line segment can be referred to as the midpoint of the microlens. The cross section that determines the apex and the midpoint may be a cross section perpendicular to the insulating layer.

### [Counter Substrate]

A counter substrate may be provided on the flattening layer. The counter substrate is provided at a position corresponding to the substrate described above, and thus is referred to as a counter substrate. The constituent material for the counter substrate may be the same as the constituent material of the substrate described above. The counter substrate may be a second substrate when the above-described substrate is defined as a first substrate.

### [Pixel Circuit]

The organic light emitting device including the organic light emitting element may include a pixel circuit connected to the organic light emitting element. The pixel circuit may be of an active matrix type to control light emission of each of the first light emitting element and the second light emitting element independently. The active matrix type circuit may be of a voltage programming type or a current programming type. The driving circuit has a pixel circuit for each pixel. The pixel circuit may have a light emitting element, a transistor that controls light emission brightness of the light emitting element, a transistor that controls the emission timing, a capacity that maintains the gate voltage of the transistor controlling the light emission brightness, and a transistor for connection to GND without using the light emitting element.

The magnitude of the driving current may be determined according to the size of a light emitting region. Specifically, the value of the current flowing through the first light emitting element may be less than the value of the current flowing through the second light emitting element when the first light emitting element and the second light emitting element emit light with the same brightness. The reason for this is that the required current is small in some cases due to a small light emitting region.

### [Pixel]

The organic light emitting device including the organic light emitting element may have a plurality of pixels. The pixels have subpixels emitting light of different colors. The subpixels may each have emission colors of red, green, and blue.

The pixel has a region emitting light, which is also referred to as a pixel aperture. The region is the same as a first region. The pixel aperture may be 5 μm or greater and 15 μm or less. More specifically, the pixel aperture may be 11 μm, 9.5 μm, 7.4 μm, 6.4 μm, or the like. The pixel aperture between subpixels may be 10 μm or less, and specifically, 8 μm, 7.4 μm, or 6.4 μm.

The pixel can employ a known arrangement form in plan view. Examples of the arrangement form include stripe arrangement, delta arrangement, pentile arrangement, and Bayer arrangement. The subpixel may employ any of known shapes in plan view. Examples thereof include a quadrangular shape such as a rectangular shape or a rhombus shape, and a hexagonal shape. Further, the rectangular shape includes a shape that is close to a rectangle without being required to have an exact figure. The shapes of subpixels and the pixel arrangements can be used in combination.

### Applications of Organic Light Emitting Element According to Present Embodiment

The organic light emitting element according to the present embodiment can be used as a constituent member of a display device or a lighting device. Further, the organic light emitting element can also be used as an exposure light source of an electrophotographic image forming apparatus, a backlight of a liquid crystal display device, a light emitting device having a color filter in white light source, or the like.

The display device may be an image information processing device that includes an image input unit inputting image information from an area CCD, a linear CCD, a memory card, or the like and an image processing unit processing the input information and displays the input image on a display unit. The display device has a plurality of pixels, and at least one of the plurality of pixels may include the organic light emitting element according to the present embodiment and a transistor connected to the organic light emitting element.

Further, a display unit of an imaging device or an ink jet printer may have a touch panel function. The driving type of this touch panel function is not particularly limited, and may be an infrared type, a capacitance type, a resistive film type, or an electromagnetic induction type. Further, the display device may be used as a display unit of a multi-function printer.

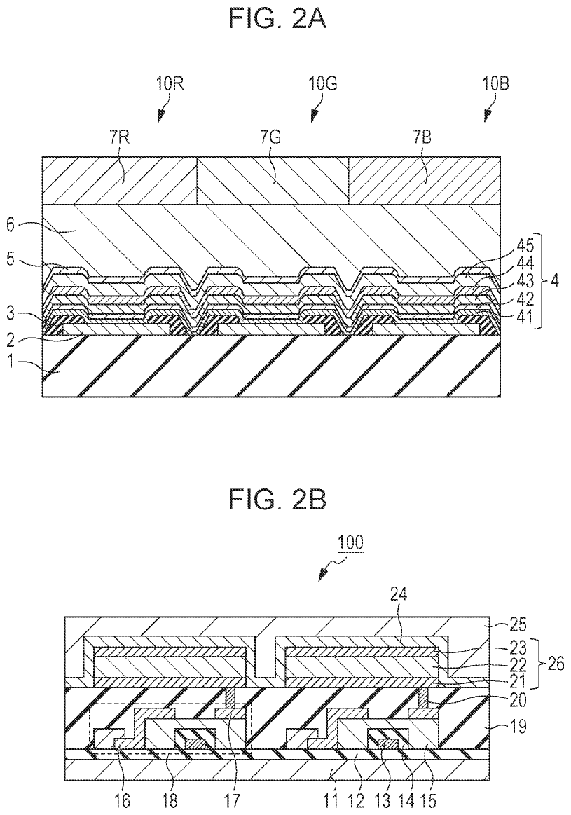

Next, the display device according to the present embodiment will be described with reference to the accompanying drawings. FIGS. 2A and 2B are schematic cross-sectional views showing an example of a display device that includes an organic light emitting element and a transistor connected to the organic light emitting element. The transistor is an example of an active element. The transistor may be a thin film transistor (TFT).

FIG. 2A shows an example of a pixel as a constituent element of the display device according to the present embodiment. The pixel includes subpixels 10. The subpixels are divided into 10R, 10G, and 10B depending on the light emission thereof. The emission color of may be distinguished by the wavelength of light emitted from the light emitting layer, and light emitted from the subpixels may be selectively transmitted or may undergo color conversion through a color filter or the like. Each of the subpixels 10 includes a reflective electrode serving as a first electrode 2 on an interlayer insulating layer 1, an insulating layer 3 covering an end of the first electrode 2, an organic compound layer 4 covering the first electrode 2 and the insulating layer 3, a transparent electrode serving as a second electrode 5, a protective layer 6, and a color filter 7.

The interlayer insulating layer 1 has a transistor and a capacitive element below or inside the layer. The transistor and the first electrode 2 may be electrically connected to each other via a contact hole (not shown).

The insulating layer 3 is also referred to as a bank or a pixel separation film. The insulating layer 3 covers an end of the first electrode 2 and is disposed to surround the first electrode 2. A portion where the insulating layer 3 is not provided is a light emitting region that is in contact with the organic compound layer 4.

The organic compound layer 4 includes a positive hole injection layer 41, a positive hole transport layer 42, a first light emitting layer 43, a second light emitting layer 44, and an electron transport layer 45.

The second electrode 5 may be a transparent electrode or a reflective electrode or may be a semi-transparent electrode.

The protective layer 6 reduces infiltration of moisture to the organic compound layer 4. The protective layer 6 is shown to be formed of a single layer, but may be formed of a plurality of layers. Each layer may be formed of an inorganic compound layer and an organic compound layer.

The color filter 7 is divided into 7R, 7G, and 7B depending on the color thereof. The color filter 7 may be formed on a flattening film (not shown). Further, a resin protective layer (not shown) may be provided on the color filter 7. Further, the color filter 7 may be formed on the protective layer 6. Alternatively, the color filter 7 may be provided on a counter substrate such as a glass substrate to be bonded thereto.

A display device 100 of FIG. 2B includes an organic light emitting element 26 and a TFT 18 as an example of a transistor. The display device 100 also includes a substrate 11 such as glass or silicon and an insulating layer 12 on the substrate 11. An active element such as the TFT 18 is disposed on the insulating layer 12, and a gate electrode 13 of the active element, a gate insulating film 14, and a semiconductor layer 15 are disposed on the insulating layer 12. The TFT 18 is also formed of a drain electrode 16 and a source electrode 17. An insulating film 19 is provided on the TFT 18. An anode 21 constituting the organic light emitting element 26 and the source electrode 17 are connected to each other via a contact hole 20 provided on the insulating film 19.

In addition, the electrical connection type between electrodes (the anode 21 and a cathode 23) of the organic light emitting element 26 and electrodes (the source electrode 17 and the drain electrode 16) of the TFT 18 is not limited to the aspect shown in FIG. 2B. That is, any one of the anode 21 or the cathode 23 and any one of the source electrode 17 and the drain electrode 16 of the TFT 18 may be electrically connected. The TFT denotes a thin film transistor.

In the display device 100 of FIG. 2B, the organic compound layer 22 is shown to be formed of one layer, but the organic compound layer 22 may be formed of a plurality of layers. A first protective layer 24 or a second protective layer 25 is provided on the cathode 23 in order to reduce deterioration of the organic light emitting element 26.

In the display device 100 of FIG. 2B, a transistor is used as a switching element, but a different element may also be used as a switching element.

Further, the transistor used in the display device 100 of FIG. 2B is not limited to a transistor obtained by using a single crystal silicon wafer, but may be a thin film transistor having an active layer on an insulating surface of a substrate. Examples of the active layer include single crystal silicon, non-single crystal silicon such as amorphous silicon or microcrystalline silicon, and a non-single crystal oxide semiconductor such as an indium zinc oxide or an indium gallium zinc oxide. Further, the thin film transistor is also referred to as a TFT element.

The transistor in the display device 100 of FIG. 2B may be formed in a substrate such as a Si substrate. Here, the expression “formed in a substrate” denotes that a transistor is prepared by processing the substrate such as a Si substrate. That is, the concept of the transistor being formed in a substrate can also denote that the substrate and the transistor are integrally formed.

The light emission brightness of the organic light emitting element according to the present embodiment is controlled by the TFT which is an example of a switching element, and in a case where a plurality of the organic light emitting elements are provided in a plane, an image can be displayed by the light emission brightness of each organic light emitting element. Further, the switching element according to the present embodiment is not limited to a TFT, and may be a transistor formed of low-temperature polysilicon or an active matrix driver formed on a substrate such as a Si substrate. The formation can be made not only on the substrate but also in the substrate. Whether the transistor is provided in the substrate or the TFT is used is selected depending on the size of the display unit, and it is preferable that the organic light emitting element be provided on a Si substrate when the size of the display unit is, for example, about 0.5 inches.

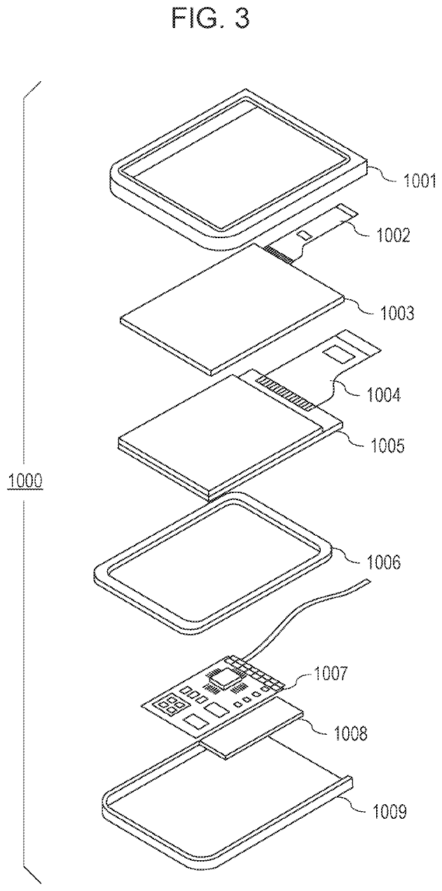

FIG. 3 is a schematic view showing an example of the display device according to the present embodiment. A display device 1000 may include a touch panel 1003, a display panel 1005, a frame 1006, a circuit board 1007, and a battery 1008 between an upper cover 1001 and a lower cover 1009. Flexible printed circuits FPC 1002 and 1004 are respectively connected to the touch panel 1003 and the display panel 1005. A transistor is printed on the circuit board 1007. The battery 1008 may not be provided unless the display device is a portable device, and may be provided at a different position even when the display device is a portable device.

The display device according to the present embodiment may include color filters having a red color, a green color, and a blue color. The color filter may be provided such that the red color, the green color, and the blue color are arranged in delta arrangement.

The display device according to the present embodiment may be used as a display unit of a portable terminal. In this case, the display device may have both a display function and an operation function. Examples of the portable terminal include a mobile phone such as a smartphone, a tablet, and a head-mounted display.

The display device according to the present embodiment may be used as a display unit of an imaging device including an optical unit that has a plurality of lenses and an imaging element that receives light having passed through the optical unit. The imaging device may include a display unit displaying information acquired by the imaging element. Further, the display unit may be a display unit exposed to the outside of the imaging device or a display unit disposed in a viewfinder. The imaging device may be a digital camera or a digital video camera.

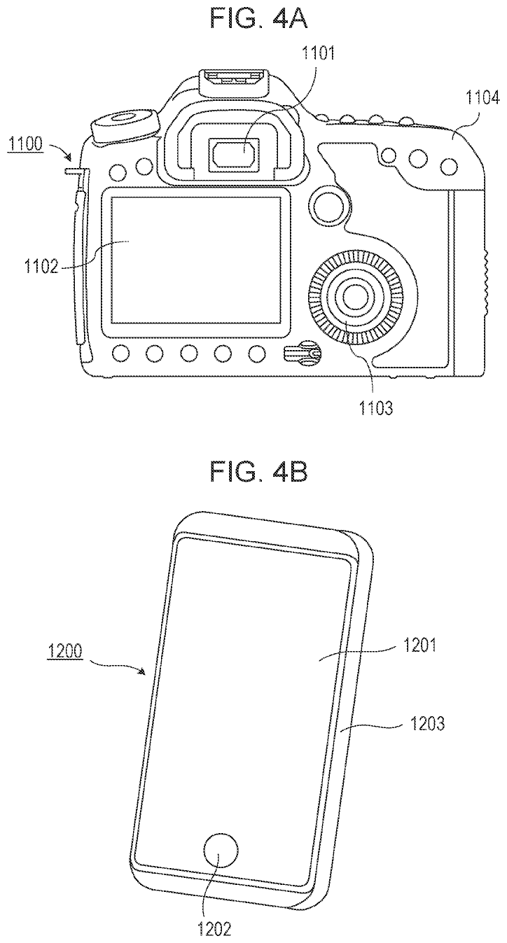

FIG. 4A is a schematic view showing an example of an imaging device according to the present embodiment. An imaging device 1100 may include a viewfinder 1101, a rear display 1102, an operation unit 1103, and a housing 1104. The viewfinder 1101 may include the display device according to the present embodiment. In this case, the display device may display not only an image to be imaged but also environmental information, imaging instructions, and the like. The environmental information may include the intensity of external light, the orientation of external light, the moving speed of a subject, and the possibility that a subject is shielded by a shielding material.

The suitable timing for imaging is only a short time, and thus information is required to be displayed as early as possible. Therefore, it is preferable that a display device formed of the organic light emitting element according to the present embodiment be used from the viewpoint that the organic light emitting element has a fast response speed. The display device formed of the organic light emitting element can be more suitably used than these devices and a liquid crystal display device required to have a high display speed.

The imaging device 1100 includes an optical unit (not shown). The optical unit includes a plurality of lenses and forms an image on an imaging element accommodated in the housing 1104. The focal point can be adjusted by adjusting the relative positions of the plurality of lenses. This operation can also be automatically performed. The imaging device may also be referred to as a photoelectric conversion device. The photoelectric conversion device is capable of capturing an image, without capturing images sequentially, by an imaging method such as a method of detecting a difference from a previous image or a method of cutting out an image from an image constantly recorded.

FIG. 4B is a schematic view showing an example of an electronic device according to the present embodiment. An electronic device 1200 includes a display unit 1201, an operation unit 1202, and a housing 1203. The housing 1203 may include a circuit, a printed circuit board including the circuit, a battery, and a communication unit. The operation unit 1202 may be in the form of a button or may be a touch panel type reaction unit. The operation unit 1202 may be a biometric authentication unit that identifies fingerprints, performs unlocking, and the like. The electronic device including a communication unit can also be used as a communication device. The electronic device 1200 may further have a camera function by including a lens and an imaging element. An image captured using a camera function is displayed on the display unit 1201. Examples of the electronic device 1200 include a smartphone and a notebook computer.

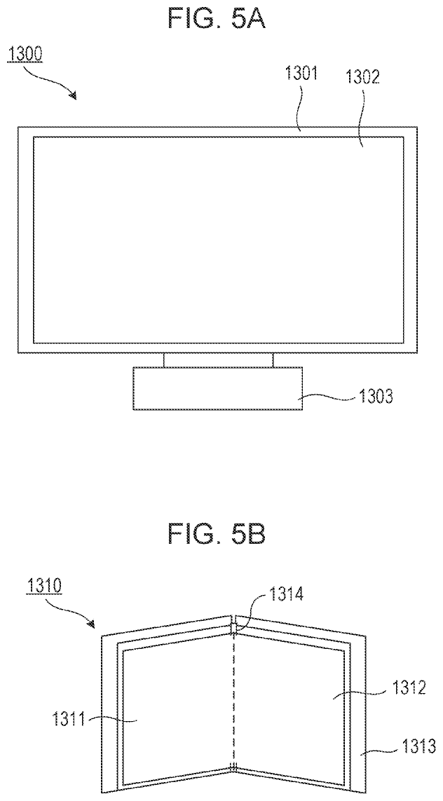

FIGS. 5A and 5B are schematic views showing examples of the display device according to the present embodiment. FIG. 5A shows a display device such as a television monitor or a PC monitor. A display device 1300 includes a frame 1301 and a display unit 1302. The display unit 1302 may be formed of the light emitting element according to the present embodiment. The display device includes a base 1303 that supports the frame 1301 and the display unit 1302. The base 1303 is not limited to the form shown in FIG. 5A. The lower side of the base 1301 may also serve as a base. Further, the frame 1301 and the display unit 1302 may be curved. The curvature radius thereof may be 5000 mm or greater and 6000 mm or less.

FIG. 5B is a schematic view showing another example of the display device according to the present embodiment. A display device 1310 of FIG. 5B is a so-called foldable display device that is formed to be foldable. The display device 1310 includes a first display unit 1311, a second display unit 1312, a housing 1313, and a bending point 1314. The first display unit 1311 and the second display unit 1312 may include the light emitting element according to the present embodiment. The first display unit 1311 and the second display unit 1312 may be one seamless display device. The first display unit 1311 and the second display unit 1312 can be divided at the bending point. The first display unit 1311 and the second display unit 1312 may each display different images or the first display unit and the second display unit may also display one image.

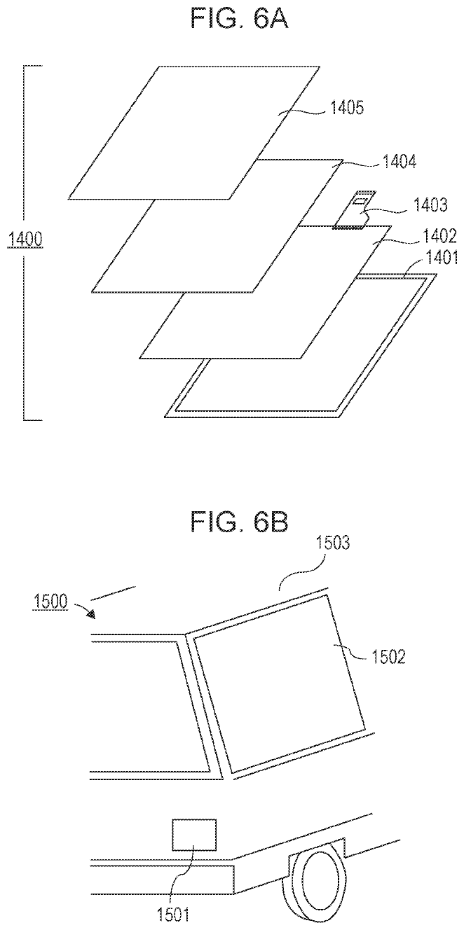

FIG. 6A is a schematic view showing an example of a lighting device according to the present embodiment. A lighting device 1400 may include a housing 1401, a light source 1402, a circuit board 1403, and an optical filter 1404 and a light diffusion unit 1405 that transmit light emitted by the light source 1402. The light source 1402 may include the organic light emitting element according to the present embodiment. The optical filter 1404 may be a filter that improves the color rendering properties of the light source. The light diffusion unit 1405 effectively diffuses light of the light source by performing lighting up or the like and thus can deliver the light to a wide range. The optical filter 1404 and the light diffusion unit 1405 may be provided on a light emission side of lighting. A cover may be provided on the outermost portion.

The lighting device is, for example, a device that lights up a room. The lighting device may emit light of white, neutral white, and any other colors from blue to red. The lighting device may include a light control circuit that controls light of these colors. The lighting device may include the organic light emitting element of the present embodiment and a power supply circuit connected to the organic light emitting element. The power supply circuit is a circuit that converts an alternating current voltage to a direct current voltage. Further, white has a color temperature of 4200K and neutral white has a color temperature of 5000K. The lighting device may include a color filter.

Further, the lighting device according to the present embodiment may include a heat radiation unit. The heat radiation unit releases heat inside the device to the outside of the device, and examples thereof include a metal with high specific heat and liquid silicon.

FIG. 6B is a schematic view showing an automobile as an example of a moving body according to the present embodiment. The automobile includes a tail lamp which is an example of a lamp. An automobile 1500 includes a tail lamp 1501 and may be in the form of turning on the tail lamp when a brake operation is performed.

The tail lamp 1501 may include the organic light emitting element according to the present embodiment. The tail lamp 1501 may include a protective member that protects the organic light emitting element. The protective member is not limited as long as the protective member has a certain high degree of strength and is transparent, but it is preferable that the protective member be formed of polycarbonate or the like. The polycarbonate may be mixed with a furandicarboxylic acid derivative, an acrylonitrile derivative, or the like.

The automobile 1500 may include a car body 1503 and a window 1502 attached to the car body 1503. The window 1502 may be a transparent display when the window is not used to confirm the front and rear of the automobile. The transparent display may include the organic light emitting element according to the present embodiment. In this case, the constituent material such as the electrode of the organic light emitting element is formed of a transparent member.

The moving body according to the present embodiment may be a ship, an aircraft, a drone, or the like. The moving body may include a machine body and a lamp provided on the machine body. The lamp may emit light to inform of the position of the machine body. The lamp includes the organic light emitting element according to the present embodiment.

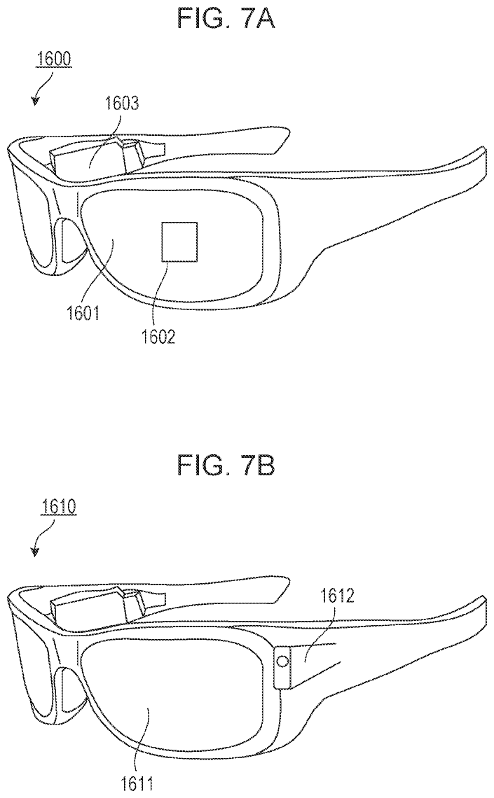

Application examples of the display device according to each of the above-described embodiments will be described with reference to FIGS. 7A and 7B. The display device can be applied to a system that can be mounted as a wearable device such as smart glasses, a HMD, or a smart contact. An imaging display device used in such application examples includes an imaging device capable of photoelectrically converting visible light and a display device capable of emitting visible light.

FIG. 7A is a schematic view showing an example of a wearable device according to an embodiment of the present invention. Glasses 1600 (smart glasses) according to one application example will be described with reference to FIG. 7A. An imaging device 1602 such as a CMOS sensor or a SPAD is provided on the front surface side of a lens 1601 of the glasses 1600. Further, the display device according to each embodiment described is provided on the rear surface side of the lens 1601.

The glasses 1600 further include a control device 1603. The control device 1603 functions as a power supply that supplies power to the imaging device 1602 to the display device. Further, the control device 1603 controls the operations of the imaging device 1602 and the display device. An optical system for condensing light on the imaging device 1602 is formed on the lens 1601.

FIG. 7B is a schematic view showing another example of a wearable device according to an embodiment of the present invention. Glasses 1610 (smart glasses) according to one application example will be described with reference to FIG. 7B. The glasses 1610 include a control device 1612, and the control device 1612 is equipped with an imaging device corresponding to the imaging device 1602 of FIG. 7A and a display device. A lens 1611 is formed with the imaging device in the control device 1612 and an optical system for projecting light emitted from the display device, and an image is projected on the lens 1611. The control device 1612 functions as a power supply that supplies power to the imaging device and the display device and controls the operations of the imaging device and the display device.

The control unit 1612 may include a visual line detection unit that detects the visual line of a wearer. The visual line may be detected by infrared rays. An infrared light emitting unit emits infrared light to the eyeballs of a user gazing a displayed image. A captured image of the eyeballs is obtained by detecting reflected light from the eyeballs to which infrared light has been emitted, using an imaging unit including a light receiving element. Degradation of the image quality is reduced by providing a reduction unit that reduces light from the infrared light emitting unit to the display unit in plan view. The visual line of a user with respect to the displayed image from the captured image of the eyeballs obtained by capturing infrared light is detected. The detection of the visual line using the captured image of the eyeballs can be performed by employing any known method. As an example, a method of detecting the visual line based on a Purkinje image using reflection of light radiated to the cornea can be used. More specifically, a visual line detection treatment is performed by a pupillary corneal reflection method. The visual line of the user is detected by calculating a visual line vector representing the orientation (rotation angle) of the eyeballs based on the pupil image and the Purkinje image included in the captured image of the eyeballs.

The display device according to an embodiment of the present invention includes an imaging device having a light receiving element and may control a displayed image of the display device based on visual line information of the user from the imaging device. Specifically, the display device determines a first visual field region at which the user gazes and a second visual field region other than the first visual field region. The first visual field region and the second visual field region may be determined by the control device of the display device, or an external control device determines any of the regions and the result may be received. In a display region of the display device, the display resolution of the first visual field region may be controlled to be higher than the display resolution of the second visual field region. That is, the resolution of the second visual field region may be set to be less than the resolution of the first visual field region.

Further, the display region has the first display region and the second display region different from the first display region, and a region with high priority is determined from the first display region and the second display region. The first display region and the second display region may be determined by the control device of the display device, or an external control device determines any of the regions and the result may be received. The resolution of the region with a high priority may be controlled to be higher than the resolution of the region other than the region with a high priority. That is, the resolution of the region with a relatively lower priority may be decreased.

Further, the first visual field region and the region with a higher priority may be determined by using AI. The AI may be a model formed to estimate the angle of the visual line from the image of the eyeballs and the distance from the eyeballs of the image to the object in front of the visual line, using the image of the eyeballs and the direction in which the eyeballs of the image are actually gazing as teaching data. The display device, the imaging device, or an external device may have an AI program. When an external device has the AI program, the AI program is transmitted to the display device through communication.

When display is controlled based on visual line detection, an imaging device that captures an image of the outside can be preferably applied to smart glasses. The smart glasses can display captured external information in real time.

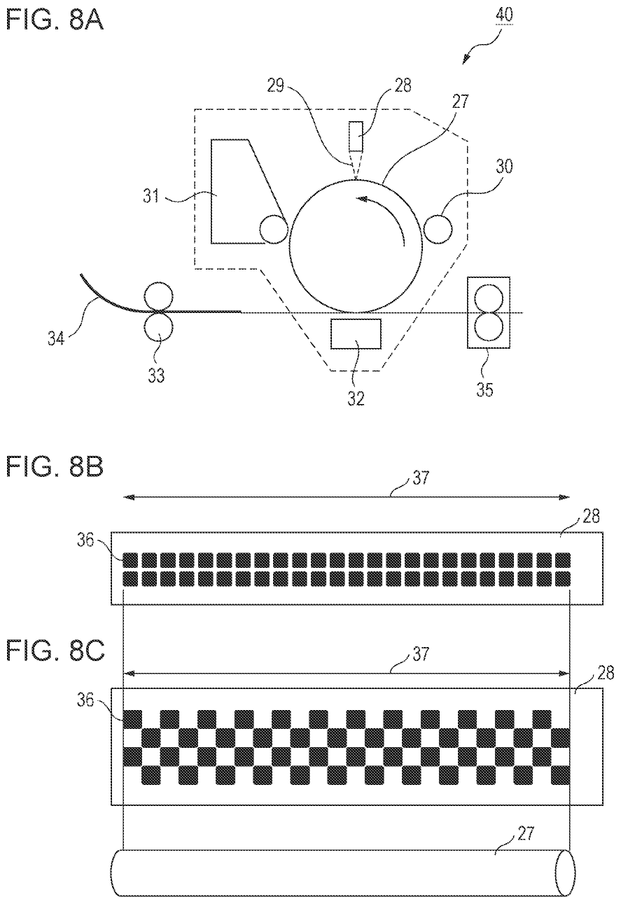

FIG. 8A is a schematic view showing an example of an image forming apparatus according to an embodiment of the present invention. An image forming apparatus 40 is an electrophotographic image forming apparatus and includes a photoreceptor 27, an exposure light source 28, a charging unit 30, a developing unit 31, a transfer device 32, a transport roller 33, and a fixing device 35. Light 29 is radiated from the exposure light source 28 to form an electrostatic latent image on a surface of the photoreceptor 27. The exposure light source 28 includes the organic light emitting element according to the present embodiment. The developing unit 31 includes a toner and the like. The charging unit 30 charges the photoreceptor 27. The transfer device 32 transfers the developed image to a recording medium 34. The transport roller 33 transports the recording medium 34. The recording medium 34 is, for example, paper. The fixing device 35 fixes the image formed on the recording medium 34.

FIGS. 8B and 8C show the exposure light source 28 and schematically show an aspect in which a plurality of the light emitting units 36 are arranged on a long substrate. An arrow 37 indicates a direction parallel to an axis of the photoreceptor and represents a column direction in which organic light emitting elements are aligned. The column direction is the same direction as the direction of an axis around which the photoreceptor 27 rotates. The direction can also be referred to as a major axis direction of the photoreceptor 27. FIG. 8B shows a form in which the light emitting units 36 are arranged in the major axis direction of the photoreceptor 27. FIG. 8C shows a form which is different from the form of FIG. 8B and in which the light emitting units 36 in each of the first column and the second column are alternately arranged in the column direction. The light emitting units 36 in the first column and the second column are arranged at different positions in the row direction. A plurality of the light emitting units 36 in the first column are arranged at intervals. In the second column, the light emitting units 36 are arranged at positions corresponding to the intervals of the light emitting units 36 in the first column. That is, a plurality of the light emitting units 36 are arranged at intervals even in the row direction. The arrangement of FIG. 8C can also be expressed as, for example, a grid-like arrangement state, a zigzag arrangement state, or a checkered pattern.

As described above, an image with a satisfactory image quality can be stably displayed for a long time by using a device formed of the organic light emitting element according to the present embodiment.

### EXAMPLES

Hereinafter, the present invention will be described based on examples. However, the present invention is not limited thereto.

### Example 1 (Synthesis of Exemplary Compounds A25 and A33)

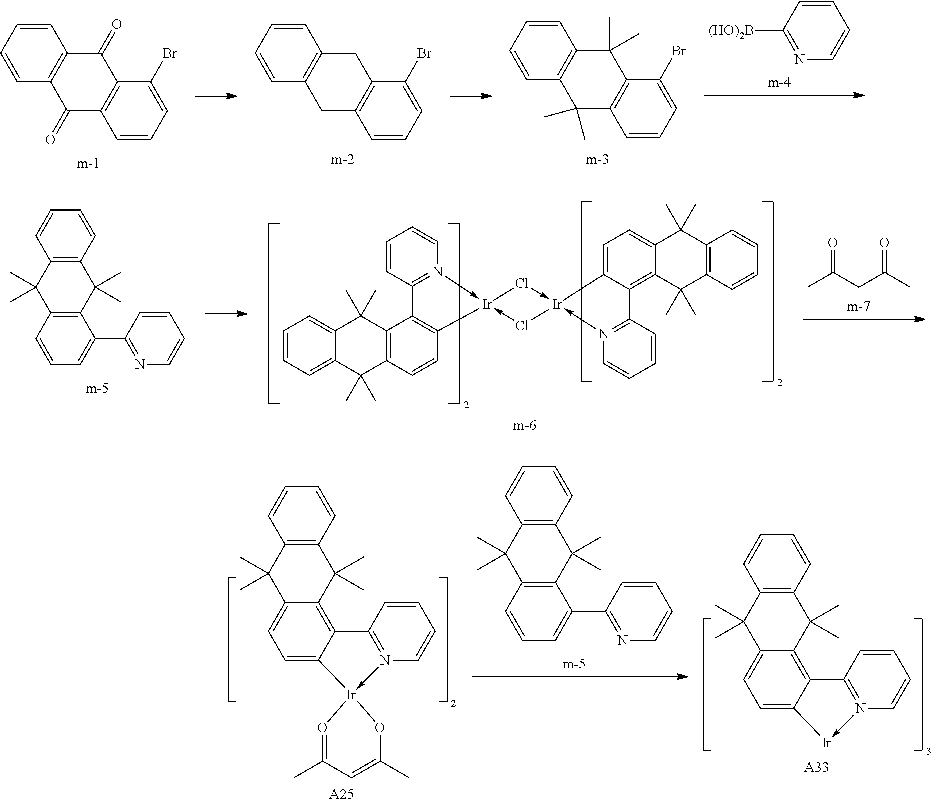

### (1) Synthesis of Compound m-2

A 2000 ml eggplant flask was charged with reagents and solvents described below.
Compound m-1: 20.0 g (0.07 mol)
Hydrazine monohydrate: 87.2 g (1.74 mol)
Potassium carbonate: 19.3 g (0.14 mol)
Diethylene glycol: 200 ml
Chlorobenzene: 200 ml

Next, the reaction solution was heated, refluxed, and stirred in a nitrogen gas stream. After the completion of the reaction, a 1N hydrochloric acid solution was added to the reaction solution at room temperature. The reaction solution was subjected to an extraction operation with toluene and concentrated, and the obtained residues were purified by column chromatography (chloroform/heptane=1:4) and recrystallized with chloroform/methanol, thereby obtaining 3.6 g of a compound m-2 (yield: 20%) in a light brown solid state.

### (2) Synthesis of Compound m-3

A 200 ml eggplant flask was charged with reagents and solvents described below.
Compound m-2: 3.0 g (11.6 mmol)
Potassium-t-butoxide: 3.9 g (26.6 mmol)
DMSO: 45 ml

Next, while the reaction solution was stirred at 5° C., 3.2 g (28.9 mmol) of methyl iodide was slowly added thereto. Thereafter, the reaction solution was stirred at room temperature. After the completion of the reaction, a 1N hydrochloric acid solution was added to the reaction solution at room temperature. The reaction solution was subjected to an extraction operation with toluene and concentrated, and the obtained residues were purified by column chromatography (chloroform/heptane=1:4) and recrystallized with chloroform/methanol, thereby obtaining 2.5 g of a compound m-2 (yield: 70%) in a light brown solid state.

### (3) Synthesis of Compound m-5

A 200 ml eggplant flask was charged with reagents and solvents described below.
Compound m-3: 2.0 g (6.3 mmol)
Compound m-4: 1.2 g (9.5 mmol)
Pd(PPh₃)₄: 0.07 g
Toluene: 20 ml
Ethanol: 10 ml
2 M sodium carbonate aqueous solution: 20 ml

Next, the reaction solution was heated to 80° C. in a nitrogen gas stream and stirred at this temperature (80° C.) for 6 hours. After the completion of the reaction, water was added to the reaction solution to perform liquid separation, and the resultant was dissolved in chloroform and purified by column chromatography (chloroform) and recrystallized with chloroform/methanol, thereby obtaining 0.95 g of a compound m-5 (yield: 48%) in a light yellow solid state.

### (4) Synthesis of Compound m-6

A 200 ml eggplant flask was charged with reagents and solvents described below.
2-Ethoxyethanol: 24 ml
Iridium(III) chloride hydrate: 0.32 g
Compound m-5: 0.8 g (2.6 mmol)

Next, the reaction solution was heated to 120° C. and stirred for 6 hours. The reaction solution was cooled, water was added thereto, and the resulting reaction solution was filtered and washed with water. The resultant was dried, thereby obtaining 1.0 g of a compound m-6 (yield of 90%) in a yellow solid state.

### (5) Synthesis of Exemplary Compound A25

A 200 ml eggplant flask was charged with reagents and solvents described below.
2-Ethoxyethanol: 30 ml
Compound m-6: 1.0 g (0.6 mmol)
Compound m-7: 0.23 g (2.3 mmol)
Sodium carbonate: 0.6 g (5.9 mmol)

Next, the reaction solution was heated to 100° C. and stirred for 6 hours. The reaction solution was cooled, methanol was added thereto, and the resulting reaction solution was filtered and washed with water. The resultant was dried, thereby obtaining 0.7 g of an exemplary compound A25 (yield of 65%) in a yellow solid state.

Further, the exemplary compound A25 was subjected to mass spectrometry using MALDI-TOF-MS (Autoflex LRF, manufactured by Bruker).

### [MALDI-TOF-MS]

Measured value: m/z=916, calculated value: C₅₁H₅₁IrN₂O₂=916

### (6) Synthesis of Exemplary Compound A33

A 50 ml eggplant flask was charged with reagents and solvents described below.
Exemplary compound A25: 0.5 g (0.5 mmol)
Compound m-5: 1.7 g (5.5 mmol)

Next, the reaction solution was heated to 230° C. and stirred for 3 hours. The reaction solution was cooled to 100° C., 2 mL of toluene was added thereto, and the reaction solution was stirred until the temperature reached room temperature. Thereafter, heptane was added to the reaction solution, and the resulting reaction solution was filtered. The filtrate was purified by silica gel column chromatography (ethyl acetate), thereby obtaining 0.1 g of an exemplary compound A33 (yield of 20%) in a dark yellow solid state.

Further, the exemplary compound A33 was subjected to mass spectrometry in the same manner as that for the exemplary compound A25.

### [MALDI-TOF-MS]

Measured value: m/z=1129, calculated value: C₆₉H₆₆IrN₃=1129

### Example 2 (Synthesis of Exemplary Compound B9)

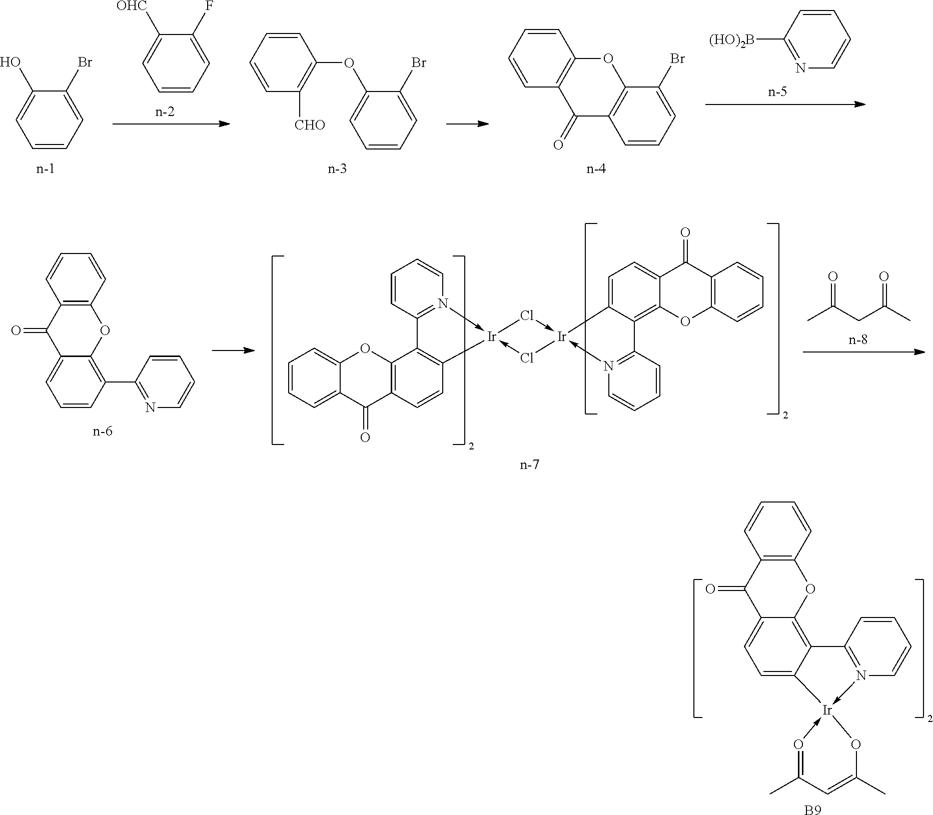

### (1) Synthesis of Compound n-3

A 1000 ml eggplant flask was charged with reagents and solvents described below.
Compound n-1: 10.0 g (0.06 mol)
Compound n-2: 8.6 g (0.07 mol)
Potassium carbonate: 24.5 g (0.12 mol)
CuCl₂: 0.4 g (0.003 mol)
Triphenylphosphine: 1.1 g (0.004 mol)
DMF: 200 ml

Next, the reaction solution was heated, refluxed, and stirred in a nitrogen gas stream. After the completion of the reaction, a 1N hydrochloric acid solution was added to the reaction solution at room temperature. The reaction solution was subjected to an extraction operation with toluene and concentrated, and the obtained residues were purified by column chromatography (chloroform/heptane=1:4) and recrystallized with chloroform/methanol, thereby obtaining 10.4 g of a compound n-3 (yield: 65%) in a light brown solid state.

### (2) Synthesis of Compound n-4

A 200 ml eggplant flask was charged with reagents and solvents described below.
Compound n-3: 5.0 g (0.02 mmol)
DDQ: 12.3 g (0.05 mmol)
FeCl₃·6H₂O: 14.6 g (0.05 mmol)
Dichloroethane: 100 ml

Next, the reaction solution was heated, refluxed, and stirred in a nitrogen gas stream. After the completion of the reaction, a 1N hydrochloric acid solution was added to the reaction solution at room temperature. The reaction solution was subjected to an extraction operation with toluene and concentrated, and the obtained residues were purified by column chromatography (chloroform/heptane=1:4) and recrystallized with chloroform/methanol, thereby obtaining 2.6 g of a compound n-4 (yield: 53%) in a gray solid state.

### (3) Synthesis of Compound n-6

A 200 ml eggplant flask was charged with reagents and solvents described below.
Compound n-4: 2.0 g (7.3 mmol)
Compound n-5: 1.3 g (10.9 mmol)
Pd(PPh₃)₄: 0.08 g
Toluene: 20 ml
Ethanol: 10 ml
2 M sodium carbonate aqueous solution: 20 ml

Next, the reaction solution was heated to 80° C. in a nitrogen gas stream and stirred at this temperature (80° C.) for 6 hours. After the completion of the reaction, water was added to the reaction solution to perform liquid separation, and the resultant was dissolved in chloroform and purified by column chromatography (chloroform) and recrystallized with chloroform/methanol, thereby obtaining 1.05 g of a compound n-6 (yield: 53%) in a light yellow solid state.

### (4) Synthesis of Compound n-7

A 200 ml eggplant flask was charged with reagents and solvents described below.
2-Ethoxyethanol: 24 ml
Iridium(III) chloride hydrate: 0.32 g
Compound n-6: 0.8 g (2.6 mmol)

Next, the reaction solution was heated to 120° C. and stirred for 6 hours. The reaction solution was cooled, water was added thereto, and the resulting reaction solution was filtered and washed with water. The resultant was dried, thereby obtaining 1.0 g of a compound n-7 (yield of 90%) in a yellow solid state.

### (5) Synthesis of Exemplary Compound B9

A 200 ml eggplant flask was charged with reagents and solvents described below.
2-Ethoxyethanol: 30 ml
Compound n-7: 1.0 g (0.6 mmol)
Compound n-8: 0.26 g (2.6 mmol)
Sodium carbonate: 0.7 g (6.5 mmol)

Next, the reaction solution was heated to 100° C. and stirred for 6 hours. The reaction solution was cooled, methanol was added thereto, and the resulting reaction solution was filtered and washed with methanol. The resultant was dried, thereby obtaining 0.7 g of an exemplary compound B9 (yield of 66%) in a yellow solid state.

Further, the exemplary compound B9 was subjected to mass spectrometry in the same manner as in Example 1.

### [MALDI-TOF-MS]

Measured value: m/z=836, calculated value: C₄₁H₂₇IrN₂O₆=836

### Examples 3 to 5 (Synthesis of Exemplary Compounds)

Exemplary compounds of Examples 3 to 5 were synthesized in the same manner as that for the exemplary compound A25 in Example 1 except that the compounds listed in Table 7 were used as the raw materials m-3, m-4, and m-7 in Example 1. Further, the measured values (m/z) as the results of mass spectrometry measured in the same manner as in Example 1 are listed in Table 7.

TABLE 7

| | Exemplary | Raw material | Raw material | Raw material | |
|---|---|---|---|---|---|
| Example | compound | m-3 | m-4 | m-7 | m/z |
| 3 | A27 | 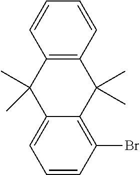 [SMILES: CC1(C)c2ccccc2C(C)(C)c2c(Br)cccc21] | 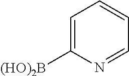 | 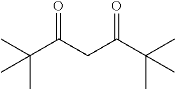 | 1000 |
| 4 | A29 | 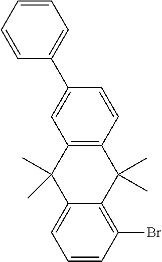 [SMILES: CC1(C)c2cc(-c3ccccc3)ccc2C(C)(C)c2c(Br)cccc21] | 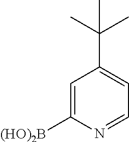 | 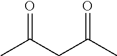 | 1080 |
| 5 | C13 | 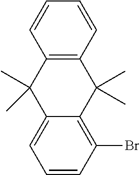 [SMILES: CC1(C)c2ccccc2C(C)(C)c2c(Br)cccc21] | 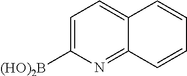 [SMILES: OB(O)c1ccc2ccccc2n1] | 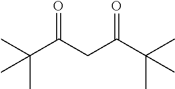 | 1110 |

### Examples 6 to 9 (Synthesis of Exemplary Compounds)

Exemplary compounds of Examples 6 to 9 were synthesized in the same manner as that for the exemplary compound A33 in Example 1 except that the compounds listed in Table 8 were used as the raw materials m-3, m-4, and m-5 in Example 1. Further, the measured values (m/z) as the results of mass spectrometry measured in the same manner as in Example 1 are listed in Table 8.

TABLE 8

| | Exemplary | Raw material | Raw material | Raw material | |
|---|---|---|---|---|---|
| Example | compound | m-3 | m-4 | m-5 | m/z |
| 6 | A36 | 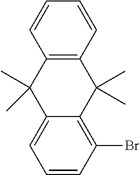 [SMILES: CC1(C)c2ccccc2C(C)(C)c2c(Br)cccc21] | 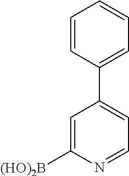 [SMILES: OB(O)c1cc(-c2ccccc2)ccn1] | 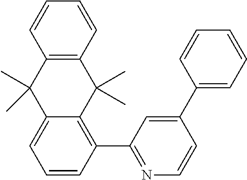 [SMILES: CC1(C)c2ccccc2C(C)(C)c2c(-c3cc(-c4ccccc4)ccn3)cccc21] | 1358 |
| 7 | B19 | 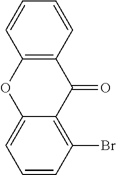 [SMILES: O=c1c2ccccc2oc2cccc(Br)c12] | 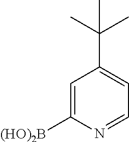 | 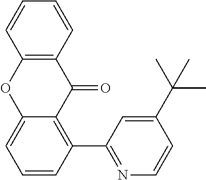 [SMILES: CC(C)(C)c1ccnc(-c2cccc3oc4ccccc4c(=O)c23)c1] | 1177 |
| 8 | C19 | 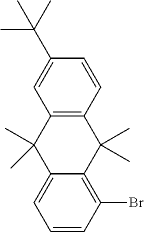 [SMILES: CC(C)(C)c1ccc2c(c1)C(C)(C)c1cccc(Br)c1C2(C)C] | 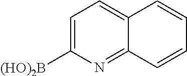 [SMILES: OB(O)c1ccc2ccccc2n1] | 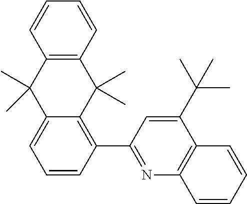 [SMILES: CC(C)(C)c1cc(-c2cccc3c2C(C)(C)c2ccccc2C3(C)C)nc2ccccc12] | 1616 |
| 9 | A35 | 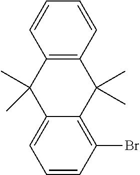 [SMILES: CC1(C)c2ccccc2C(C)(C)c2c(Br)cccc21] | 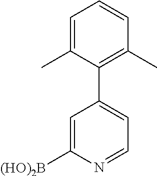 | 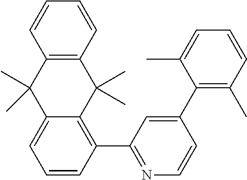 | 1442 |

### Example 10 (Synthesis of Exemplary Compound A1)

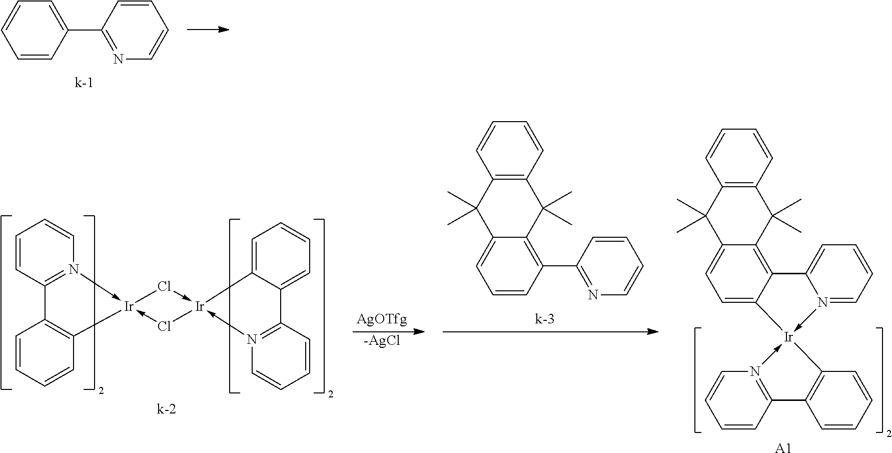

A compound k-2 was synthesized in the same manner as in “(4) Synthesis of compound m-6” of Example 1, and thus the description thereof will not be provided.

A 200 ml eggplant flask was charged with reagents and solvents described below.
Compound k-2: 1.0 g (0.9 mmol)
AgOTf: 0.5 g (1.9 mmol)
Dichloromethane: 50 ml
Methanol: 2 ml

Next, the reaction solution was stirred at room temperature for 6 hours. Thereafter, the solvent was distilled off under reduced pressure, thereby obtaining a yellow solid.

Next, a 200 ml eggplant flask was charged with the obtained yellow solid, and reagents and solvents described below.
Ethanol: 30 ml
Compound k-3: 0.4 g (1.9 mmol)

Next, the reaction solution was heated to 85° C. and stirred for 3 hours. The reaction solution was cooled and filtered. The filtrate was purified by silica gel column chromatography (chloroform:heptane=1:1), thereby obtaining 0.9 g of an exemplary compound A1 (yield of 59%) in a dark yellow solid state.

Further, the exemplary compound A1 was subjected to mass spectrometry in the same manner as in Example 1.

### [MALDI-TOF-MS]

Measured value: m/z=813, calculated value: C₄₅H₃₈IrN₃=813

### Examples 11 to 20 (Synthesis of Exemplary Compounds)

Exemplary compounds of Examples 11 to 20 were synthesized in the same manner as in Example 10 except that the compounds listed in Tables 9 and 10 were used as the raw materials k-1 and k-3 in Example 10. Further, the measured values (m/z) as the results of mass spectrometry measured in the same manner as in Example 10 are listed in Tables 9 and 10.

TABLE 9

| | Exemplary | | | |
|---|---|---|---|---|
| Example | compound | Raw material k-1 | Raw material k-3 | m/z |
| 11 | A2 | 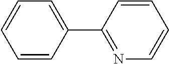 [SMILES: c1ccc(-c2ccccn2)cc1] | 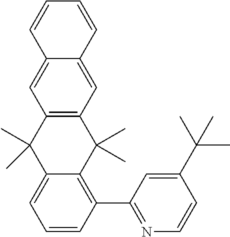 [SMILES: CC(C)(C)c1ccnc(-c2cccc3c2C(C)(C)c2cc4ccccc4cc2C3(C)C)c1] | 919 |
| 12 | A10 | 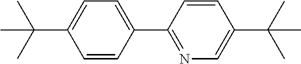 [SMILES: CC(C)(C)c1ccc(-c2ccc(C(C)(C)C)cn2)cc1] | 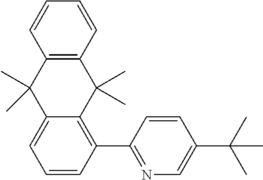 [SMILES: CC(C)(C)c1ccc(-c2cccc3c2C(C)(C)c2ccccc2C3(C)C)nc1] | 1094 |
| 13 | A14 | 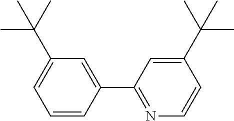 [SMILES: CC(C)(C)c1cccc(-c2cc(C(C)(C)C)ccn2)c1] | 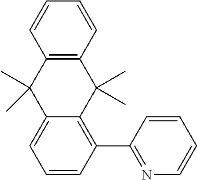 [SMILES: CC1(C)c2ccccc2C(C)(C)c2c(-c3ccccn3)cccc21] | 1037 |
| 14 | A12 | 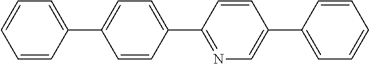 [SMILES: c1ccc(-c2ccc(-c3ccc(-c4ccccc4)cn3)cc2)cc1] | 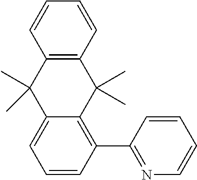 [SMILES: CC1(C)c2ccccc2C(C)(C)c2c(-c3ccccn3)cccc21] | 1117 |
| 15 | A17 | 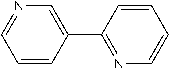 [SMILES: c1ccc(-c2cccnc2)nc1] | 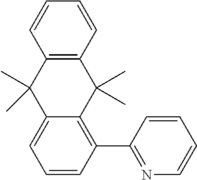 [SMILES: CC1(C)c2ccccc2C(C)(C)c2c(-c3ccccn3)cccc21] | 871 |

TABLE 10

| | Exemplary | | | |
|---|---|---|---|---|
| Example | compound | Raw material k-1 | Raw material k-3 | m/z |
| 16 | A30 | 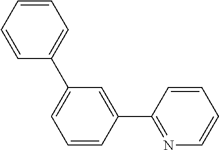 [SMILES: c1ccc(-c2cccc(-c3ccccn3)c2)cc1] | 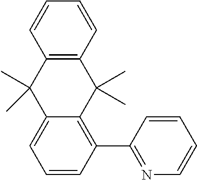 [SMILES: CC1(C)c2ccccc2C(C)(C)c2c(-c3ccccn3)cccc21] | 965 |
| 17 | B2 | 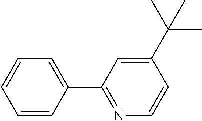 [SMILES: CC(C)(C)c1ccnc(-c2ccccc2)c1] | 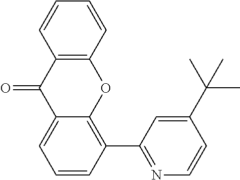 [SMILES: CC(C)(C)c1ccnc(-c2cccc3c(=O)c4ccccc4oc23)c1] | 941 |
| 18 | B6 | 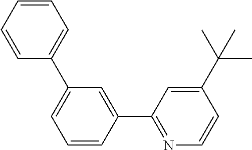 [SMILES: CC(C)(C)c1ccnc(-c2cccc(-c3ccccc3)c2)c1] | 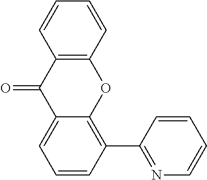 [SMILES: O=c1c2ccccc2oc2c(-c3ccccn3)cccc12] | 1037 |
| 19 | B8 | 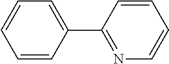 [SMILES: c1ccc(-c2ccccn2)cc1] | 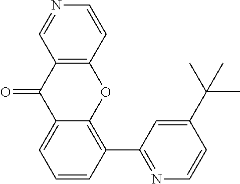 [SMILES: CC(C)(C)c1ccnc(-c2cccc3c(=O)c4cnccc4oc23)c1] | 830 |
| 20 | C1 | 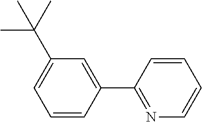 [SMILES: CC(C)(C)c1cccc(-c2ccccn2)c1] | 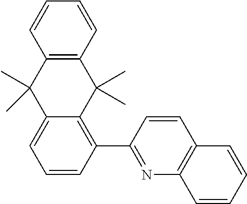 [SMILES: CC1(C)c2ccccc2C(C)(C)c2c(-c3ccc4ccccc4n3)cccc21] | 975 |

### Example 21

An organic light emitting element having a bottom emission type structure, in which an anode, a positive hole injection layer, a positive hole transport layer, an electron blocking layer, a light emitting layer, a positive hole blocking layer, an electron transport layer, an electron injection layer, and a cathode were formed in this order on a substrate, was prepared.

First, an ITO electrode (anode) was formed by forming an ITO film on a glass substrate and performing desired patterning processing. Here, the film thickness of the ITO electrode was set to 100 nm. The following step was performed by using the substrate on which the ITO electrode had been formed in the above-described manner as an ITO substrate. Next, vacuum deposition was performed by resistance heating in a vacuum chamber at 1.33×10⁻⁴ Pa, and an organic compound layer and an electrode layer listed in Table 11 were continuously formed on the ITO substrate. At this time, the electrode area of the opposing electrodes (the metal electrode layer and the cathode) was set to 3 mm².

TABLE 11

| | | | | Film |
|---|---|---|---|---|
| | | | | thickness |
| | Material | | | (nm) |
| Cathode | A1 | | | 100 |
| Electron injection layer (EIL) | LiF | | | 1 |
| Electron transport layer (ETL) | ET2 | | | 20 |
| Positive hole blocking layer (HBL) | ET11 | | | 20 |
| Light emitting layer (EML) | Host | BB37 | Mass ratio | 20 |
| | Guest | A1 | BB37:A1 = 90:10 | |

| | | |
|---|---|---|
| Electron blocking layer (EBL) | HT19 | 15 |
| Positive hole transport layer (HTL) | HT3 | 30 |
| Positive hole injection layer (HIL) | HT16 | 5 |

The characteristics of the obtained element were measured and evaluated. The maximum emission wavelength of the light emitting element was 532 nm, and the maximum external quantum efficiency (E.Q.E) was 11%.

Further, a continuous driving test was performed at a current density of 100 mA/cm², and the time when the brightness deterioration rate reached 5% was measured. The brightness deterioration rate of the present example was 1.9 when the time when the brightness deterioration rate of Comparative Example 1 reached 5% was set to 1.0.

In the present example, specifically, the current voltage characteristics were measured using a microammeter 4140B (manufactured by Hewlett-Packard Company) and the light emission brightness was measured using BM7 (manufactured by Topcon Corporation) as a measuring device.

### Examples 22 to 31 and Comparative Examples 1 to 3

In Examples 22 to 31, organic light emitting elements were prepared by the same method as in Example 21 except that the compounds listed in Table 12 were appropriately changed. The characteristics of the obtained elements were measured and evaluated in the same manner as in Example 21. The results of the measurement are listed in Table 12. Further, the comparative compound 1-A and the comparative compound 1-B respectively denote the comparative compound 1-A listed in Tables 1, 3, and 4 and the comparative compound 1-B listed in Table 5.

TABLE 12
E.Q.E Ratio of brightness

| | | | | EML | | | | E.Q.E | Ratio of brightness |
|---|---|---|---|---|---|---|---|---|---|
| | HIL | HTL | EBL | Host | Guest | HBL | ETL | [%] | deterioration rate |
| Example 22 | HT16 | HT3 | HT19 | BB19 | A14 | ET12 | ET15 | 12 | 1.9 |
| Example 23 | HT16 | HT2 | HT15 | BB18 | A10 | ET12 | ET2 | 11 | 1.8 |
| Example 24 | HT16 | HT2 | HT15 | CC19 | A11 | ET11 | ET2 | 10 | 1.7 |
| Example 25 | HT16 | HT3 | HT19 | CC7 | A17 | ET12 | ET15 | 10 | 1.7 |
| Example 26 | HT16 | HT3 | HT19 | AA7 | A1 | ET12 | ET15 | 13 | 1.5 |
| Example 27 | HT16 | HT3 | HT19 | BB41 | A33 | ET11 | ET15 | 9 | 1.8 |
| Example 28 | HT16 | HT3 | HT19 | BB19 | A25 | ET12 | ET2 | 11 | 1.6 |
| Example 29 | HT16 | HT2 | HT15 | BB8 | B6 | ET12 | ET15 | 12 | 1.9 |
| Example 30 | HT16 | HT3 | HT19 | BB20 | C2 | ET12 | ET15 | 11 | 1.9 |
| Example 31 | HT16 | HT2 | HT15 | EM16 | A1 | ET11 | ET2 | 10 | 1.3 |
| Comparative | HT16 | HT3 | HT19 | BB37 | Comparative | ET11 | ET2 | 8 | 1.0 |
| Example 1 | | | | | compound 1-A | | | | |
| Comparative | HT16 | HT3 | HT19 | EM33 | Comparative | ET11 | ET2 | 8 | 0.5 |
| Example 2 | | | | | compound 1-A | | | | |
| Comparative | HT16 | HT3 | HT19 | BB37 | Comparative | ET11 | ET2 | 10 | 0.8 |
| Example 3 | | | | | compound 1-B | | | | |

As listed in Table 12, the maximum external quantum efficiency (E.Q.E.) of Comparative Example was 8%, and the light emitting element according to the present invention had higher emission efficiency. This is because the organometallic complex according to the present invention had a higher quantum yield. Further, the light emitting element according to the present invention had a longer lifetime. The reason for this is assumed that the Ir complex (comparative compound 1-A) used in Comparative Example 1 is the Ir complex described in PTL 1 which is a material with low bonding stability.

Further, the ratio of the brightness deterioration rate of Comparative Example 2 was 0.5, and the light emitting element according to the present invention had a longer lifetime. The Ir complex (comparative compound 1-A) used in Comparative Example 2 is the Ir complex described in PTL 1, and the host material is CBP which is the host material described in PTL 1.

Further, the ratio of the brightness deterioration rate of Comparative Example 3 was 0.8, and the light emitting element according to the present invention had a longer lifetime. The reason for this is assumed that the Ir complex (comparative compound 1-B) used in Comparative Example 3 is the Ir complex described in PTL 2 which is a material with low oxidation stability.

As described above, a device with high efficiency and excellent durability can be provided by using the organometallic complex according to the present invention and more preferably selecting a preferable host material.

### Example 32

An organic light emitting element was prepared by the same method as in Example 21 except that the organic compound layer and the electrode layer listed in Table 13 were continuously formed.

TABLE 13

| | | | | Film |
|---|---|---|---|---|
| | | | | thickness |
| | Material | | | (nm) |
| Cathode | A1 | | | 100 |
| Electron injection layer (EIL) | LiF | | | 1 |
| Electron transport layer (ETL) | ET2 | | | 20 |
| Positive hole blocking layer (HBL) | ET11 | | | 20 |
| Light emitting layer (EML) | Host | BB37 | Mass ratio | 20 |
| | Guest | A10 | BB37:A10:EM30 = | |
| | Assist | EM30 | 60:10:30 | |

| | | |
|---|---|---|
| Electron blocking layer (EBL) | HT19 | 15 |
| Positive hole transport layer (HTL) | HT3 | 30 |
| Positive hole injection layer (HIL) | HT16 | 5 |

The characteristics of the obtained element were measured and evaluated. The emission color of the light emitting element was green, and the maximum external quantum efficiency (E.Q.E) was 20%.

### Examples 33 to 42

In Examples 33 to 42, organic light emitting elements were prepared by the same method as in Example 32 except that the compounds listed in Table 14 were appropriately changed. The characteristics of the obtained elements were measured and evaluated in the same manner as in Example 32. The results of the measurement are listed in Table 14.

TABLE 14

| | | | | EML | | | | | E.Q.E |
|---|---|---|---|---|---|---|---|---|---|
| | HIL | HTL | EBL | Host | Guest | Assist | HBL | ETL | [%] |
| Example 33 | HT16 | HT3 | HT19 | BB19 | A14 | EM29 | ET26 | ET3 | 18 |
| Example 34 | HT16 | HT2 | HT15 | BB18 | A15 | EM38 | ET13 | ET2 | 17 |
| Example 35 | HT16 | HT2 | HT15 | CC19 | A9 | EM37 | ET13 | ET2 | 17 |
| Example 36 | HT16 | HT3 | HT19 | CC18 | A29 | AA16 | ET16 | ET15 | 16 |
| Example 37 | HT16 | HT3 | HT19 | AA7 | B1 | AA5 | ET16 | ET15 | 15 |
| Example 38 | HT16 | HT3 | HT19 | BB41 | B2 | A10 | ET17 | ET15 | 17 |
| Example 39 | HT16 | HT3 | HT19 | BB19 | B3 | EM40 | ET13 | ET2 | 18 |
| Example 40 | HT16 | HT2 | HT15 | BB29 | B6 | EM28 | ET15 | ET3 | 19 |
| Example 41 | HT16 | HT3 | HT19 | BB19 | B9 | ET15 | ET15 | ET15 | 16 |
| Example 42 | HT16 | HT2 | HT15 | CC21 | B8 | ET17 | ET2 | ET2 | 14 |

The organic compound according to the present invention has a high quantum yield and excellent light emitting properties. Further, the chemical stability of the compound itself is high. Therefore, an organic light emitting element with excellent emission efficiency and excellent durability can also be provided by using this organic compound.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

1. An organic compound represented by M(L₁)ₙ(L₂)ₘ,
wherein M represents a metal atom, n+m=3, n≥1,
wherein M(L₁) is represented by Formulae [2] and [3], and M(L₂) is represented by Formula [4] or [5], 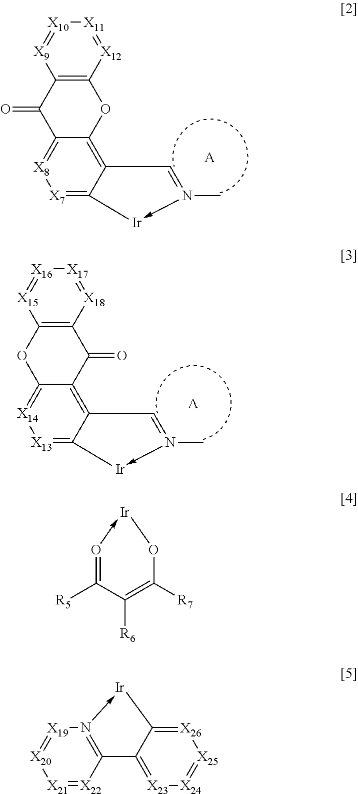
in Formulae [2] and [3], a ring A is selected from structures represented by Formula [6] or [7], 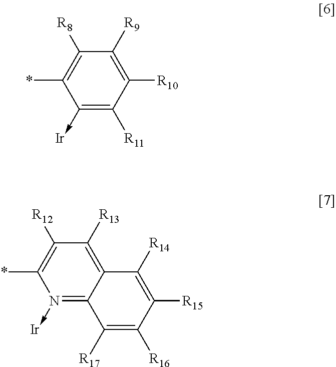
* represents a bonding position,
in Formulae [2], [3], and [5], X₁ to X₂₆ each independently represent a carbon atom or a nitrogen atom, the carbon atom has a hydrogen atom, a deuterium atom, or a substituent R, the substituent R is selected from a halogen atom, a substituted or unsubstituted alkyl group, a substituted or unsubstituted alkoxy group, a substituted or unsubstituted amino group, a substituted or unsubstituted aryloxy group, a substituted or unsubstituted heteroaryloxy group, a substituted or unsubstituted silyl group, a cyano group, a trifluoromethyl group, a substituted or unsubstituted aromatic hydrocarbon group, and a substituted or unsubstituted heterocyclic group,
in Formulae [4], [6], and [7], R₅ to R₁₇ each independently represent a hydrogen atom, a deuterium atom, a halogen atom, a substituted or unsubstituted alkyl group, a substituted or unsubstituted alkoxy group, a substituted or unsubstituted amino group, a substituted or unsubstituted aryloxy group, a substituted or unsubstituted heteroaryloxy group, a substituted or unsubstituted silyl group, a cyano group, a trifluoromethyl group, a substituted or unsubstituted aromatic hydrocarbon group, or a substituted or unsubstituted heterocyclic group.

2. (canceled)

3. The organic compound according to claim 1,
wherein R₅ to R₁₇ represent any of a hydrogen atom, a deuterium atom, a tertiary butyl group, or a phenyl group.

4. The organic compound according claim 1,
wherein R₈ and R₁₂ represent a hydrogen atom.

5. (canceled)

6. (canceled)

7. An organic light emitting element comprising:
an anode;
a cathode; and
organic compound layers disposed between the anode and the cathode,
wherein at least one of the organic compound layers contains the organic compound according to claim 1.

8. The organic light emitting element according to claim 7,
wherein the layer containing the organic compound is a light emitting layer.

9. The organic light emitting element according to claim 8,
wherein the light emitting layer further contains a host material, and
a content of the organic compound is 1% by mass or greater and 30% by mass or less.

10. The organic light emitting element according to claim 9,
wherein the host material has at least an azine ring in a skeleton.

11. The organic light emitting element according to claim 9,
wherein the host material has at least any of triphenylene, phenanthrene, chrysene, or fluoranthene in a skeleton.

12. The organic light emitting element according to claim 9,
wherein the host material has at least any of dibenzothiophene or dibenzofuran in a skeleton.

13. The organic light emitting element according to claim 9,
wherein the host material contains no SP³ carbon.

14. The organic light emitting element according to claim 9,
wherein the light emitting layer further contains a third component.

15. The organic light emitting element according to claim 8, further comprising:
a different light emitting layer disposed by being laminated on the light emitting layer,
wherein the different light emitting layer emits light of a color different from an emission color of light emitted by the light emitting layer.

16. The organic light emitting element according to claim 15,
wherein the organic light emitting element emits light of a white color.

17. A display device comprising:
a plurality of pixels,
wherein at least one of the plurality of pixels includes the organic light emitting element according to claim 7 and an active element connected to the organic light emitting element.

18. A photoelectric conversion device comprising:
an optical unit that includes a plurality of lenses;
an imaging element that receives light allowed to pass through the optical unit; and
a display unit that displays an image captured by the imaging element,
wherein the display unit includes the organic light emitting element according to claim 7.

19. An electronic device comprising:
a display unit that includes the organic light emitting element according to claim 7;
a housing where the display unit is provided; and
a communication unit that is provided in the housing and communicates with an outside.

20. A lighting device comprising:
a light source that includes the organic light emitting element according to claim 7; and
a light diffusion unit or an optical filter that transmits light emitted by the light source.

21. A moving body comprising:
a lamp that includes the organic light emitting element according to claim 7; and
a machine body where the lamp is provided.

22. An exposure light source of an electrophotographic image forming apparatus, comprising:
the organic light emitting element according to claim 7.
